(19) United States
(12) Patent Application Publication
(10) Pub. No.: US 2025/0113492 A1
(43) Pub. Date: Apr. 3, 2025

(54) THREE-DIMENSIONAL MEMORY DEVICE CONTAINING LATERALLY UNDULATING ISOLATION TRENCHES AND METHODS OF MAKING THE SAME

(71) Applicant: WESTERN DIGITAL TECHNOLOGIES, INC.,, SAN JOSE, CA (US)

(72) Inventors: Wataru MURANAGA, Yokkaichi (JP); Keisuke SHIGEMURA, Yokkaichi (JP); Atsushi SHIMIZU, Yokkaichi (JP)

(21) Appl. No.: 18/508,638

(22) Filed: Nov. 14, 2023

Related U.S. Application Data
(63) Continuation-in-part of application No. 18/477,907, filed on Sep. 29, 2023.

(51) Int. Cl. H10B 43/50; H01L 23/00; H01L 25/00; H01L 25/065; H01L 25/18; H10B 41/27; H10B 41/50; H10B 43/27; H10B 80/00

(52) U.S. Cl. CPC H10B 43/50; H01L 24/08; H01L 24/80; H01L 25/0657; H01L 25/18; H01L 25/50; H10B 41/27; H10B 41/50; H10B 43/27; H10B 80/00; H01L 2224/08145; H01L 2224/80006; H01L 2224/80895; H01L 2224/80896; H01L 2924/1431; H01L 2924/14511

(57) ABSTRACT

A three-dimensional memory device includes a pair of alternating stacks of insulating layers and electrically conductive layers that are laterally spaced from each other by a lateral isolation trench that laterally extends along a first horizontal direction, memory opening fill structures including a respective vertical stack of memory elements and a vertical semiconductor channel, support pillar structures extending in rows along the first horizontal direction with a uniform pitch, and a lateral isolation trench fill structure located in the lateral isolation trench and having a variable width along a second horizontal direction, the variable width having a periodic undulation along the first horizontal direction with a periodicity that is the same as the uniform pitch.

### RELATED APPLICATIONS

This application is a continuation-in-part (CIP) application of U.S. patent application Ser. No. 18/477,907 filed on Sep. 29, 2023, the entire contents of which are incorporated herein by reference.

### FIELD

The present disclosure relates generally to the field of semiconductor devices, and particularly to a three-dimensional memory device including laterally undulating isolation trenches and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: a pair of alternating stacks, wherein each alternating stack within the pair of alternating stacks comprises insulating layers and electrically conductive layers that are interlaced along a vertical direction, and wherein the pair of alternating stacks are laterally spaced from each other by a lateral isolation trench that laterally extends along a first horizontal direction; memory openings vertically extending through a respective one of the pair of alternating stacks; memory opening fill structures located in a respective one of the memory openings and comprising a respective vertical semiconductor channel and a respective vertical stack of memory elements; rows of support pillar structures, wherein each row of the support pillar structures laterally extends along the first horizontal direction and vertically extends through a respective one of the pair of alternating stacks; and a lateral isolation trench fill structure having a variable width along a second horizontal direction and located in the lateral isolation trench, the lateral isolation trench fill structure comprising: a plurality of neck portions having a pair of straight sidewalls which extend along the first horizontal direction and having a first width along the second horizontal direction that is perpendicular to the first horizontal direction; and a plurality of laterally bulging portions having a second width along the second horizontal direction that is greater than the first width, wherein the plurality of laterally bulging portions is interlaced with the plurality of neck portions along the first horizontal direction.

According to another aspect of the present disclosure, a method of forming a three-dimensional memory device is provided. The method comprises: forming a vertically alternating sequence of continuous insulating layers and continuous sacrificial material layers over a substrate; forming memory openings through the vertically alternating sequence; forming memory opening fill structures in the memory openings, wherein each of the memory opening fill structures comprises a respective vertical stack of memory elements and a vertical semiconductor channel; forming rows of support pillar structures, wherein each row of the support pillar structures is periodically arranged along a first horizontal direction with a uniform pitch and vertically extends through the vertically alternating sequence; forming a lateral isolation trench that generally extends along the first horizontal direction through the vertically alternating sequence, wherein the lateral isolation trench has a variable width along a second horizontal direction, the variable width having a periodic undulation along the first horizontal direction with a periodicity that is the same as the uniform pitch; and replacing remaining portions of the continuous sacrificial material layers with electrically conductive layers to form a pair of alternating stacks of insulating layers and electrically conductive layers that are separated by the lateral isolation trench along the second horizontal direction.

According to an aspect of the present disclosure, a three-dimensional memory device comprises: a pair of alternating stacks, wherein each alternating stack within the pair of alternating stacks comprises insulating layers and electrically conductive layers that are interlaced along a vertical direction, and wherein the pair of alternating stacks are laterally spaced from each other by a lateral isolation trench that laterally extends along a first horizontal direction; memory openings vertically extending through a respective one of the pair of alternating stacks; memory opening fill structures located in a respective one of the memory openings and comprising a respective vertical stack of memory elements and a respective vertical semiconductor channel; and a lateral isolation trench fill structure located in the lateral isolation trench and comprising a plurality of neck portions having a pair of straight sidewalls which extend along the first horizontal direction and having a first width along a second horizontal direction that is perpendicular to the first horizontal direction; and a plurality of laterally bulging portions having a second width along the second horizontal direction that is greater than the first width, wherein the plurality of laterally bulging portions is interlaced with the plurality of neck portions along the first horizontal direction.

According to an aspect of the present disclosure, a three-dimensional memory device comprises: an alternating stack of insulating layers and electrically conductive layers; memory openings vertically extending through the alternating stack in a memory array region; memory opening fill structures located in a respective one of the memory openings and comprising a respective vertical stack of memory elements and a respective vertical semiconductor channel; layer contact via structures contacting a respective one of the electrically conductive layers and located in a contact region that is laterally offset from the memory array region along the first horizontal direction; a lateral isolation trench fill structure located adjacent to the alternating stack, the lateral isolation trench fill structure comprising a plurality of narrower neck portions and wider laterally bulging portions which alternate with the neck portions along the first horizontal direction and which are located in a transition region between the memory array region and the contact region along the first horizontal direction; first-type support pillar structures each vertically extending through the alternating stack in the contact region and consisting essentially of at least one dielectric material; and second-type support pillar structures each vertically extending through the alternating stack in the transition region and comprising a respective set of dielectric material layers and a respective semiconductor material layer.

According to another aspect of the present disclosure, a method of forming a three-dimensional memory device is provided, which comprises: forming a vertically alternating sequence of continuous insulating layers and continuous sacrificial material layers over a substrate; forming memory openings through the vertically alternating sequence; forming memory opening fill structures in the memory openings, wherein each of the memory opening fill structures comprises a respective vertical semiconductor channel and a respective vertical stack of memory elements; forming a lateral isolation trench that generally extends along a first horizontal direction through the vertically alternating sequence, wherein the lateral isolation trench comprises a plurality of neck portions having a first width along a second horizontal direction that is perpendicular to the first horizontal direction between a respective pair of straight surface segments that extend along the first horizontal direction, and further comprises a plurality of laterally bulging portions having a second width along the second horizontal direction that is greater than the first width, wherein the plurality of laterally bulging portions is interlaced with the plurality of neck portions along the first horizontal direction; and replacing remaining portions of the continuous sacrificial material layers with electrically conductive layers, to form a pair of alternating stacks of insulating layers and electrically conductive layers that are separated by the lateral isolation trench along the second horizontal direction.

### BRIEF DESCRIPTION OF THE DRAWINGS

FIG. 1 is a schematic vertical cross-sectional view of a first exemplary structure for forming a memory die after formation of a stopper insulating layer, source-level material layers, and an alternating stack of insulating layers and sacrificial material layers over a carrier substrate according to an embodiment of the present disclosure.

FIG. 2 is a schematic vertical cross-sectional view of the first exemplary structure after formation of stepped surfaces and a stepped dielectric material portion according to an embodiment of the present disclosure.

FIG. 3A is a schematic vertical cross-sectional view of the first exemplary structure after forming memory openings and support openings according to an embodiment of the present disclosure. FIG. 3B is a top-down view of the first exemplary structure of FIG. 3A. The vertical plane A-A′ is the cut plane of the vertical cross-sectional view of FIG. 3A.

FIG. 4 is a vertical cross-sectional view of the first exemplary structure after formation of sacrificial opening fill structures according to an embodiment of the present disclosure.

FIG. 5 is a vertical cross-sectional view of the first exemplary structure after removal of first-type sacrificial support opening fill structures according to an embodiment of the present disclosure.

FIG. 6 is a vertical cross-sectional view of the first exemplary structure after formation of dielectric support pillar structures according to an embodiment of the present disclosure.

FIG. 7 is a vertical cross-sectional view of the first exemplary structure after removal of the memory opening fill structures and second-type sacrificial support opening fill structures according to an embodiment of the present disclosure.

FIGS. 8A-8D are sequential vertical cross-sectional views of a memory opening during formation of a memory opening fill structure according to an embodiments of the present disclosure.

FIG. 9A is a vertical cross-sectional view of the first exemplary structure after formation of memory opening fill structures and composite support pillar structures according to an embodiment of the present disclosure. FIG. 9B is a top-down view of the first exemplary structure of FIG. 9A. The vertical plane A-A′ is the cut plane of the vertical cross-sectional view of FIG. 9A.

FIG. 10A is a vertical cross-sectional view of the first exemplary structure after formation of lateral isolation trenches according to an embodiment of the present disclosure. FIG. 10B is a top-down view of the first exemplary structure of FIG. 10A. The vertical plane A-A′ is the cut plane of the vertical cross-sectional view of FIG. 10A.

FIGS. 11A-11F are top-down views alternative configurations of the first exemplary structure at the processing steps of FIGS. 10A and 10B according to an embodiment of the present disclosure.

FIG. 12 is a vertical cross-sectional view of the first exemplary structure after formation of a source-level cavity according to an embodiment of the present disclosure.

FIG. 13 is a vertical cross-sectional view of the first exemplary structure after formation of a source contact layer according to an embodiment of the present disclosure.

FIG. 14 is a vertical cross-sectional view of the first exemplary structure after formation of laterally-extending cavities according to an embodiment of the present disclosure.

FIGS. 15A-15D are sequential vertical cross-sectional views of a region of the first exemplary structure during formation of electrically conductive layers according to an embodiment of the present disclosure.

FIG. 16 is a vertical cross-sectional view of the first exemplary structure after formation of electrically conductive layers according to an embodiment of the present disclosure.

FIG. 17A is a vertical cross-sectional view of the first exemplary structure after formation of insulating spacers according to an embodiment of the present disclosure. FIG. 17B is a top-down view of the first exemplary structure of FIG. 17A. The vertical plane A-A′ is the cut plane of the vertical cross-sectional view of FIG. 17A. FIG. 17C is a vertical cross-sectional view of the first exemplary structure along the vertical plane C-C′. FIG. 17D is a vertical cross-sectional view of the first exemplary structure along the vertical plane D-D′. FIG. 17E is a vertical cross-sectional view of the first exemplary structure along the vertical plane E-E′.

FIGS. 18A-18C are vertical cross-sectional view of the first exemplary structure after formation of a first metallic barrier liner according to an embodiment of the present disclosure. The cut plane of FIG. 18A corresponds to the vertical plane C-C′ of FIG. 17B. The cut plane of FIG. 18B corresponds to the vertical plane D-D′ of FIG. 17B. The cut plane of FIG. 18C corresponds to the vertical plane E-E′ of FIG. 17B.

FIGS. 19A-19C are vertical cross-sectional view of the first exemplary structure after formation of a first metal layer according to an embodiment of the present disclosure. The cut plane of FIG. 19A corresponds to the vertical plane C-C′ of FIG. 17B. The cut plane of FIG. 19B corresponds to the vertical plane D-D′ of FIG. 17B. The cut plane of FIG. 19C corresponds to the vertical plane E-E′ of FIG. 17B.

FIGS. 20A-20C are vertical cross-sectional view of the first exemplary structure after formation of a second metallic barrier liner according to an embodiment of the present disclosure. The cut plane of FIG. 20A corresponds to the vertical plane C-C′ of FIG. 17B. The cut plane of FIG. 20B corresponds to the vertical plane D-D′ of FIG. 17B. The cut plane of FIG. 20C corresponds to the vertical plane E-E′ of FIG. 17B.

FIGS. 21A-21C are vertical cross-sectional view of the first exemplary structure after formation of metal portions according to an embodiment of the present disclosure. The cut plane of FIG. 21A corresponds to the vertical plane C-C′ of FIG. 17B. The cut plane of FIG. 21B corresponds to the vertical plane D-D′ of FIG. 17B. The cut plane of FIG. 21C corresponds to the vertical plane E-E′ of FIG. 17B.

FIGS. 22A-22C are vertical cross-sectional view of the first exemplary structure after formation of a second metal layer according to an embodiment of the present disclosure. The cut plane of FIG. 22A corresponds to the vertical plane C-C′ of FIG. 17B. The cut plane of FIG. 22B corresponds to the vertical plane D-D′ of FIG. 17B. The cut plane of FIG. 22C corresponds to the vertical plane E-E′ of FIG. 17B.

FIG. 23A is a vertical cross-sectional view of the first exemplary structure after formation of isolation trench fill structures according to an embodiment of the present disclosure. FIG. 23B is a top-down view of the first exemplary structure of FIG. 23A. The vertical plane A-A′ is the cut plane of the vertical cross-sectional view of FIG. 23A. FIG. 23C is a vertical cross-sectional view of the first exemplary structure along the vertical plane C-C′. FIG. 23D is a vertical cross-sectional view of the first exemplary structure along the vertical plane D-D′. FIG. 23E is a vertical cross-sectional view of the first exemplary structure along the vertical plane E-E′.

FIGS. 24A-24F are top-down views alternative configurations of the first exemplary structure at the processing steps of FIGS. 23A and 23B according to an embodiment of the present disclosure.

FIG. 25A is a vertical cross-sectional view of the first exemplary structure after formation of contact via structures according to an embodiment of the present disclosure. FIG. 25B is a top-down view of the first exemplary structure of FIG. 25A. The vertical plane A-A′ is the cut plane of the vertical cross-sectional view of FIG. 25A.

FIG. 26A is a vertical cross-sectional view of the first exemplary structure after formation of bit lines and bit-line-level metal lines according to an embodiment of the present disclosure. FIG. 26B is a top-down view of the first exemplary structure of FIG. 26A. The vertical plane A-A′ is the cut plane of the vertical cross-sectional view of FIG. 26A.

FIG. 27 is a vertical cross-sectional view of the first exemplary structure after formation of a memory die according to an embodiment of the present disclosure.

FIG. 28 is a vertical cross-sectional view of a logic die according to an embodiment of the present disclosure.

FIG. 29 is a vertical cross-sectional view of the first exemplary structure after formation of a bonded assembly of the memory die and the logic die according to an embodiment of the present disclosure.

FIG. 30 is a vertical cross-sectional view of the first exemplary structure after removal of a carrier substrate from the memory die according to an embodiment of the present disclosure.

FIG. 31 is a vertical cross-sectional view of an alternative configuration of the first exemplary structure after formation of an alternating stack of insulating layers and sacrificial material layers according to an embodiment of the present disclosure.

FIG. 32 is a vertical cross-sectional view of the alternative configuration of the first exemplary structure after formation of memory-side metal interconnect structures and memory-side bonding pads according to an embodiment of the present disclosure.

FIG. 33A is a vertical cross-sectional view of a second exemplary structure after formation of memory opening fill structures and support pillar structures according to an embodiment of the present disclosure. FIG. 33B is a top-down view of the first exemplary structure of FIG. 33A. The vertical plane A-A′ is the cut plane of the vertical cross-sectional view of FIG. 33A.

FIG. 34A is a vertical cross-sectional view of the second exemplary structure after formation of a contact-level dielectric layer and lateral isolation trenches according to an embodiment of the present disclosure. FIG. 34B is a top-down view of the first exemplary structure of FIG. 34A. The vertical plane A-A′ is the cut plane of the vertical cross-sectional view of FIG. 34A.

FIG. 35 is a vertical cross-sectional view of the second exemplary structure after formation of a source layer according to an embodiment of the present disclosure.

FIG. 36 is a vertical cross-sectional view of the second exemplary structure after replacement of sacrificial material layers with electrically conductive layers according to an embodiment of the present disclosure.

FIG. 37A is a vertical cross-sectional view of the second exemplary structure after formation of insulating spacers according to an embodiment of the present disclosure. FIG. 37B is a top-down view of the first exemplary structure of FIG. 37A. The vertical plane A-A′ is the cut plane of the vertical cross-sectional view of FIG. 37A.

FIG. 38A is a vertical cross-sectional view of the second exemplary structure after formation of conductive fill structures in the lateral isolation trenches according to an embodiment of the present disclosure. FIG. 38B is a top-down view of the first exemplary structure of FIG. 38A. The vertical plane A-A′ is the cut plane of the vertical cross-sectional view of FIG. 38A.

FIG. 39A is a vertical cross-sectional view of the second exemplary structure after formation of various contact via structures according to an embodiment of the present disclosure. FIG. 39B is a top-down view of the first exemplary structure of FIG. 39A. The vertical plane A-A′ is the cut plane of the vertical cross-sectional view of FIG. 39A.

### DETAILED DESCRIPTION

As discussed above, the present disclosure is directed to a three-dimensional memory device including laterally undulated isolation trench fill structures for providing enhanced structural support and methods for manufacturing the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

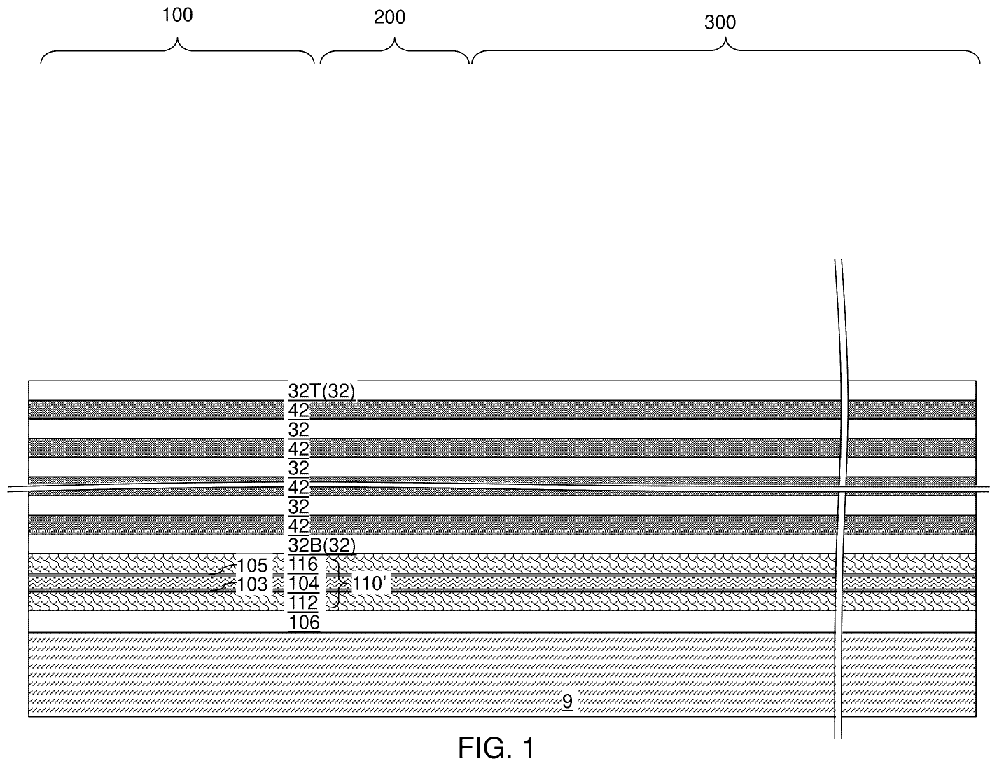

Referring to FIG. 1, a first exemplary structure according to an embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An insulating material layer can be formed on a top surface of the carrier substrate 9. The insulating material layer can be subsequently employed as a stopping material layer for a process that removes the carrier substrate 9, and is herein referred to as a stopper insulating layer 106, or as a backside pad dielectric layer. If a polishing process such as a chemical mechanical polishing process is employed to subsequently remove the carrier substrate 9, the stopper insulating layer 106 may be subsequently employed as a polishing stopper material layer. If an etch process such as a wet etch process is employed to subsequently remove the carrier substrate 9, the stopper insulating layer 106 may be subsequently employed as an etch stop material layer. In one embodiment, the stopper insulating layer 106 comprises a dielectric material such as undoped silicate glass, a doped silicate glass, or silicon nitride. The thickness of the stopper insulating layer 106 may be in a range from 50 nm to 600 nm, such as from 100 nm to 300 nm, although lesser and greater thicknesses may also be employed.

In-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

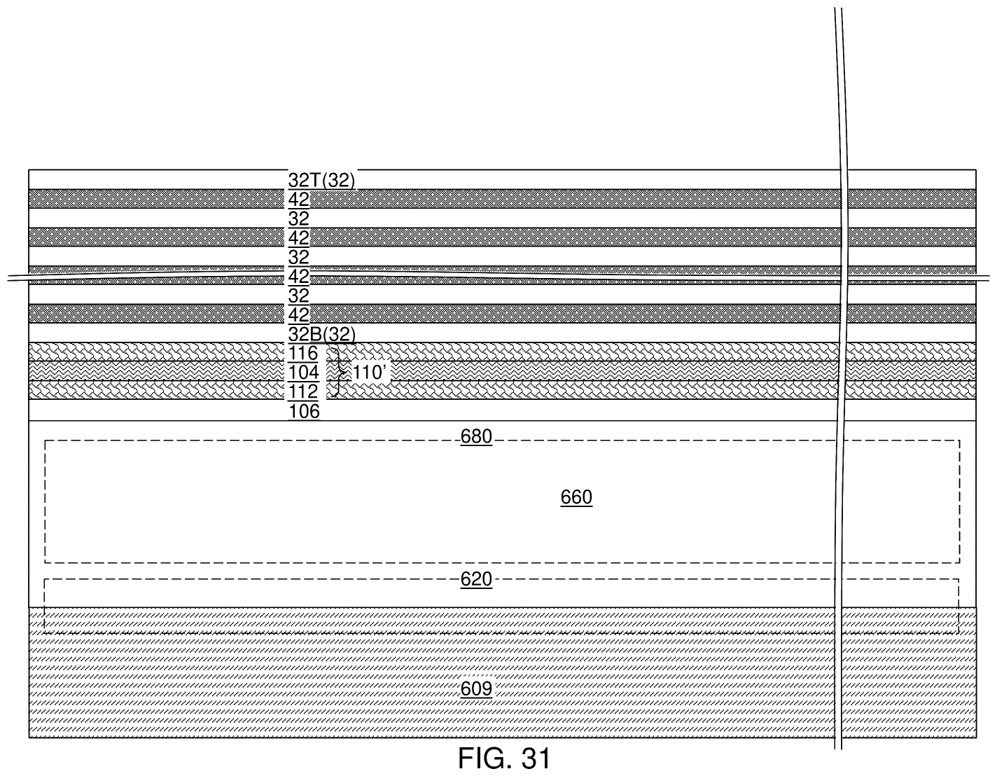

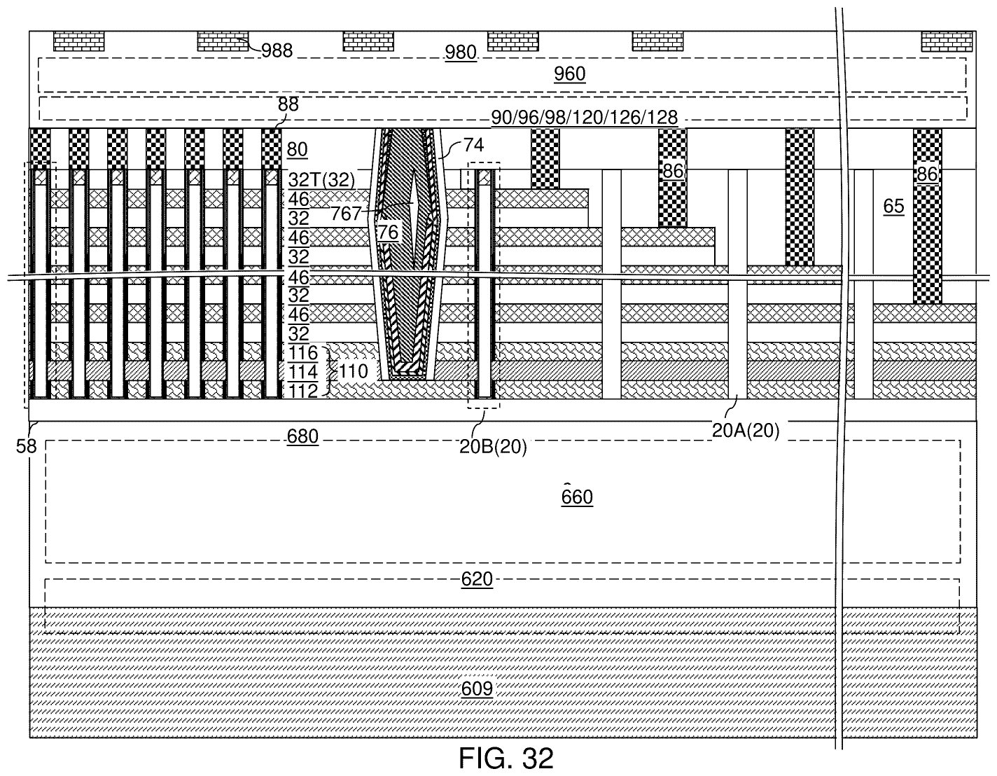

An alternating stack of first material layers and second material layers can be formed over the in-process source-level material layers 110′. The alternating sequence comprises a vertically alternating stack in which the first material layers and the second material layers are interlaced along the vertical direction. In an alternative embodiment, the in-process source-level material layers 110′ and the stopper insulating layer 106 may be omitted, and the alternating stack is formed directly on a surface of the carrier substrate 9. In another alternative embodiment describe below with respect to FIGS. 31 and 32, a peripheral circuit is formed on the same substrate as the alternating stack prior to formation of the alternating stack. For example, the peripheral circuit may comprise word line driver regions, bit line driver regions, sense amplifier regions, input/output buffer regions, etc. In this alternative embodiment, a separate logic die containing the peripheral circuit may be omitted. In this alternative embodiment, the alternating stack may be deposited on the in-process source-level material layers 110′ or the in-process source-level material layers 110′ may be omitted, and the alternating stack may be deposited on the stopper insulating layer 106.

In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9 (e.g., over the in-process source-level material layers 110′, if present). The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B. Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed. The first exemplary structure further comprises a transition region 200 in which support openings and composite support pillar structures including multiple materials are to be subsequently formed. The insulating layers 32 continuously extend across the memory array region 100 and the contact region 300 without a pattern, and may be referred to as continuous insulating layers 32. The sacrificial material layers 42 continuously extend across the memory array region 100 and the contact region 300 without a pattern, and may be referred to as continuous sacrificial material layers 42. Thus, a vertically alternating sequence of continuous insulating layers 32 and continuous sacrificial material layers 42 can be formed.

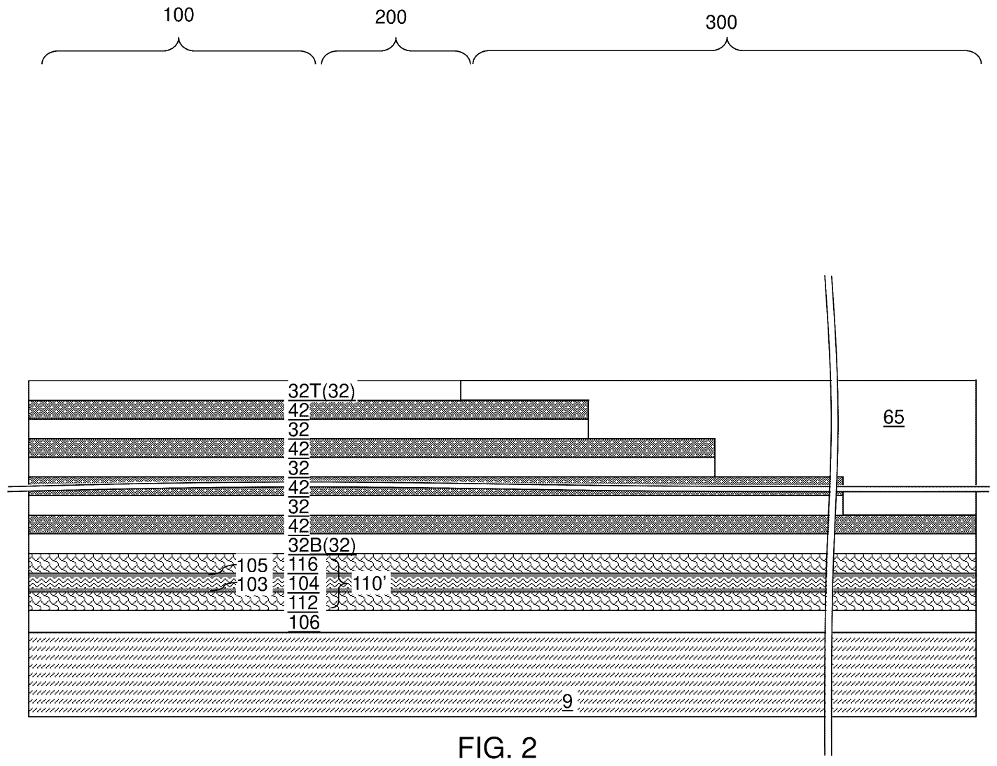

Referring to FIG. 2, stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65, which can be a retro-stepped dielectric material portion. As used herein, a “retro-stepped” element refers to an element that has stepped surfaces and a horizontal cross-sectional area that increases monotonically as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

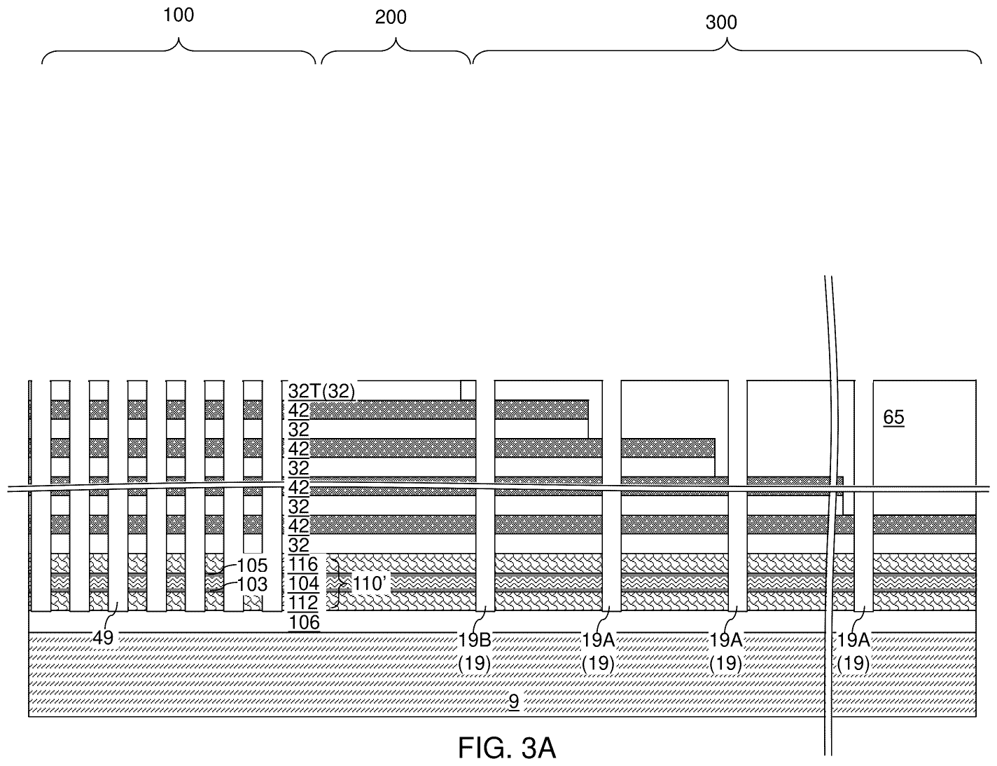

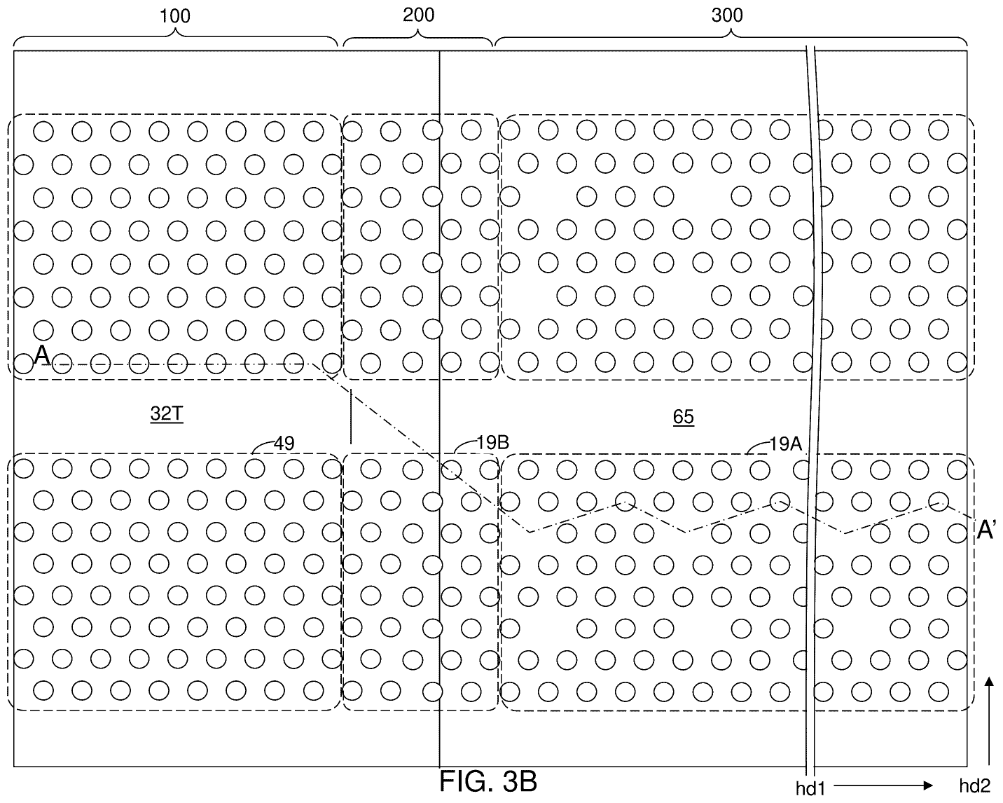

Referring to FIGS. 3A and 3B, an etch mask layer (not shown) can be formed over the alternating stack (32, 42), and can be lithographically patterned to form openings therein. An anisotropic etch process can be performed to transfer the pattern of the openings in the etch mask layer through the alternating stack (32, 42) to form memory openings 49 and support openings 19. The memory openings 49 can be formed through the alternating stack (32, 42) in the memory array region 100. Each of the memory openings 49 can vertically extend through the alternating stack (32, 42) and into the in-process source-level material layers 110′ In one embodiment, bottom surfaces of the memory openings 49 may be formed within the lower source-level semiconductor layer 112 or at an interface between the lower source-level semiconductor layer and the stopper insulating layer 106. The support openings 19 can be formed through the alternating stack (32, 42) and the stepped dielectric material portion 65 in the contact region 300 and the transition region 200. In one embodiment, the support openings 19 may have the same depth as the memory openings 49. The support openings 19 may comprise first-type support openings 19A that are formed in the contact region 300, and second-type support openings 19B that are formed in the transition region 200.

In one embodiment, the memory array region 100 may be laterally spaced apart from the contact region 300 along a first horizontal direction hd1 by the transition region 200. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2 by strip regions that are free of any opening (49, 19). Likewise, multiple clusters of first-type support openings 19A may be formed in the contact region 300 such that the clusters of first-type support openings 19A may be laterally spaced apart along the second horizontal direction hd2 by the strip regions that are free of any opening (49, 19). Further, multiple clusters of second-type support openings 19B may be formed in the transition region such that the clusters of second-type support openings 19B may be laterally spaced apart along the second horizontal direction hd2 by the strip regions that are free of any opening (49, 19).

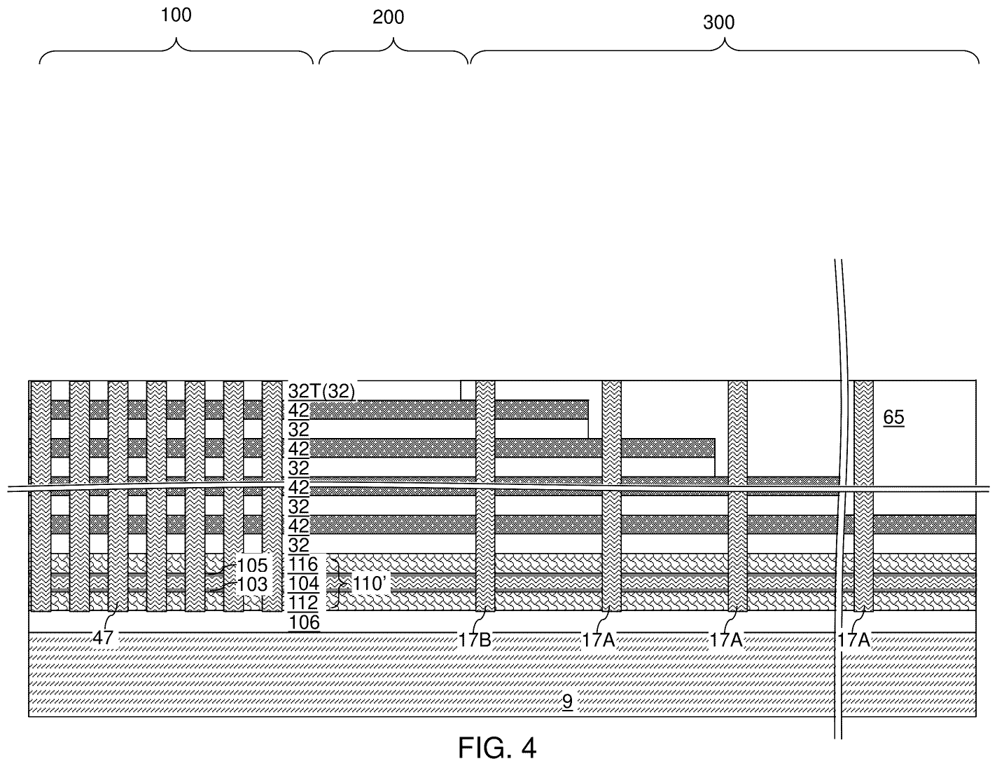

Referring to FIG. 4, a sacrificial fill material such as amorphous carbon or diamond-like carbon may be deposited in the memory openings 49 and the support openings 19 by a conformal deposition process. Excess portions of the sacrificial fill material can be removed from above the horizontal plane including the top surface of the topmost insulating layer 32T by a planarization process such as a recess etch process or a chemical mechanical polishing process. Remaining portions of the sacrificial fill material that fills the memory openings 49 constitute sacrificial memory opening fill structures 47. Remaining portions of the sacrificial fill material that fills the first-type support openings 19A constitute first-type sacrificial support opening fill structures 17A. Remaining portions of the sacrificial fill material that fills the second-type support openings 19B constitute second-type sacrificial support opening fill structures 17B.

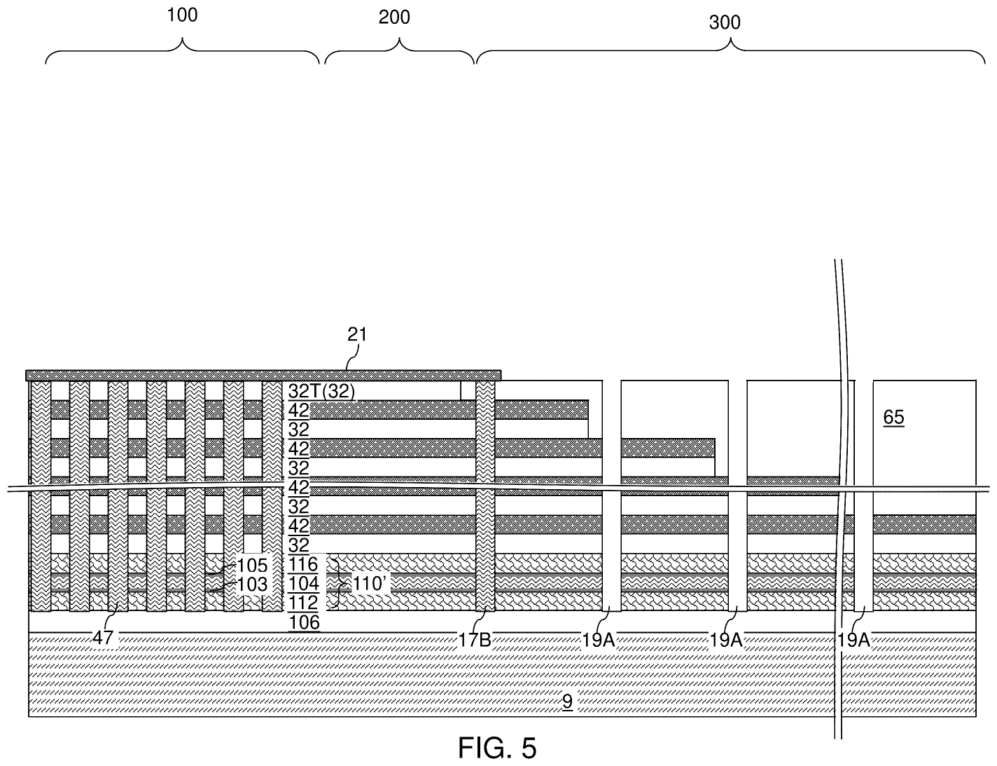

Referring to FIG. 5, a hard mask layer 21 can be applied over the first exemplary structure, and can be lithographically patterned to cover the memory array region 100 and the transition region 200 without covering the contact region 300. The hard mask layer 21 may comprise a dielectric material, such as silicon oxide or silicon nitride, and may have a thickness in a range from 10 nm to 50 nm, although lesser and greater thicknesses may also be employed. The first-type sacrificial support opening fill structures 17A can be removed selective to the materials of the hard mask layer 21, the alternating stack (32, 42) (i.e., the vertically alternating sequence (32, 42)) and the in-process source-level material layers 110′ by performing a selective removal process such as an ashing process. Cavities are formed in the volumes of the reopened first-type support openings 19A.

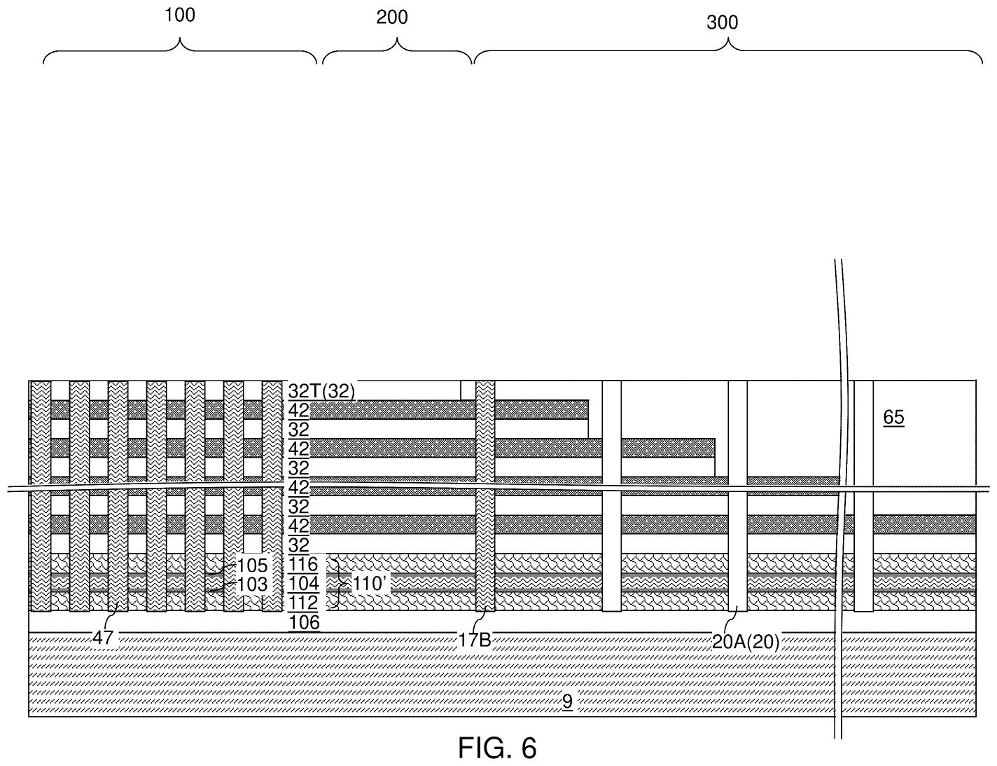

Referring to FIG. 6, a dielectric fill material, such as silicon oxide, can be deposited in the first-type support openings 19A. Excess portions of the dielectric fill material and the hard mask layer overlying the horizontal plane including the top surface of the stepped dielectric material portion 65 can be removed by a planarization process, such as a recess etch process or a chemical mechanical polishing process. Remaining portions of the dielectric fill material filling the first-type support openings 19A constitute first-type support pillar structures 20A. The first-type support pillar structures 20A vertically extend through the vertically alternating sequence (32, 42) in the contact region 300. In one embodiment, the first-type support pillar structures 20A consist essentially of at least one dielectric material, such as silicon oxide.

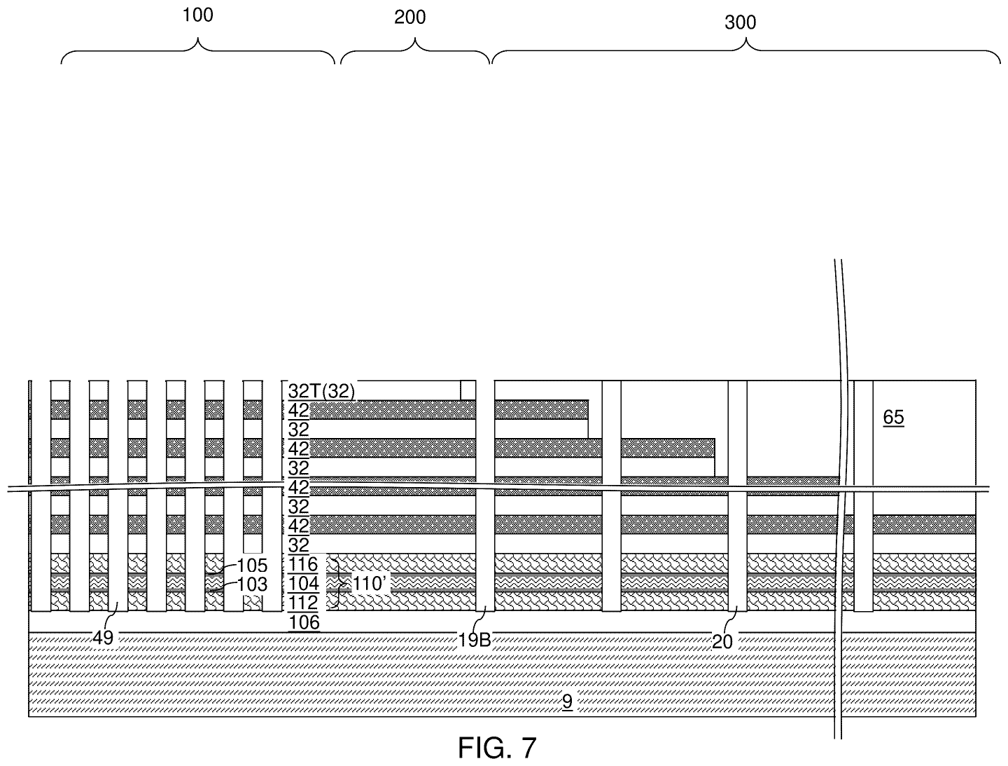

Referring to FIG. 7, the sacrificial memory opening fill structures 47 and the second-type sacrificial support opening fill structures 17B can be removed selective to the materials of the alternating stack (32, 42) (i.e., the vertically alternating sequence (32, 42)), the first-type support pillar structures 20A, and the in-process source-level material layers 110′ by performing a selective removal process such as an ashing process. Cavities are formed in the volumes of the memory openings 49 and the second-type support openings 19B to reopen the memory openings 49 and the second-type support openings 19B.

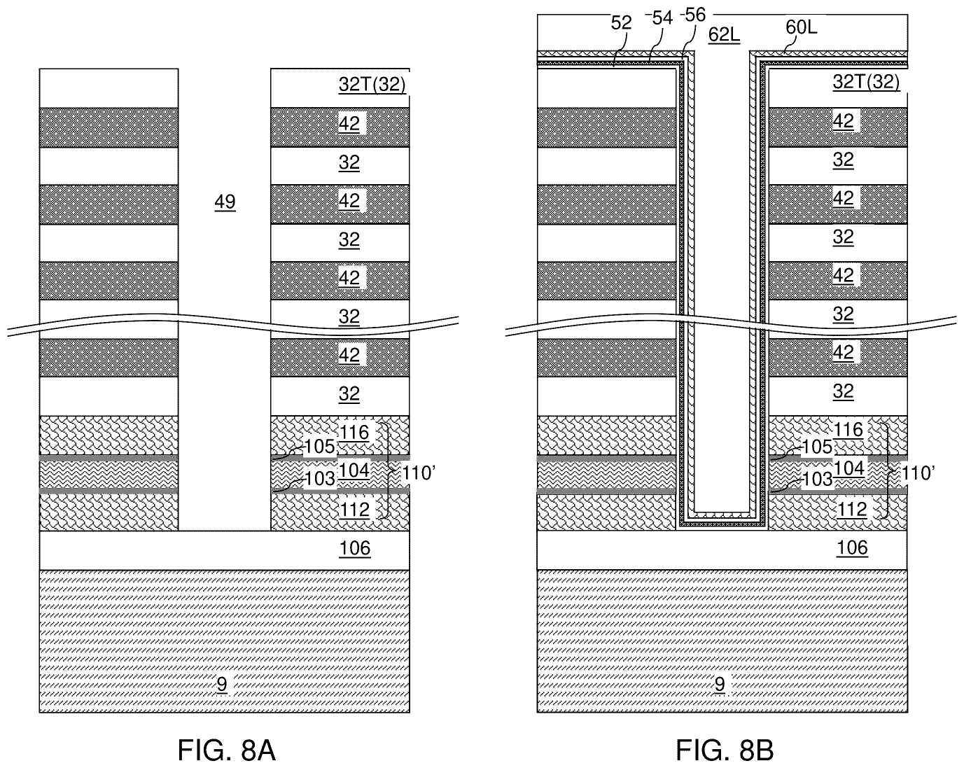

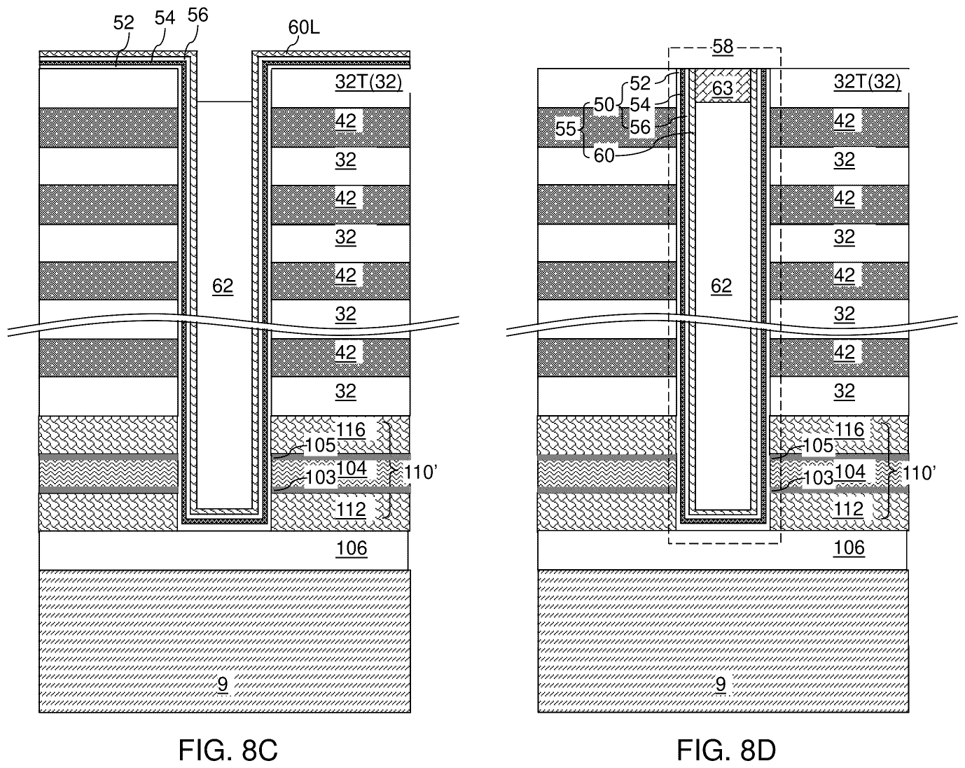

FIGS. 8A-8D are sequential vertical cross-sectional views of a memory opening 49 during formation of a memory opening fill structure 58 in each memory opening 49 and formation of a second-type support pillar structure 20B (e.g., dummy memory opening fill structure) in each second-type support opening 19B according to an embodiment of the present disclosure. The memory opening fill structure 58 may comprise a vertical NAND string.

Referring to FIG. 8A, a memory opening 49 is illustrated after the processing steps of FIG. 7.

Referring to FIG. 8B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 8C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 8D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be subsequently replaced at least partly with electrically conductive layers.

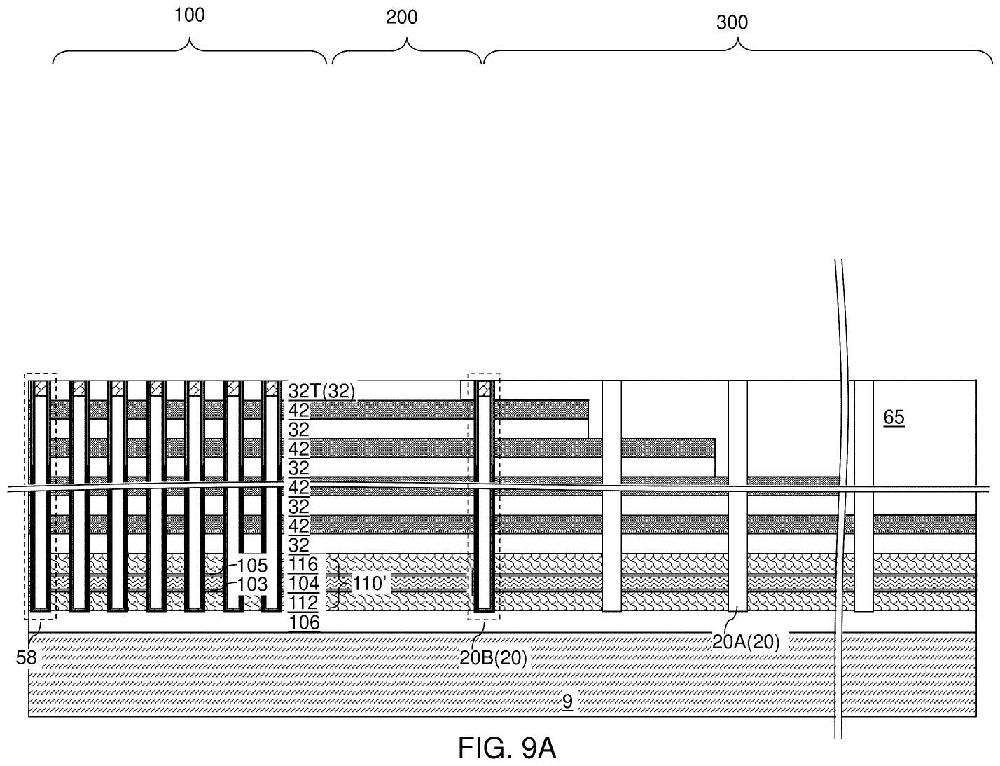

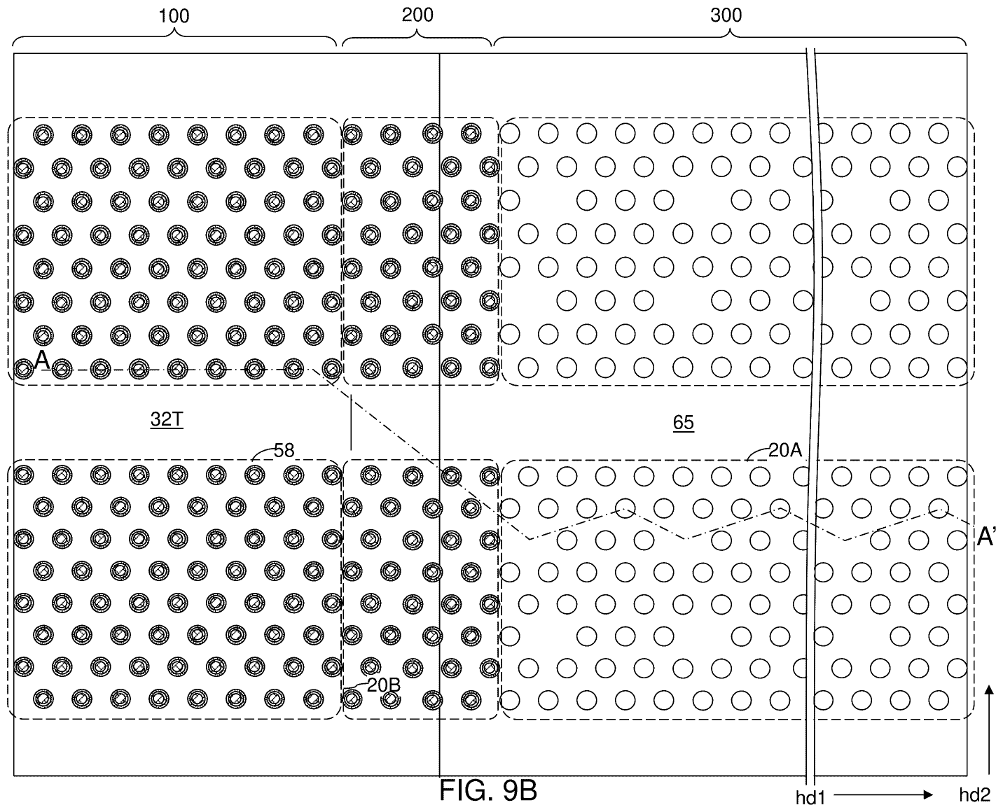

Referring to FIGS. 9A and 9B, the first exemplary structure is illustrated after formation of memory opening fill structures 58 within the memory openings 49 in the memory array region 100. Each of the memory opening fill structures 58 may comprise a memory film 50 and a vertical semiconductor channel 60. Each of the memory opening fill structures 58 comprises a respective vertical stack of memory elements, which may comprise portions of a respective memory material layer 54 located at levels of the sacrificial material layers 42. Second-type support pillar structures 20B are formed within the second-type support openings 19B that are located within the transition region 200. Each second-type support pillar structure 20B may have a same set of material portions as a memory opening fill structure 58.

Each of the second-type support pillar structures 20B comprises a respective set of dielectric material layers and a respective semiconductor material layer. Each set of dielectric material layers may have a same set of material layers as the memory film 50. In other words, each memory film 50 has a same set of materials as, and has a same thickness as, a set of dielectric material layers in a second-type support pillar structure 20B. Furthermore, each of the memory opening fill structures 58 comprises a vertical semiconductor channel 60 having a same material composition and a same thickness as a semiconductor material layer in a second-type support pillar structure 20B. Each semiconductor material layer may have the same material composition and the same thickness as a vertical semiconductor channel 60. Thus, the second-type support pillar structures 20B comprise dummy memory opening structures which have the same structure and composition as the memory opening fill structures 58, but which are not electrically connected to bit lines and which are not used to store data during operation of the memory device.

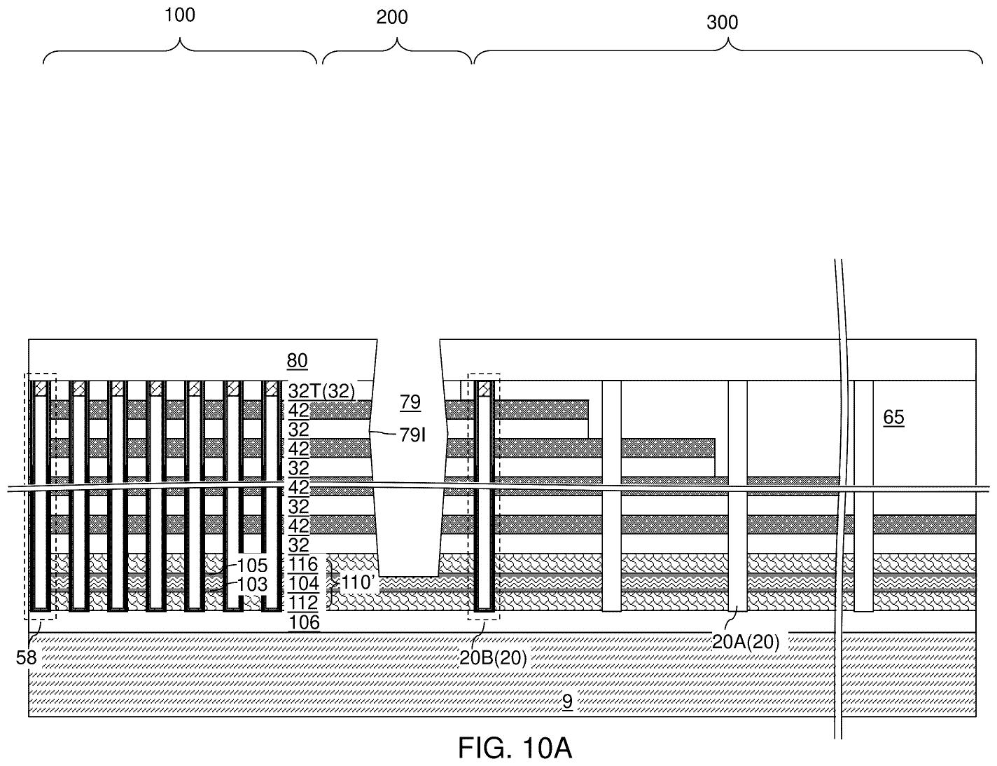

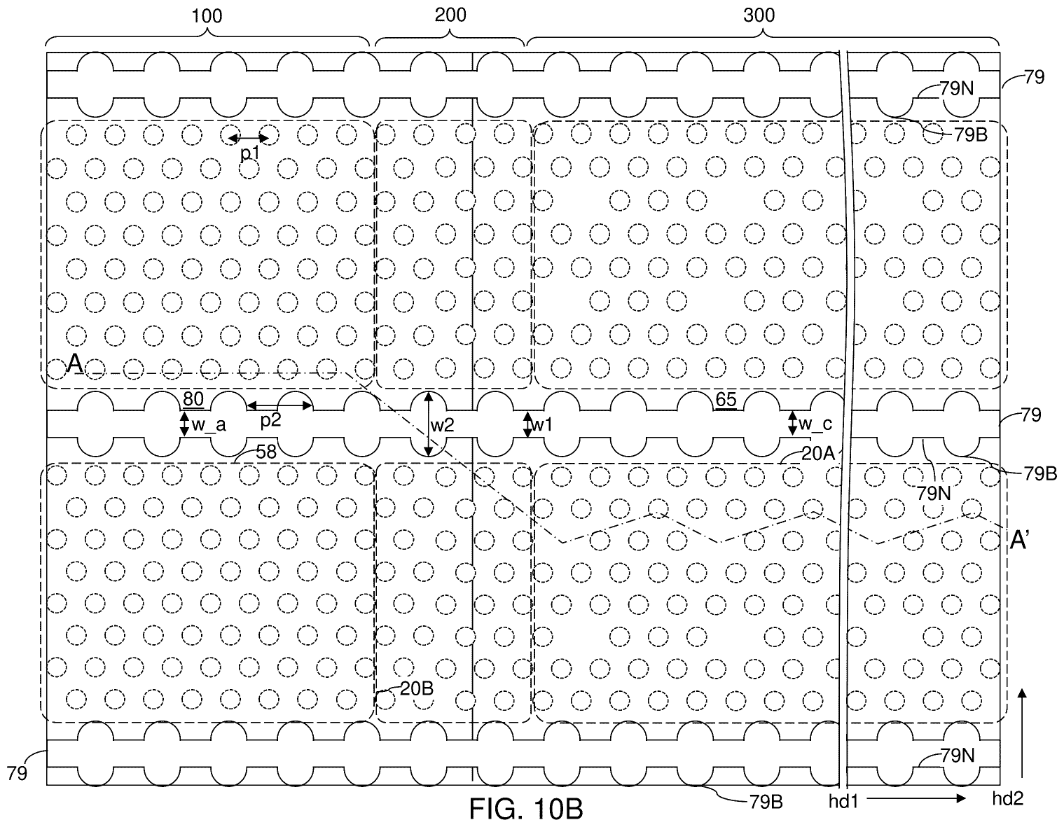

Referring to FIGS. 10A and 10B, a dielectric material, such as undoped silicate glass or a doped silicate glass, can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form various openings therein. The openings in the photoresist layer comprise elongated laterally-undulating openings that generally extend along the first horizontal direction hd1 in the strip regions located between neighboring clusters of memory opening fill structures 58 (e.g., between adjacent memory block areas).

An anisotropic etch process can be performed to transfer the pattern of the openings in the photoresist layer through the contact-level dielectric layer 80, the alternating stack (32, 42) (i.e., the vertically alternating sequence (32, 42)), and the stepped dielectric material portion 65, and into the in-process source-level material layers 110′ (if present). Lateral isolation trenches 79 can be formed through the alternating stack (32, 42), the stepped dielectric material portion 65, and the in-process source-level material layers 110′ (if present). The lateral isolation trenches 79 vertically extend through each layer within the alternating stack (32, 42) and into an upper portion of a semiconductor material layer (which may be located in the in-process source-level material layers 110′ or which may comprise a top portion of the carrier substrate 9 if the in-process source-level material layers 110′ are omitted). The lateral isolation trenches 79 laterally extend along the first horizontal direction hd1 (e.g., a word line direction). Each of the lateral isolation trenches 79 may comprise a respective pair of laterally-undulating lengthwise sidewalls that generally extend along the first horizontal direction hd1, have a respective width modulation along the second horizontal direction hd2, and vertically extend from the stopper insulating layer 106 to the top surface of the contact-level dielectric layer 80. In one embodiment, the lower source-level semiconductor layer 112 may be physically exposed underneath each lateral isolation trench 79.

In one embodiment, the lateral isolation trenches 79 may have a respective vertical cross-sectional profile including an inflection line 79I, at which a tapered surface segment of a continuously-extending sidewall is adjoined to a reverse-tapered surface segment of a continuously-extending sidewall. As used herein, a tapered surface segment refers to a surface segment at which a lateral dimension of a volume of an element increases with a vertical distance from an underlying substrate, and a reverse-tapered surface segment refers to a surface segment at which the lateral dimension of the volume of the element decreases with a vertical distance from the underlying substrate. Thus, in one embodiment, the sidewall of the lateral isolation trenches 79 may optionally have gradually changing slopes, and may optionally have a bowing vertical cross-sectional profile, with the largest width being at the inflection line 79I. The lateral isolation trenches 79 may have a maximum lateral width at along the second horizontal direction hd2 at the inflection line 79I. Each inflection line may laterally extend generally along the first horizontal direction hd1, and may have a respective periodic lateral undulation along the second horizontal direction hd2.

In summary, lateral isolation trenches 79 can be formed through the vertically alternating sequence (32, 42). Each lateral isolation trench 79 may comprise a pair of lengthwise sidewalls that generally extend along the first horizontal direction hd1. A vertical cross-sectional profile of the lateral isolation trench 79 in a vertical plane that is perpendicular to the first horizontal direction hd1 has a variable width that increases with a vertical distance from a horizontal plane including a bottommost surface of the vertically alternating sequence (32, 42) in a lower portion of the vertically alternating sequence (32, 42) to the horizontal plane including the inflection line 79I, and decreases with the vertical distance from the horizontal plane including the inflection line 79I located in an upper portion of the vertically alternating sequence (32, 42), as shown in FIG. 10A. In one embodiment, each lateral isolation trench 79 has a width modulation along the second horizontal direction hd2 that is perpendicular to the first horizontal direction hd1 as a function of a lateral distance along the first horizontal direction hd1, as shown in FIG. 10B.

In one embodiment shown in FIG. 10B, each lateral isolation trench 79 comprises a periodic laterally alternating sequence of neck portions (e.g., regions) 79N having a minimum width along the second horizontal direction hd2 and bulging portions (e.g., regions) 79B having a maximum width along the second horizontal direction hd2. In the embodiment shown in FIG. 10B, the neck portions 79N include horizontally-linear (i.e., straight) sidewalls and the bulging portions 79B include horizontally-convex sidewalls that bulge outward from the center of the lateral isolation trench 79. In this embodiment, each lateral isolation trench 79 comprises a pair of laterally-undulating lengthwise sidewalls that have lateral undulations at the bulging portions 79B; and each of the pair of laterally-undulating lengthwise sidewalls comprises a set of horizontally-convex and vertically-tapered surface segments in the bulging portions 79B that are adjoined at edges to horizontally-linear and vertically-tapered surface segments in the neck portions 79N.

In the embodiment shown in FIG. 10B, each lateral isolation trench 79 generally extends along a first horizontal direction hd1 through the vertically alternating sequence (32, 42). Each lateral isolation trench 79 comprises a plurality of neck portions 79N having a first width w1 along a second horizontal direction hd2 that is perpendicular to the first horizontal direction hd1 between a respective pair of straight surface segments that extend along the first horizontal direction hd1. Each lateral isolation trench 79 further comprises a plurality of laterally bulging portions 79B having a variable width along the second horizontal direction that is greater than the first width w1. The plurality of laterally bulging portions 79B are interlaced with the plurality of neck portions 79N along the first horizontal direction hd1. In one embodiment, the maximum of the variable width may be a second width w2 at the middle of the laterally bulging portions 79B.

In one embodiment shown in FIG. 10B, the memory opening fill structures 58 may be arranged in rows that laterally extend along the first horizontal direction hd1. Memory opening fill structures 58 located within each row of memory opening fill structures 58 may be arranged with a uniform pitch along the first horizontal direction hd1, which is herein referred to as a first pitch p1. In one embodiment, the plurality of laterally bulging portions 79B has a uniform pitch, which is herein referred to as a second pitch p2, along the first horizontal direction hd1. The second pitch p2 may be the same as the first pitch p1, or may be greater than the first pitch p1. Each of the plurality of laterally bulging portions 79B may be laterally bounded along the second horizontal direction hd2 by a pair of laterally convex surface segments that are laterally spaced from each other. As used herein, a laterally convex surface has a convex profile in a horizontal cross-sectional view. A laterally concave surface has a concave profile in a horizontal cross-sectional view.

In one embodiment, each of the laterally convex surface segments of the laterally-bulging portions 79B may be laterally bounded by concave surfaces of alternating stacks of insulating layers 32 and sacrificial material layers 42 in a horizontal cross-sectional view. The plurality of laterally bulging portions 79B are formed at least in the transition region 200, and may be formed in the memory array region 100 and/or in the contact region 300. In one embodiment, a first subset of the laterally bulging portions 79B may be located in the transition region 200, a second subset of the laterally bulging portions 79B may be located in the memory array region 100, and a third subset of the laterally bulging portions 79B may be located in the contact region 300.

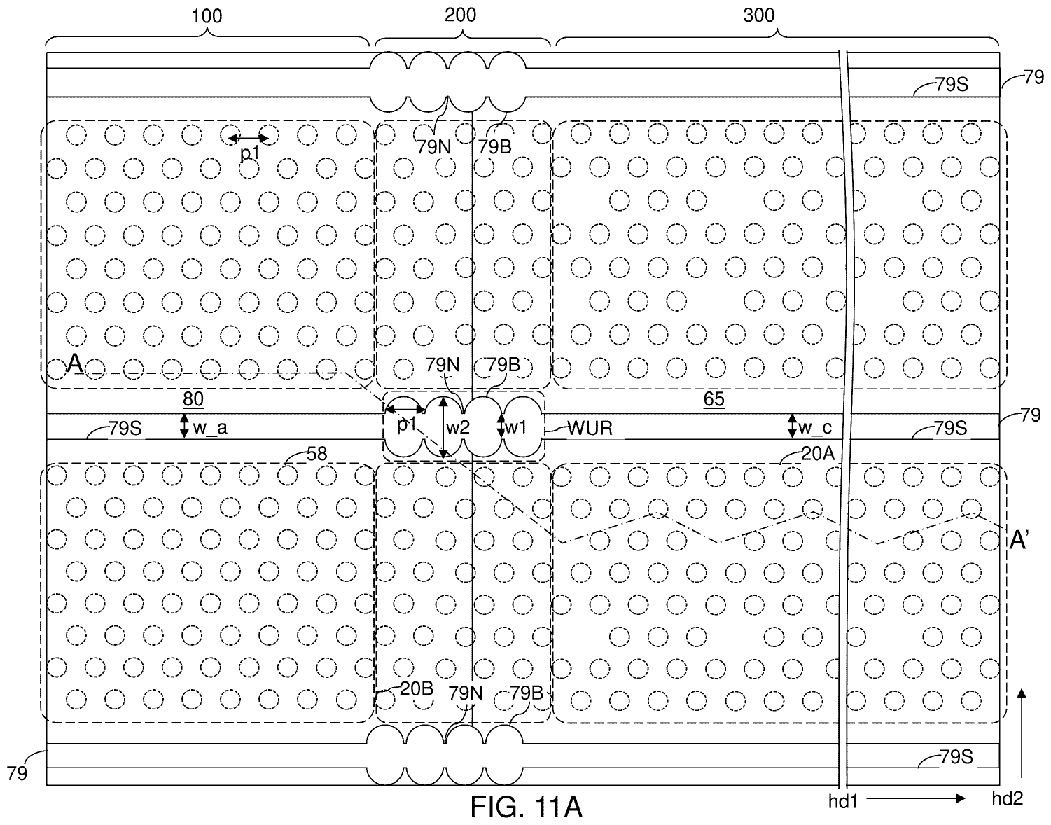

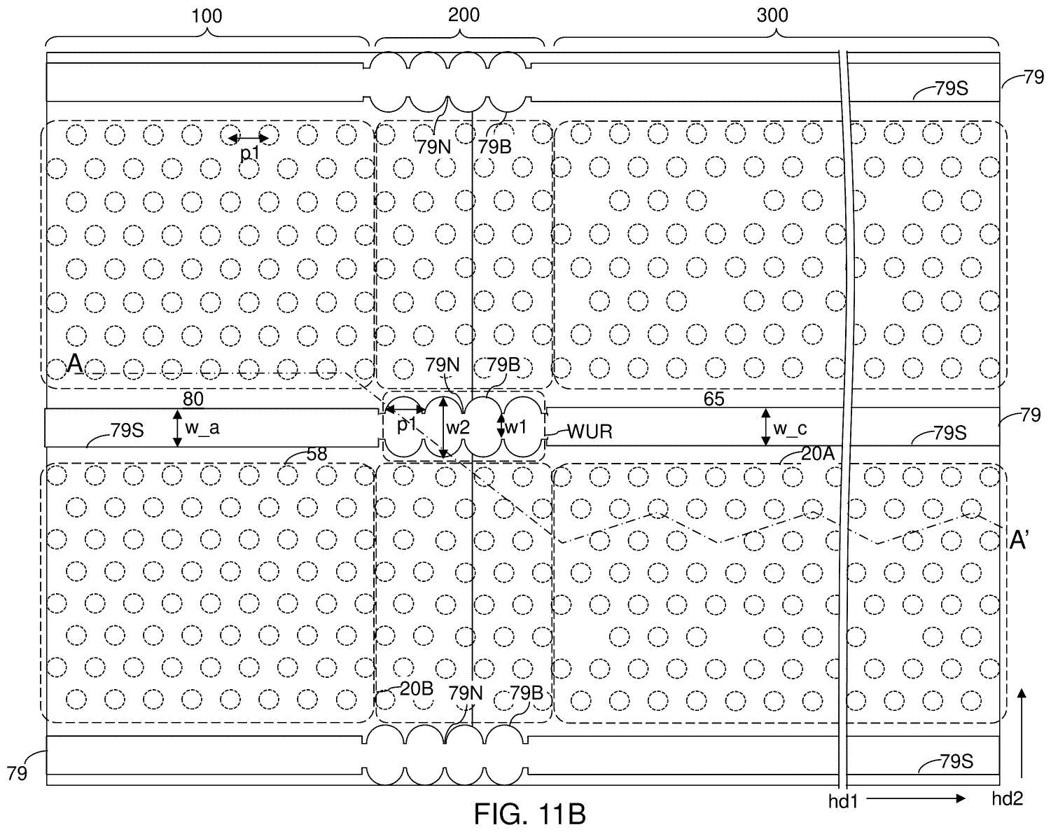

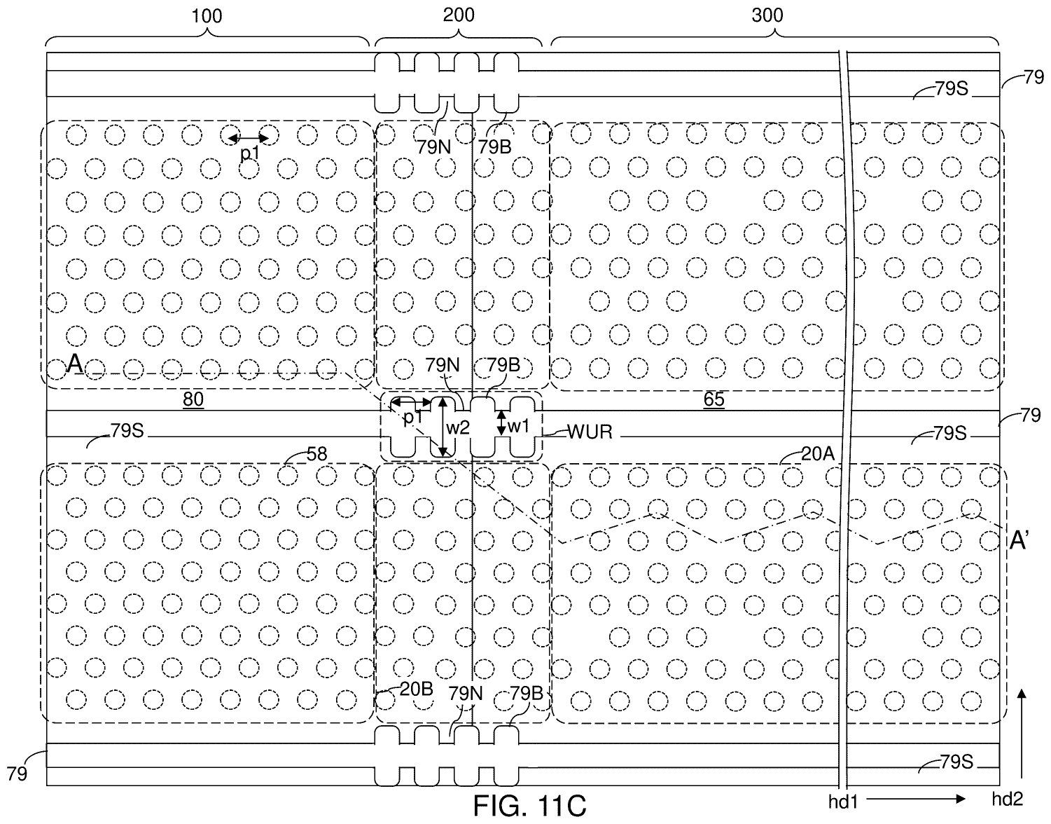

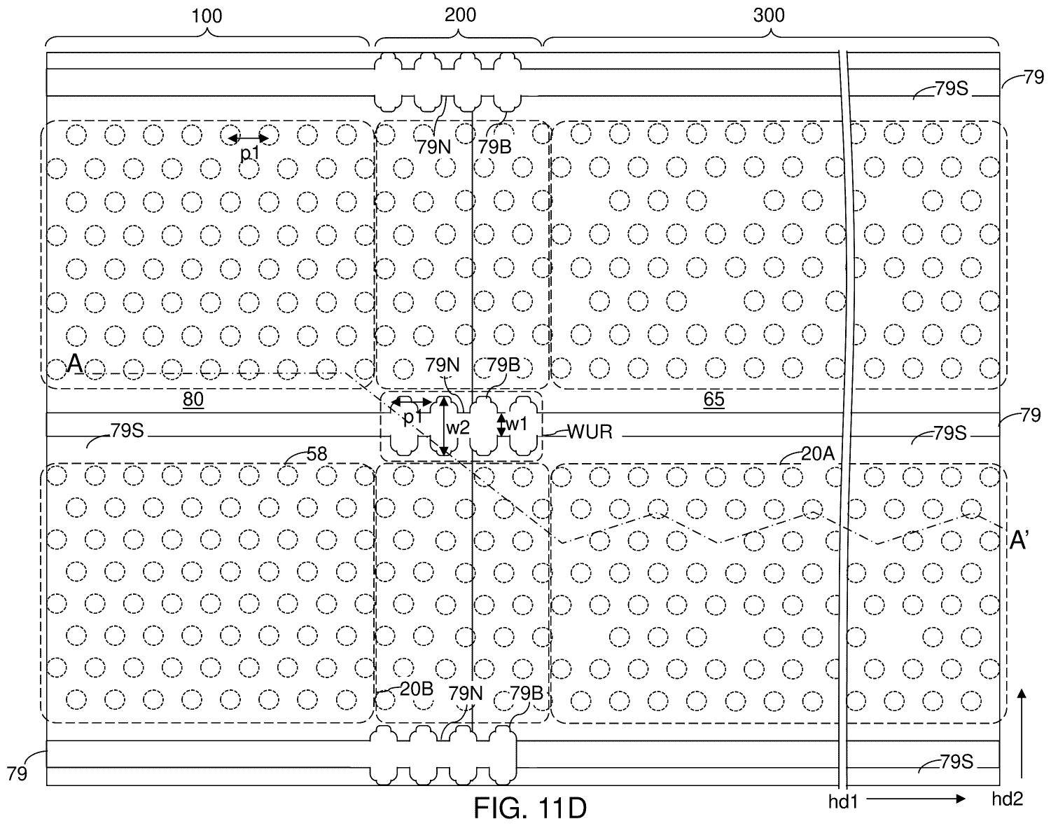

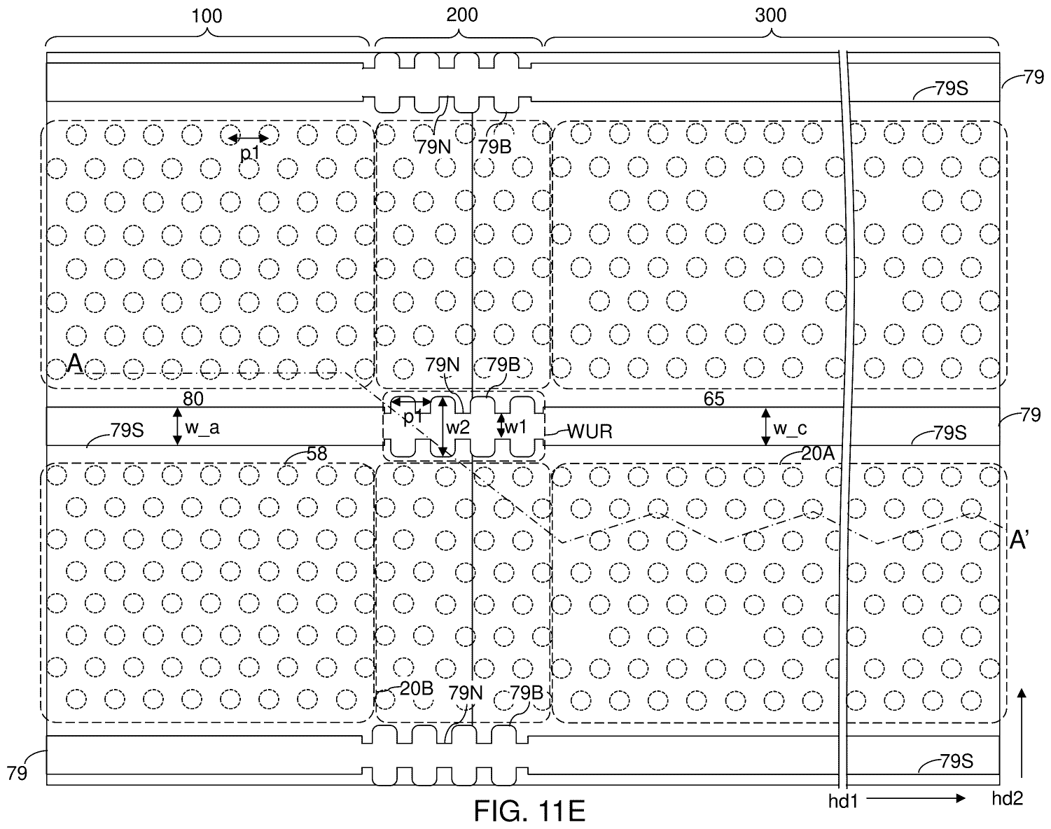

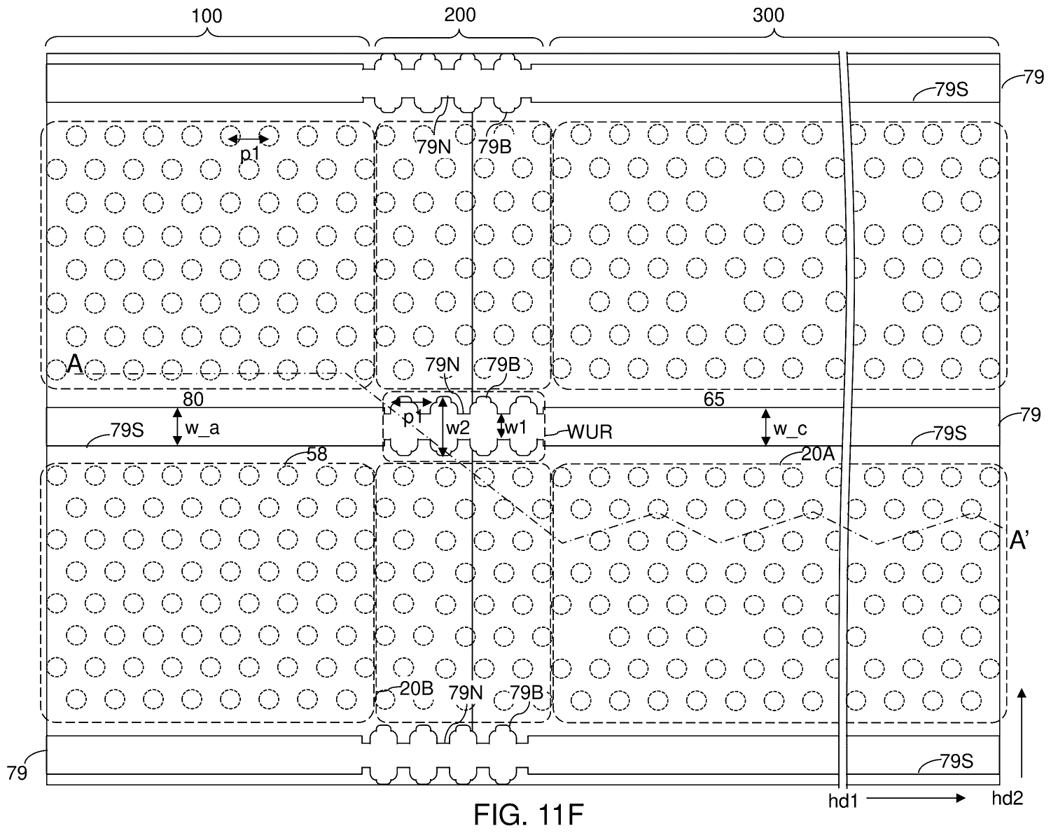

FIGS. 11A-11F are top-down views alternative configurations of the first exemplary structure at the processing steps of FIGS. 10A and 10B according to an embodiment of the present disclosure. In the alternative configurations illustrated in FIGS. 11A-11F, the laterally bulging portions 79B of the lateral isolation trenches 79 may be formed entirely within the transition region 200. In this case, the portion of each lateral isolation trench 79 having a lateral width undulation is referred to as a width undulation region WUR.

Referring to FIG. 11A, a first alternative configuration of the first exemplary structure is illustrated after the processing steps described with reference to FIGS. 10A and 10B. Each lateral isolation trench 79 comprises a plurality of neck portions 79N having a first width w1 along a second horizontal direction hd2 that is perpendicular to the first horizontal direction hd1 and a plurality of laterally bulging portions 79B having a variable width along the second horizontal direction that is greater than the first width w1. The plurality of laterally bulging portions 79B is interlaced with the plurality of neck portions 79N along the first horizontal direction hd1. The plurality of laterally bulging portions 79B and neck portions 79N can be formed entirely within the transition region 200 between a respective pair of straight surface segments 79S that extend along the first horizontal direction hd1 in the memory array region 100 and the contact region 300. In this embodiment, the neck portions 79N may lack the straight sidewalls and may be located where the edges of adjacent bulging portions 79B meet each other.

In one embodiment, the maximum of the variable width is a second width w2. In the first alternative configuration, an entire portion of each lateral isolation trench 79 located in the memory array region 100 may have a uniform array-region width w_a that is less than the second width w2, and an entire portion of each lateral isolation trench 79 located in the contact region 300 may have a uniform contact-region width w_c that is less than the second width w2. In one embodiment, the uniform array-region width w_a is not less than the first width w1; and the uniform contact-region width w_c is not less than the first width w1. In one embodiment, the uniform array-region width w_a and the uniform contact-region width w_c may be the same as the first width w1 of the neck portions 79N. In one embodiment, the plurality of laterally bulging portions 79B in each lateral isolation trench 79 has a uniform pitch along the first horizontal direction hd1, which may be the same as the first pitch p1.

Referring to FIG. 11B, a second alternative configuration of the first exemplary structure can be derived from the first alternative configuration of the first exemplary structure by selecting the value for the uniform array-region width w_a to be greater than the first width w1, and/or by selective the value for the uniform contact-region width w_c to be greater than the first width w1.

Referring to FIG. 11C, a third alternative configuration of the first exemplary structure can be derived from the first alternative configuration of the first exemplary structure by providing a straight surface segment in each of the laterally bulging portions 79B and each of the neck portions 79N of the lateral isolation trenches 79. In this case, each of the plurality of laterally bulging portions 79B comprises a respective uniform width portion having the second width w2. Each of the plurality of laterally bulging portions 79B can be laterally bounded by four laterally concave surface segments that are laterally spaced from each other and not directly contact each other.

Referring to FIG. 11D, a fourth alternative configuration of the first exemplary structure can be derived from the third alternative configuration of the first exemplary structure by providing multiple stepwise increases in the variable width of the laterally bulging portions 79B of the lateral isolation trenches 79. In this case, each of the plurality of laterally bulging portions 79B can be laterally bounded by four sets of laterally concave surface segments, each set comprising two laterally concave surface segments, that are laterally spaced from each other and not directly contact each other.

Referring to FIG. 11E, a fifth alternative configuration of the first exemplary structure can be derived from the second alternative configuration of the first exemplary structure by providing a straight surface segment in each of the laterally bulging portions 79B and neck portions 79N of the lateral isolation trenches 79. In this case, each of the plurality of laterally bulging portions 79B comprises a respective uniform width portion having the second width w2. Each of the plurality of laterally bulging portions 79B can be laterally bounded by four laterally concave surface segments that are laterally spaced from each other and not directly contact each other.

Referring to FIG. 11F, a sixth alternative configuration of the first exemplary structure can be derived from the fifth alternative configuration of the first exemplary structure by providing multiple stepwise increases in the variable width of the laterally bulging portions 79B of the lateral isolation trenches 79. In this case, each of the plurality of laterally bulging portions 79B can be laterally bounded by four sets of laterally concave surface segments, each set comprising two laterally concave surface segments, that are laterally spaced from each other and not directly contact each other.

As shown in FIGS. 11A-11F, each of the laterally bulging portions 79B may be located adjacent to a respective second-type support pillar structure 20B along the second horizontal direction hd2. Without wishing to be bound by a particular theory, the ions used to etch the lateral isolation trenches 79 during a reactive ion etch process, are concentrated in the laterally bulging portions 79B adjacent to the respective second-type support pillar structures 20B. The second-type support pillar structures 20B provide support for the device structure, and minimize bending of the lateral isolation trenches 79 along the second horizontal direction hd2 due to ion attack on the sidewalls of the lateral isolation trenches 79. Furthermore, by concentrating the ions in the laterally bulging portions 79B adjacent to the respective second-type support pillar structures 20B, reduces ion attack on the first-type support pillar structures 20A, which may consist entirely of the same material (e.g., silicon oxide) as the insulating layers 32, which is etched by the reactive ion etching process. This also reduces bending of the lateral isolation trenches 79 along the second horizontal direction hd2.

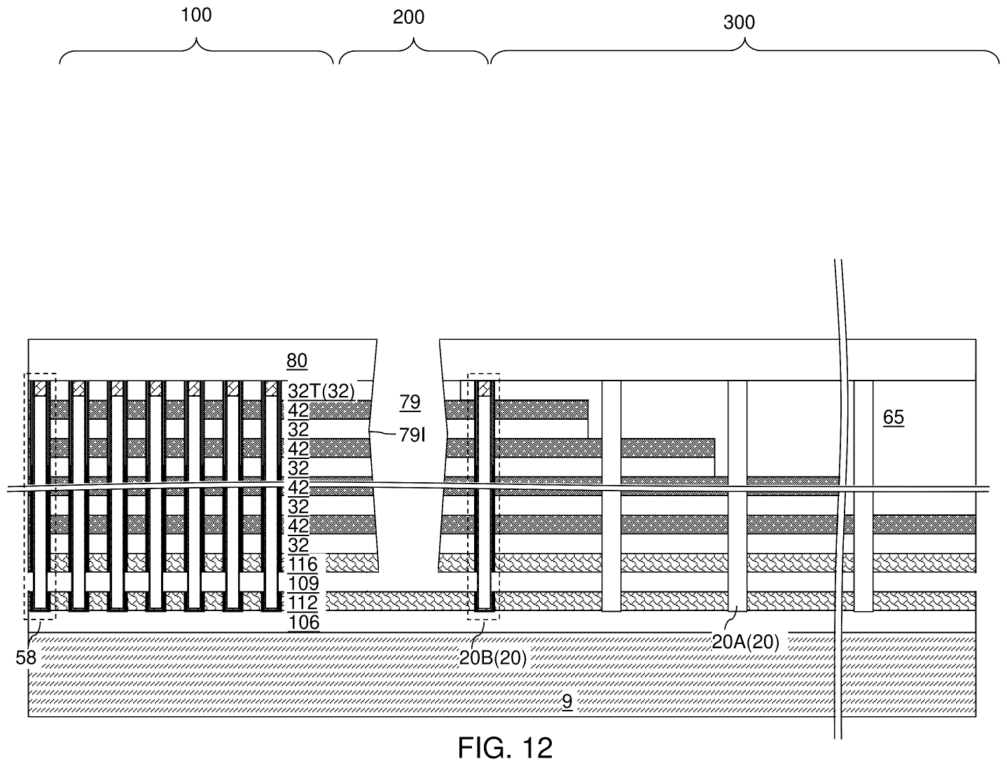

Referring to FIG. 12, if the in-process source-level material layers 110′ are used, then the source-level sacrificial layer 104 is selectively removed through the lateral isolation trenches 79. An etchant that etches the material of the source-level sacrificial layer 104 selective to the materials of the alternating stack (32, 42), the contact-level dielectric layer 80, the stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the first exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

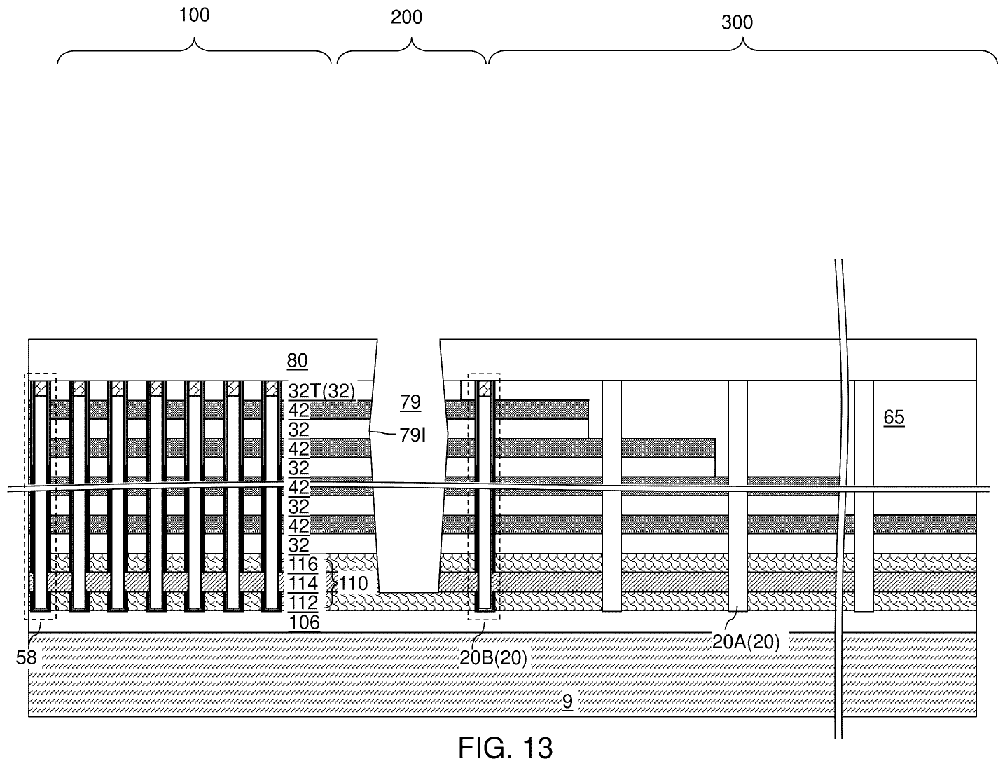

Referring to FIG. 13, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the first exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes source-level material layers 110, which replaces the in-process source-level material layers 110′. The source-level material layers 110 contact an end portion of each of the vertical semiconductor channels 60. Optionally, a dielectric surface conversion process, such as an oxidation process or a nitridation process, may be performed to convert physically exposed surface portions of the source-level material layers 110 from underneath each lateral isolation trench 79 to form trench bottom dielectric liners 129. The source-level material layers 110 include semiconductor material layers such as a stack of a lower source-level semiconductor layer 112, a source contact layer 114, and an upper source-level semiconductor layer 116.

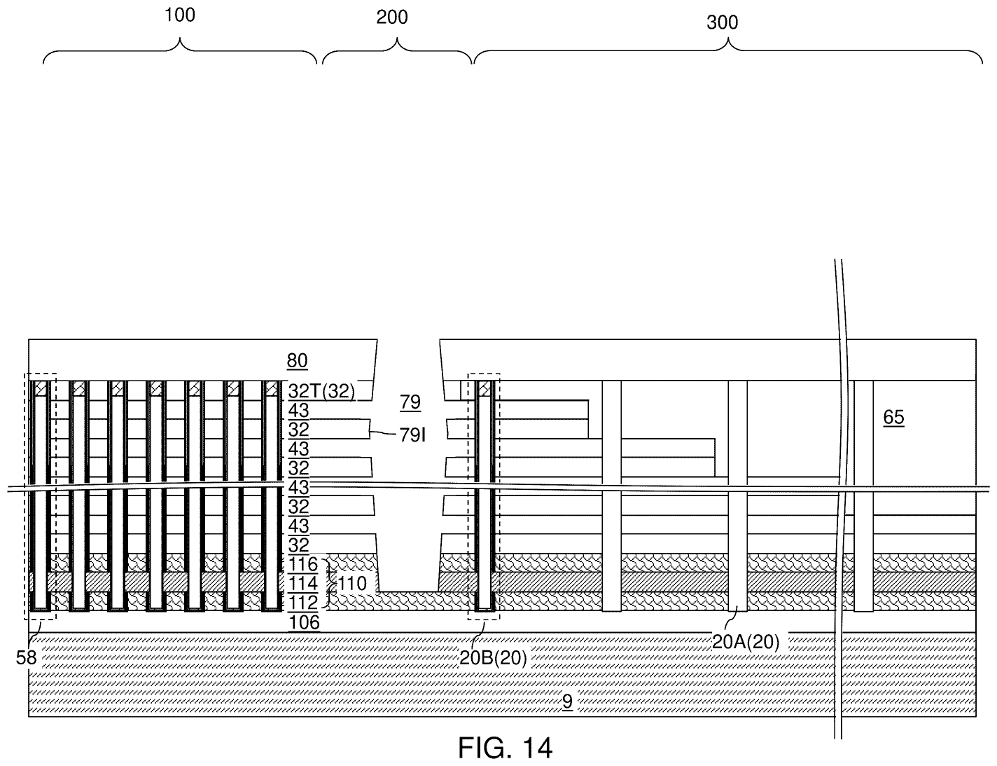

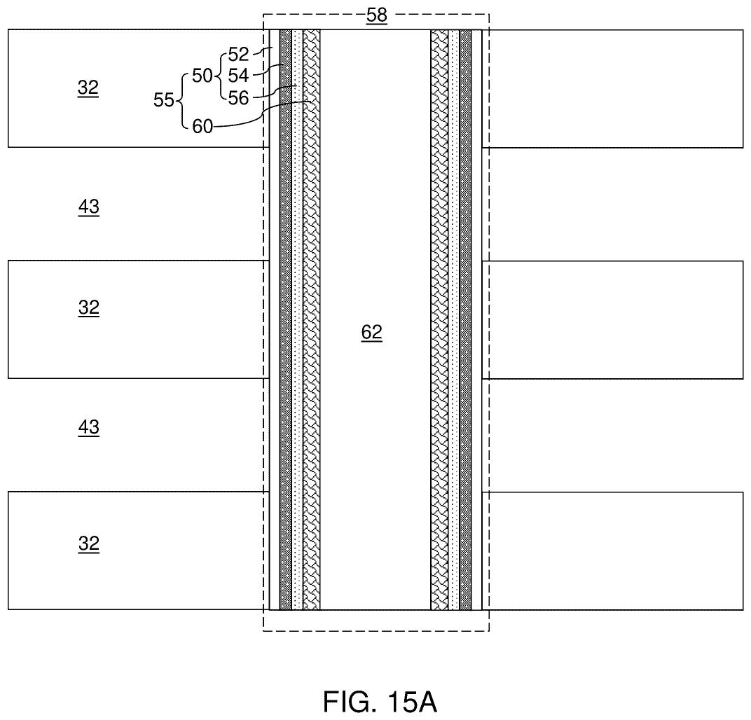

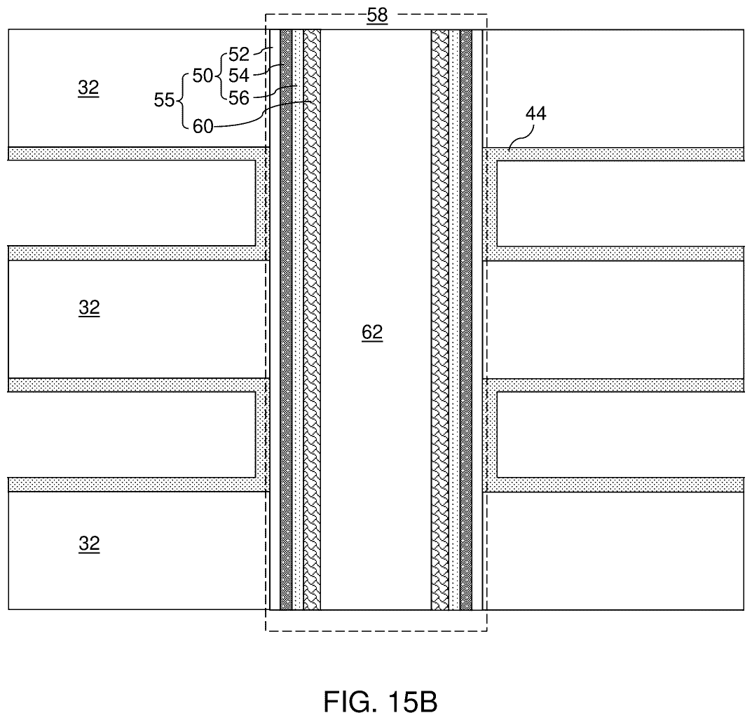

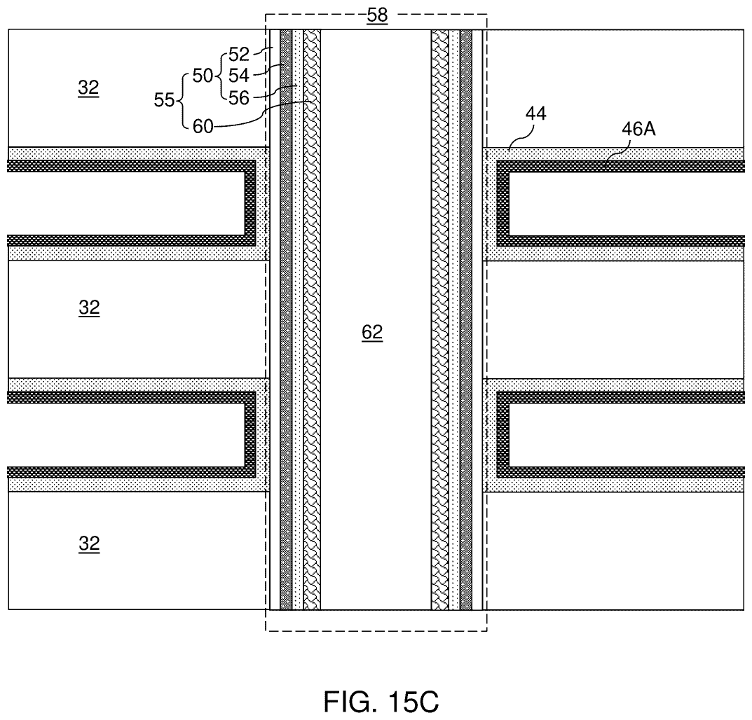

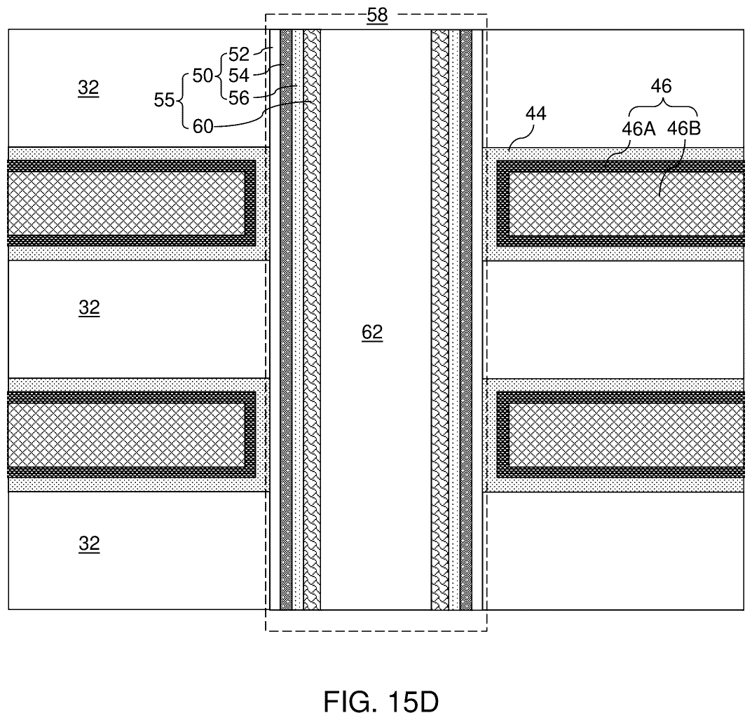

Referring to FIGS. 14 and 15A, an isotropic etch process can be performed to remove the sacrificial material layers 42 selective to the insulating layers 32, the stopper insulating layer 106, the memory opening fill structures 58, the sacrificial etch stop liners 71, and the source-level material layers 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon oxide, the isotropic etch process may comprise a wet etch process employing hot phosphoric acid, which is a process in which the first exemplary structure is immersed in phosphoric acid at, or near, the boiling point of the phosphoric acid. A suitable clean process may be performed as needed.

Referring to FIG. 15B, an outer blocking dielectric layer 44 can be optionally formed in the laterally-extending cavities 43 by a conformal deposition process.

Referring to FIG. 15C, a metallic barrier material can be conformally deposited in the laterally-extending cavities 43. The metallic barrier material may comprise, for example, TiN, TaN, WN, MON, TiC, TaC, WC, or a combination thereof.

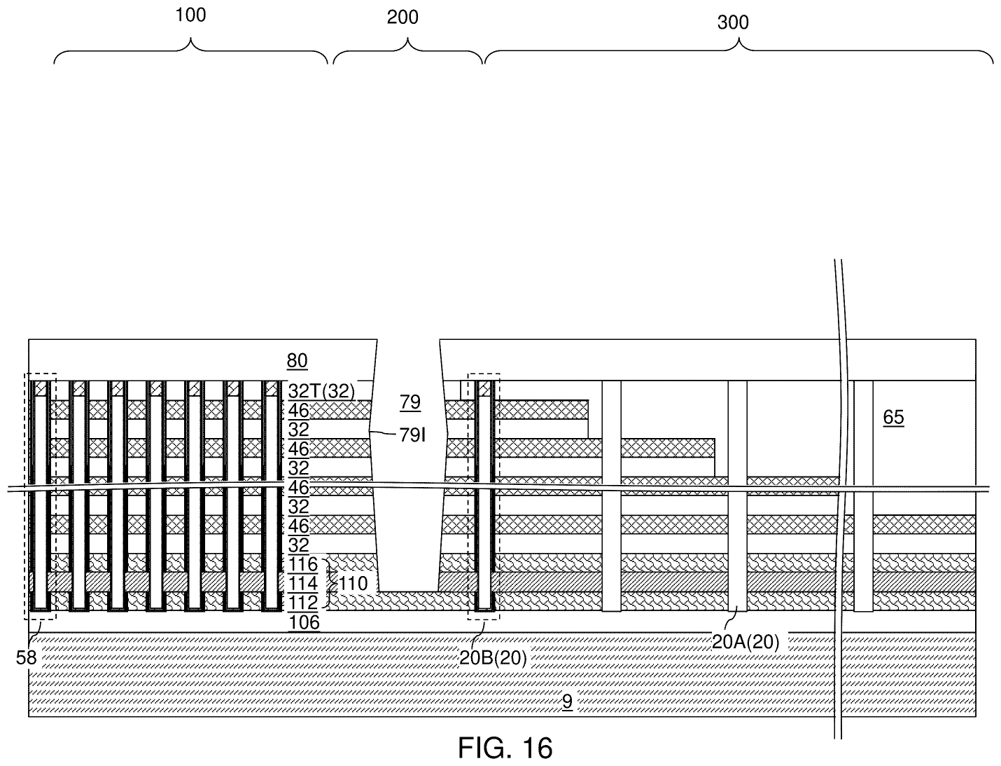

Referring to FIGS. 15D and 16, a metallic fill material can be conformally deposited in remaining volumes of the laterally-extending cavities 43. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the insulating cap layer 70 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the carrier substrate 9. A plurality of alternating stacks of insulating layers 32 and electrically conductive layers 46 can be laterally spaced apart among one another by the lateral isolation trenches 79. The electrically conductive layers 46 include the word lines and the select gate electrodes.

A plurality of alternating stacks (32, 46) of insulating layers 32 and electrically conductive layers 46 can be formed, which can be laterally spaced apart from each other by the lateral isolation trenches 79. Each laterally-neighboring pair of alternating stacks (32, 46) can be laterally spaced from each other by a lateral isolation trench 79 that laterally extends along a first horizontal direction hd1. Memory openings 49 vertically extend through a respective one of the alternating stacks (32, 46). Memory opening fill structures 58 can be located in a respective one of the memory openings 49. Each of the memory opening fill structures 58 comprises a respective vertical semiconductor channel 60 and a respective vertical stack of memory elements (e.g., portions of the memory film 50) located at levels of the electrically conductive layers 46.

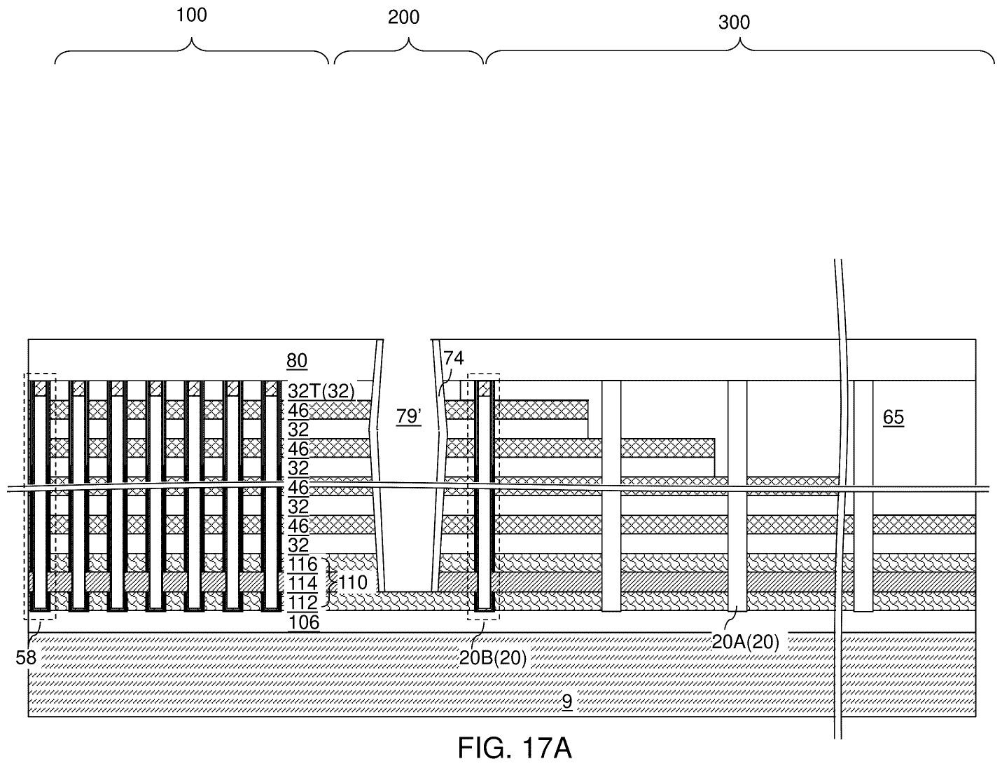

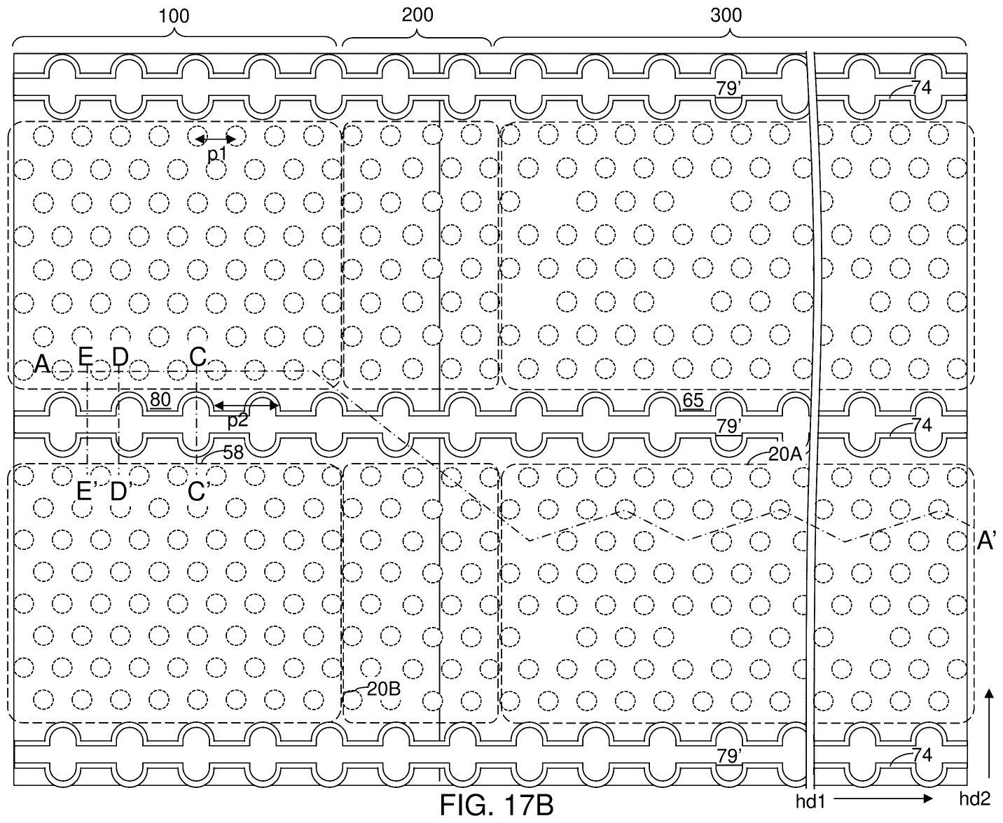

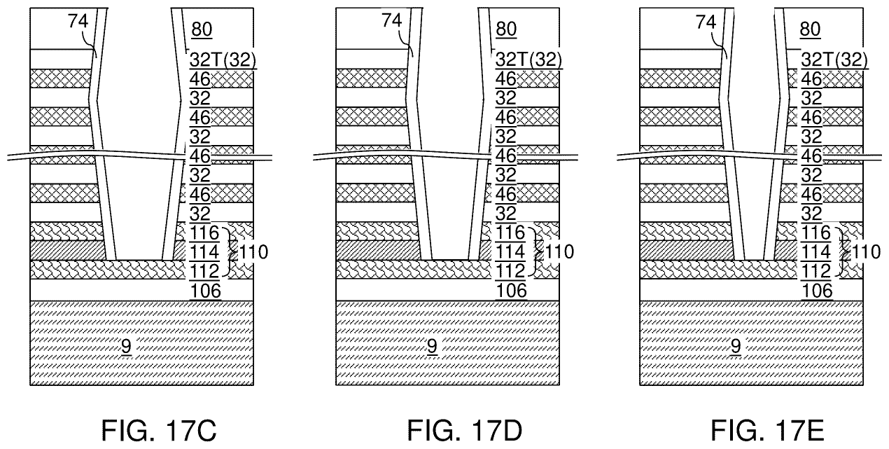

Referring to FIGS. 17A-17E, an insulating material may be conformally deposited in the lateral isolation trenches 79, and may be anisotropically etched to form insulating spacers 74 in peripheral portions of the lateral isolation trenches 79. The insulating spacers 74 comprise an insulating material, such as undoped silicate glass or a doped silicate glass. Each of the insulating spacers 74 may comprise a pair of laterally-undulating outer sidewalls and a pair of laterally-undulating inner sidewalls. A lateral isolation cavity 79′ can be present within each lateral isolation trench 79.

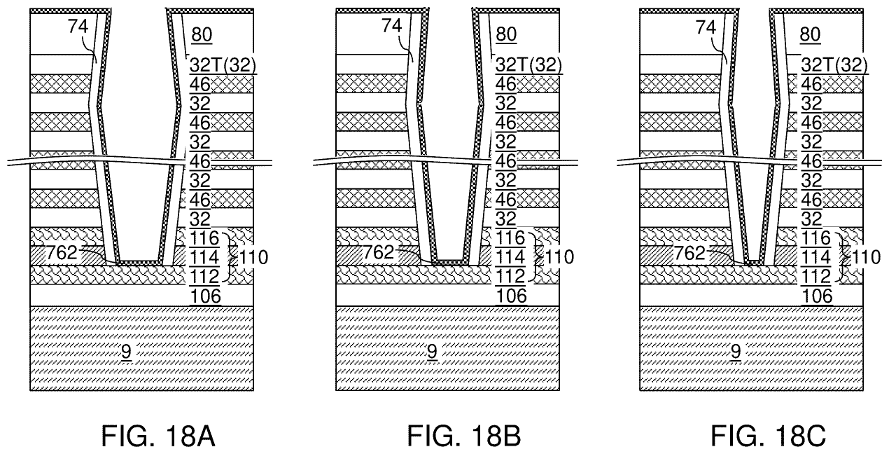

Referring to FIGS. 18A-18C, a first metallic barrier liner 762 can be conformally deposited on the physically exposed surfaces of the insulating spacers 74, the source-level material layers 110, and the contact-level dielectric layer 80. For example, a chemical vapor deposition process may be employed to deposit the first metallic barrier liner 762. The first metallic barrier liner 762 may comprise a conductive metallic nitride material such as TiN, TaN, WN, MON, etc., and may have a thickness in a range from 5 nm to 100 nm, although lesser and greater thicknesses may also be employed. Alternatively, a refractory metal layer, such as Ti, Ta, W or Mo can be conformally deposited on the physically exposed surfaces of the insulating spacers 74, the source-level material layers 110, and the contact-level dielectric layer 80, and then exposed to a nitrogen containing ambient (e.g., an ammonia containing ambient) at an elevated temperature to convert the refractory metal layer into the conductive metallic nitride material such as TiN, TaN, WN, MON, etc., of the first metallic barrier liner 762.

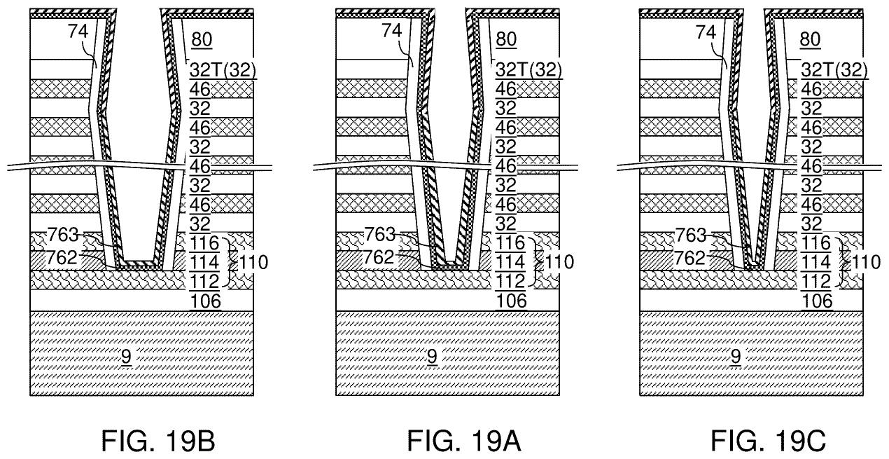

Referring to FIGS. 19A-19C, a first metal layer 763 can be conformally deposited on the physically exposed surfaces of the first metallic barrier liner 762. For example, a chemical vapor deposition may be employed to deposit the first metal layer 763. The first metal layer 763 comprises a first metal, which may be an elemental metal or an intermetallic compound. For example, the first metal layer 763 may comprise, and/or may consist essentially of, W, Ti, Ta, Mo, etc. The thickness of the first metal layer 763 may be in a range from 20 nm to 100 nm, although lesser and greater thicknesses may also be employed.

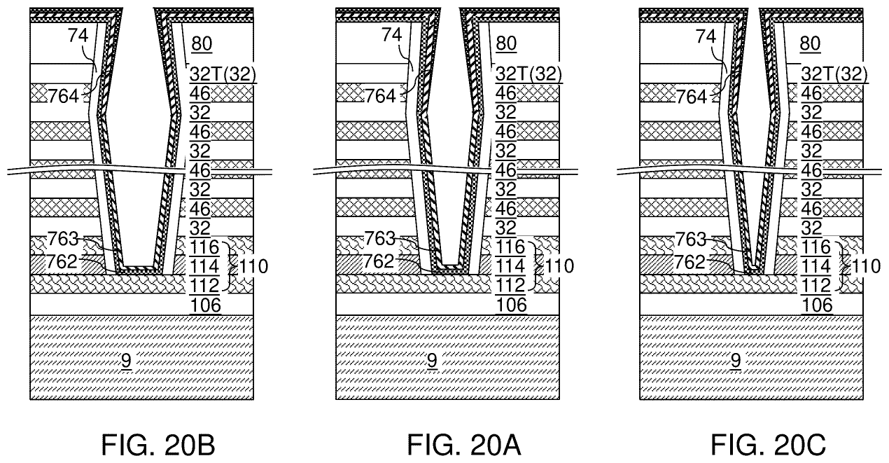

Referring to FIGS. 20A-20C, a second metallic barrier liner 764 can be non-conformally deposited on the horizontally-extending portion of the first metal layer 763 that overlies the contact-level dielectric layer 80 and in upper portions of the first metal layer 763 that are proximal to the contact-level dielectric layer 80. For example, the second metallic barrier liner 764 may be deposited by physical vapor deposition. The second metallic barrier liner 764 may comprise a conductive metallic nitride material such as TiN, TaN, WN, MON, etc. The horizontally-extending portion of the second metallic barrier liner 764 that overlies the contact-level dielectric layer 80 may have a thickness in a range from 5 nm to 30 nm, although lesser and greater thicknesses may also be employed.

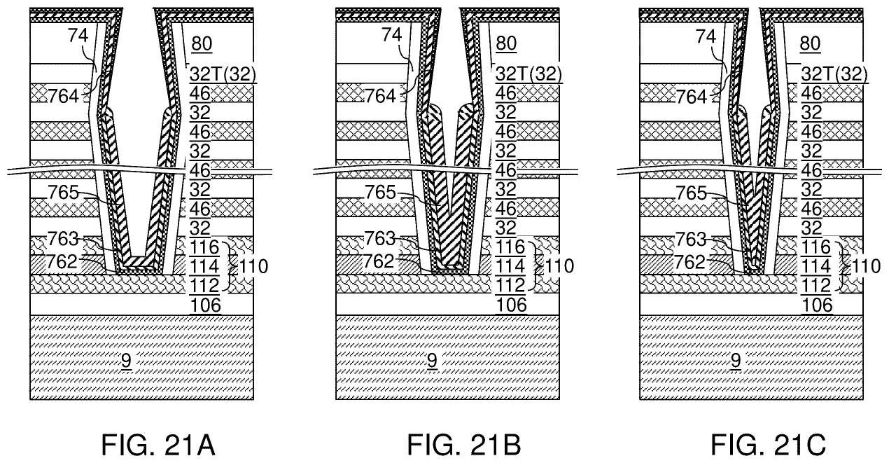

Referring to FIGS. 21A-21C, a selective metal deposition process may be performed to grow a second metal from physically exposed surfaces of the first metal layer 763, while suppressing growth of the second metal from the physically exposed surfaces of the second metallic barrier liner 764. For example, a metal such as W, Ti, Ta, or Mo can be grown from the physically exposed surfaces of the first metal layer 763 by a chemical vapor deposition process. In an illustrative example, the chemical vapor deposition process may employ a fluorine-containing metal precursor gas (such as tungsten hexafluoride) or a chlorine-containing metal precursor gas that decomposes on a metal surface (such as a tungsten surface) and does not decompose on a metal nitride surface (such as a titanium nitride surface). The deposited portions of the second metal are herein referred to as metal portions 765. The thickness of each metal portion 765 may be in a range from 30 nm to 150 nm, although lesser and greater thicknesses may also be employed. The metal portions 765 reduce the volume of unfilled cavities in the lateral isolation trenches 79.

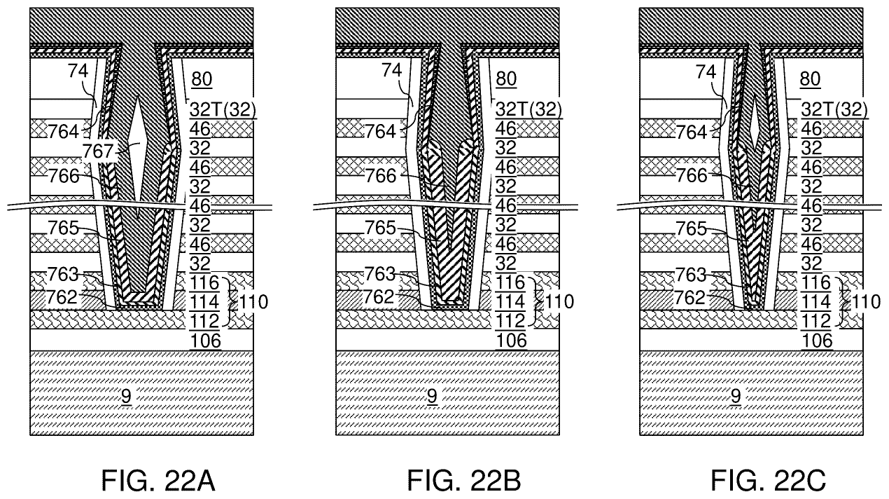

Referring to FIGS. 22A-22C, a second metal layer 766 can be conformally deposited to fill remaining portions of the lateral isolation trenches 79 by a conformal deposition process, such as a chemical vapor deposition process. The laterally bulging portions 79B in the lateral isolation trenches 79 function as access paths for precursor reactants for deposition of the second metal. The second metal may comprise an elemental metal or an intermetallic alloy. The second metal may comprise W, Ti, Ta, Co, Ru, Mo, Cu, or alloys thereof. Encapsulated cavities (i.e., airgaps) 767 that are free of any solid-phase material may be formed in center portions of the laterally building portions of the lateral isolation trenches 79.

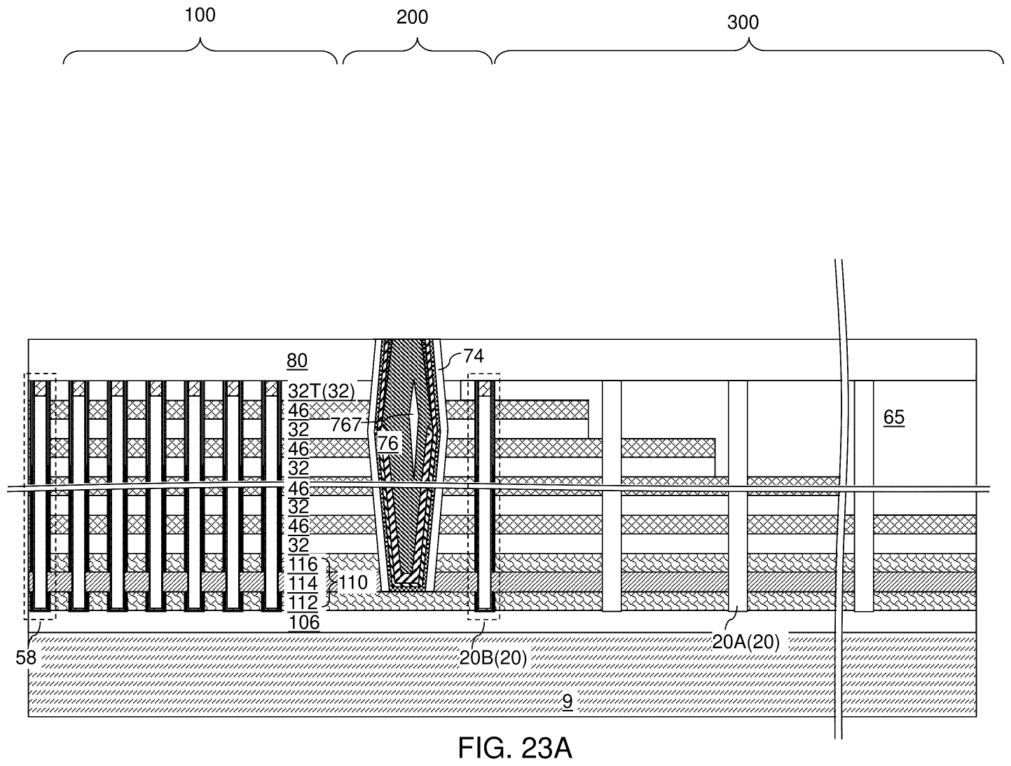

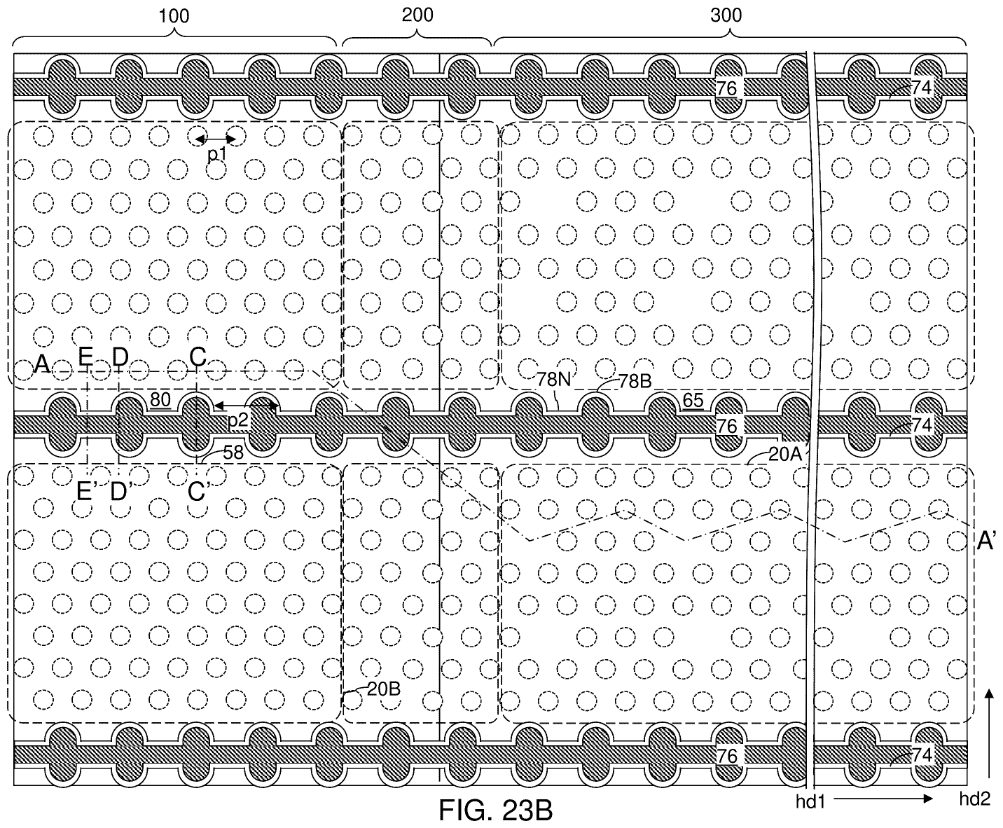

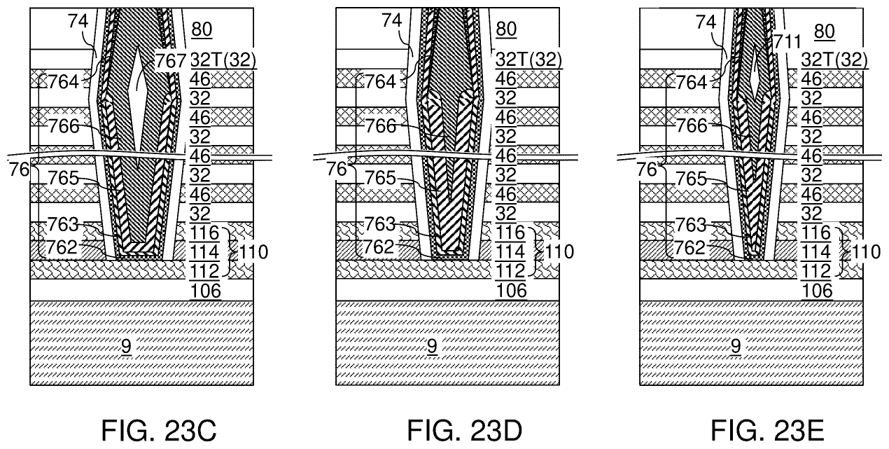

Referring to FIGS. 23A-23E, portions of the metallic materials of the first metallic barrier liner 762, the first metal layer 763, the second metallic barrier liner 764, and the second metal layer 766 that overlie the horizontal plane including the top surface of the contact-level dielectric layer 80 can be removed by performing a planarization process, such as a chemical mechanical polishing process. Each remaining portion of the metallic materials that remain in a respective lateral isolation trench 79 constitutes a conductive fill structure 76. Each contiguous combination of an insulating spacer 74 and a conductive fill structure 76 constitutes a lateral isolation trench fill structure (74, 76).

Each isolation trench fill structure (74, 76) comprises an insulating spacer 74 and a conductive fill structure 76 that is laterally surrounded by the insulating spacer 74. In one embodiment, each insulating spacer 74 comprises a pair of outer lengthwise sidewalls each comprising a plurality of laterally-convex surface segments that are interlaced with a plurality of first laterally-straight surface segments, and a pair of inner lengthwise sidewalls each comprising a plurality of laterally-concave surface segments that are interlaced with a plurality of second laterally-straight surface segments.

Each lateral isolation trench fill structure (74, 76) may comprise a pair of lengthwise sidewalls that generally extend along the first horizontal direction hd1. A vertical cross-sectional profile of the lateral isolation trench fill structure (74, 76) in a vertical plane that is perpendicular to the first horizontal direction hd1 has a variable width that increases with a vertical distance from a horizontal plane including a bottommost surface of the vertically alternating sequence (32, 42) in a lower portion of the vertically alternating sequence (32, 42) to the above described inflection line 79I, and decreases with the vertical distance from the horizontal plane including the inflection line 79I in an upper portion of the vertically alternating sequence (32, 42). In one embodiment, each lateral isolation trench fill structure (74, 76) has a width modulation along a second horizontal direction hd2 that is perpendicular to the first horizontal direction hd1 as a function of a lateral distance along the first horizontal direction hd1.

In one embodiment, each lateral isolation trench fill structure (74, 76) comprises a periodic laterally alternating sequence of neck portions (e.g., regions) 78N having a minimum width along the second horizontal direction hd2 and bulging portions (e.g., regions) 78B having a maximum width along the second horizontal direction hd2. In the embodiment shown in FIG. 20B, the neck portions 78N include horizontally-linear (i.e., straight) sidewalls and the bulging portions 78B include horizontally-convex sidewalls that bulge outward from the center of the lateral isolation trench fill structure (74, 76). In this embodiment, each lateral isolation trench fill structure (74, 76) comprises a pair of laterally-undulating lengthwise sidewalls that have lateral undulations at the bulging portions 78B; and each of the pair of laterally-undulating lengthwise sidewalls in the bulging portions 78B comprises a set of horizontally-convex and vertically-tapered surface segments that are adjoined at edges to horizontally-linear and vertically-tapered surface segments in the neck portions 78N. In one embodiment, each of the plurality of laterally bulging portions 78B has a pair of laterally convex surface segments that are laterally spaced from each other.

Each lateral isolation trench fill structure (74, 76) generally extends along a first horizontal direction hd1 through the vertically alternating sequence (32, 42). Each lateral isolation trench fill structure (74, 76) comprises a plurality of neck portions 78N having a first width w1 along a second horizontal direction hd2 that is perpendicular to the first horizontal direction hd1 between a respective pair of straight surface segments that extend along the first horizontal direction hd1. Each lateral isolation trench fill structure (74, 76) further comprises a plurality of laterally bulging portions 78B having a variable width along the second horizontal direction that is greater than the first width w1. The plurality of laterally bulging portions 78B are interlaced with the plurality of neck portions 78N along the first horizontal direction hd1. In one embodiment, the maximum of the variable width may be a second width w2 at the middle of the laterally bulging portions 78B.

In one embodiment shown in FIG. 23B, the memory opening fill structures 58 may be arranged in rows that laterally extend along the first horizontal direction hd1. Memory opening fill structures 58 located within each row of memory opening fill structures 58 may be arranged with a uniform pitch, which is herein referred to as a first pitch p1 along the first horizontal direction hd1. In one embodiment, the plurality of laterally bulging portions 78B has a uniform pitch, which is herein referred to as a second pitch p2, along the first horizontal direction hd1. The second pitch p2 may be the same as the first pitch p1, or may be greater than the first pitch p1. Each of the plurality of laterally bulging portions 78B may be laterally bounded along the second horizontal direction hd2 by a pair of laterally convex surface segments that are laterally spaced from each other.

In one embodiment, each of the laterally convex surface segments of the laterally-bulging portions 78B may have a respective pair of convex surfaces in a horizontal cross-sectional view. The plurality of laterally bulging portions 78B are formed at least in the transition region 200, and may be formed in the memory array region 100 and/or in the contact region 300. In one embodiment, a first subset of the laterally bulging portions 78B may be located in the transition region 200, a second subset of the laterally bulging portions 78B may be located in the memory array region 100, and a third subset of the laterally bulging portions 78B may be located in the contact region 300.

The airgaps 767 are formed due to the second metal layer 766 necking at the top of the lateral isolation trenches 79, which may have a narrowing width above the inflection line 79I. If the airgaps 767 were continuous along the entire length of the lateral isolation trench fill structures (74, 76) along the first horizontal direction hd1, then such continuous airgaps 767 would structurally weaken the lateral isolation trench fill structures (74, 76). However, by forming lateral isolation trench fill structure (74, 76) with lateral undulations (e.g., with the alternating bulging and neck portions), the airgaps are closed off at the interface between the lateral undulations.

As shown in FIGS. 23C-23E, discrete airgaps 767 may be present in the middle of the bulging portions 78B and the neck portions 78N. However, as shown in FIG. 23D, the airgaps 767 are closed off and do not continue through the interface regions between the bulging portions 78B and the neck portions 78N due to the lateral undulations in the lateral isolation trench fill structures (74, 76). Thus, by making the airgaps 767 discontinuous instead of continuous along the entire length of the lateral isolation trench fill structures (74, 76), the mechanical strength of the lateral isolation trench fill structures (74, 76) is improved.

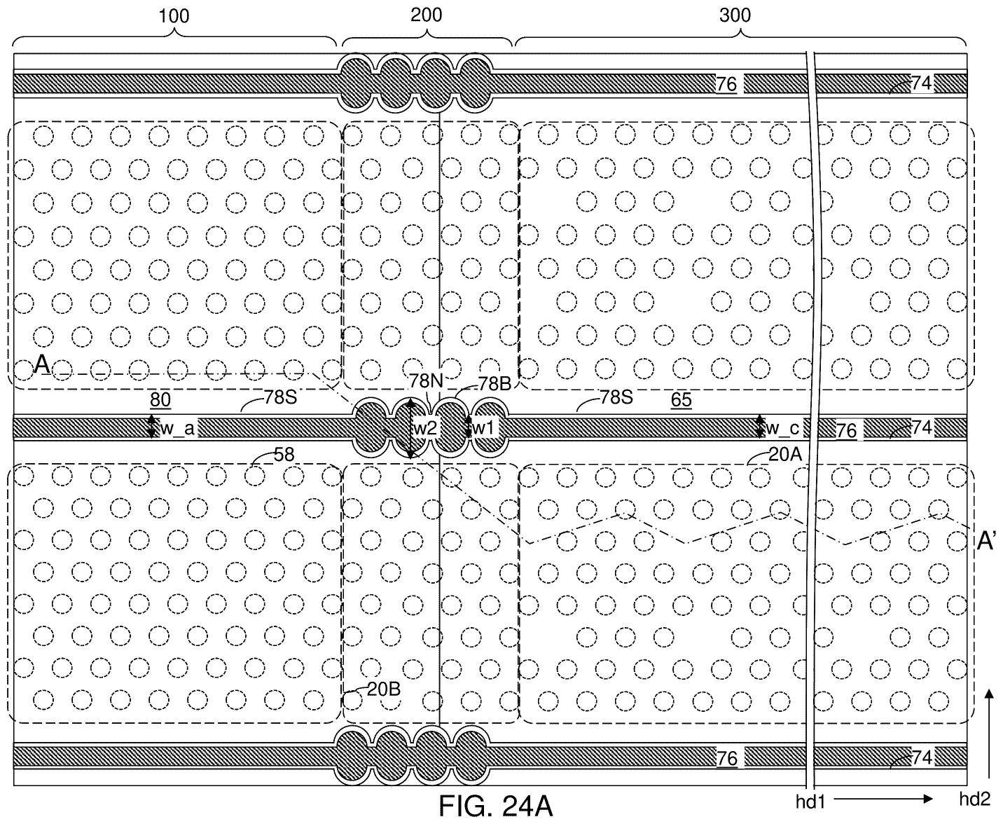

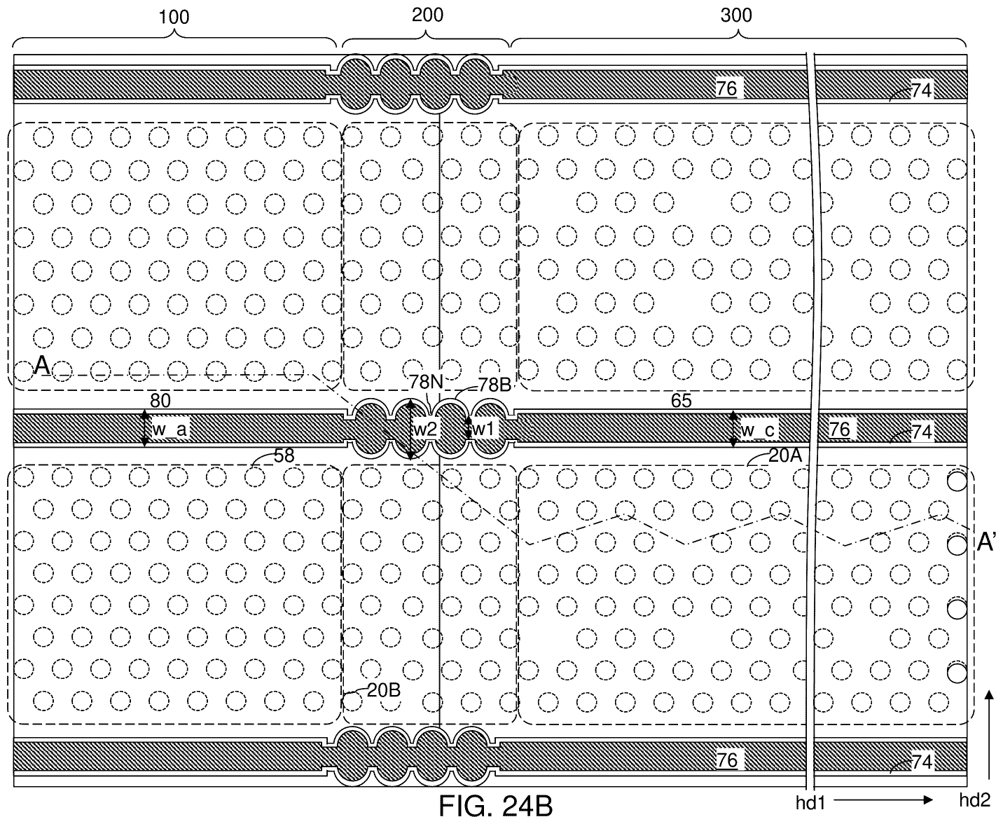

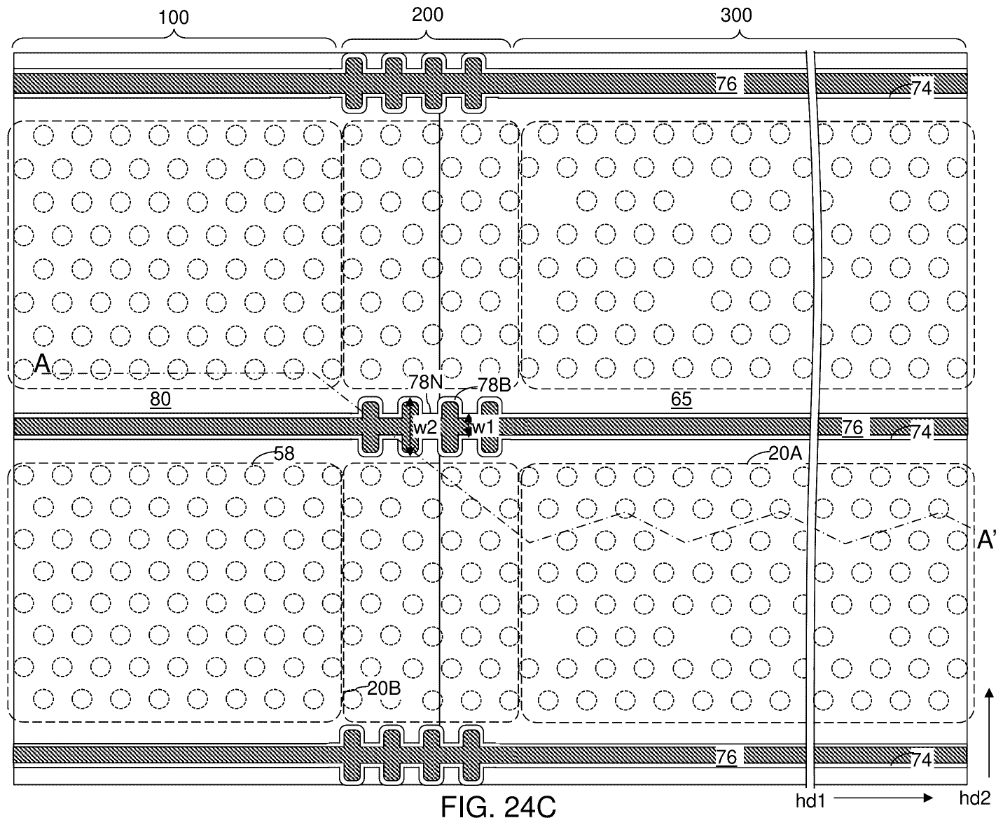

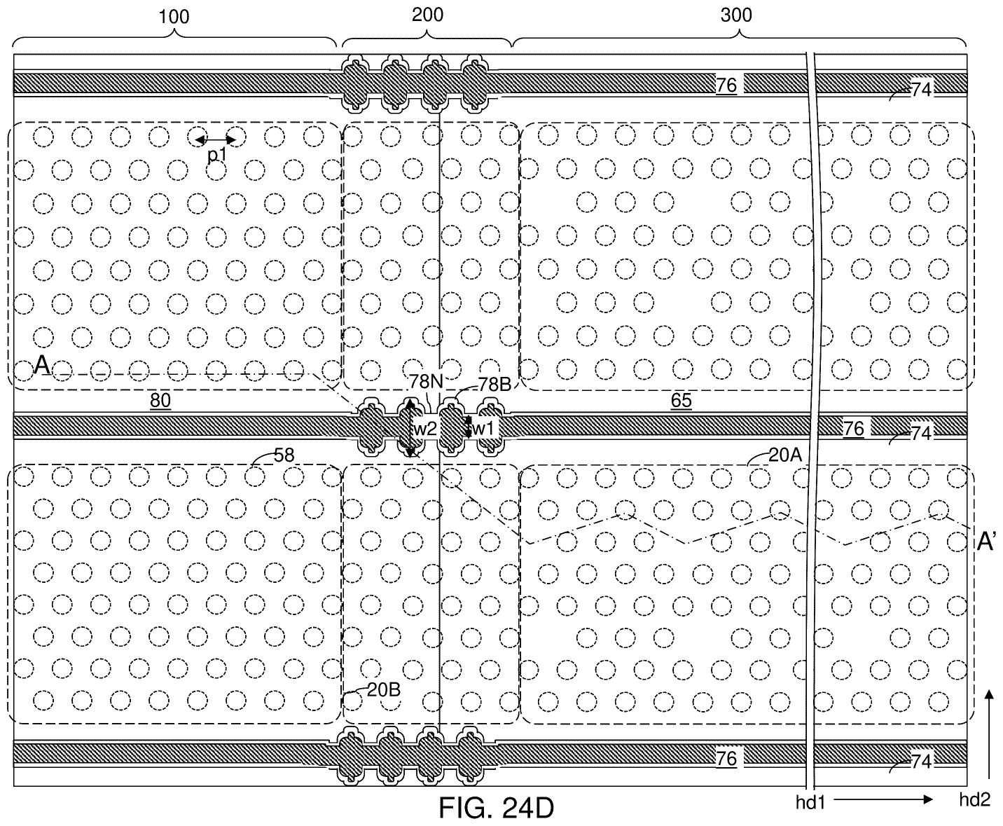

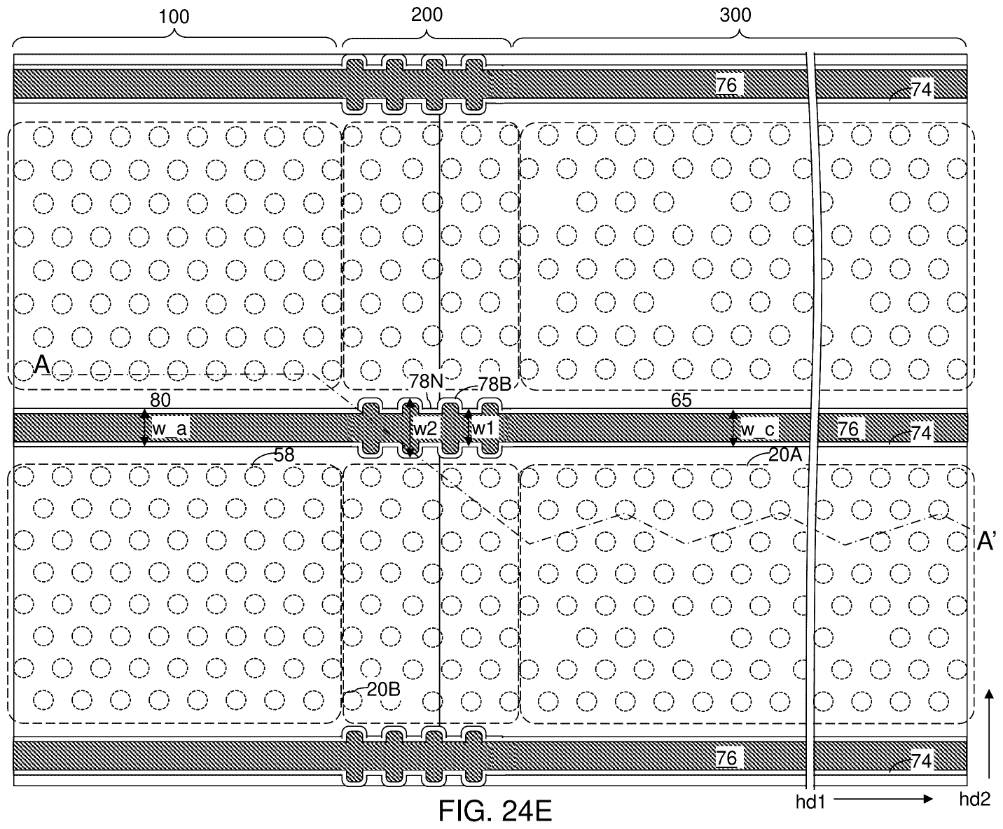

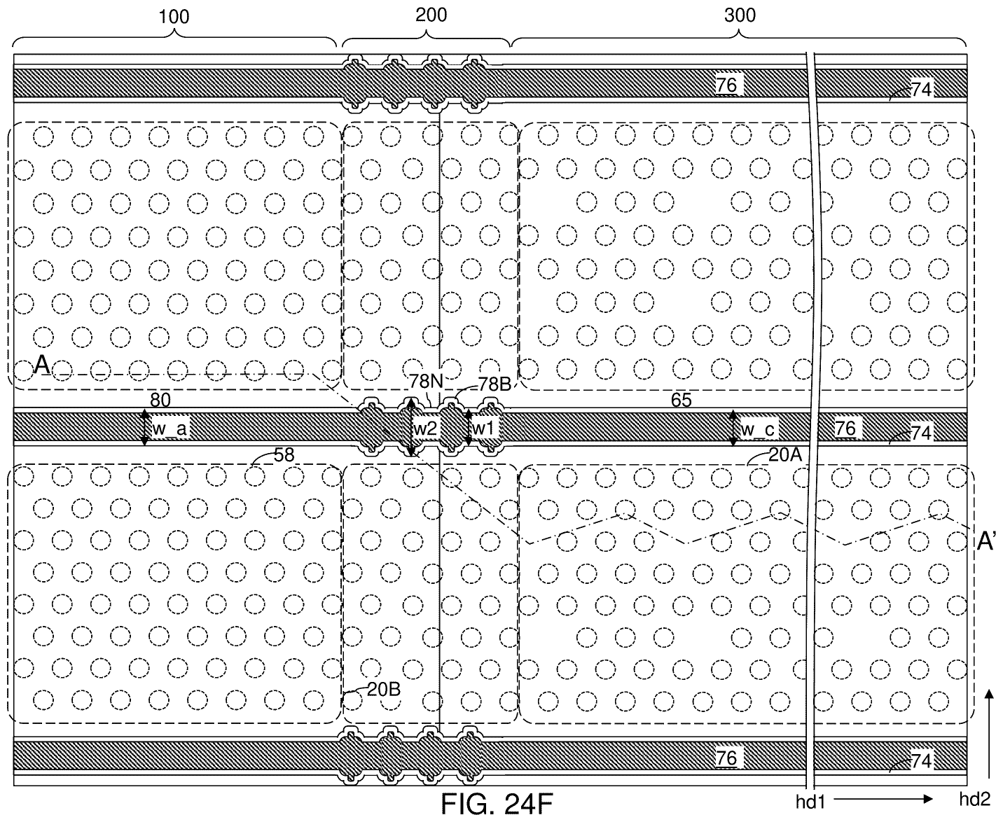

FIGS. 24A-24F are top-down views alternative configurations of the first exemplary structure at the processing steps of FIGS. 23A-23E according to an embodiment of the present disclosure. In the alternative configurations illustrated in FIGS. 24A-24F, the laterally bulging portions 78B may be formed entirely within the transition region 200. In this case, the portion of each lateral isolation trench fill structure (74, 76) having a lateral width undulation is referred to as a width undulation region WUR.

Referring to FIG. 24A, a first alternative configuration of the first exemplary structure is illustrated after the processing steps described with reference to FIGS. 23A and 23B. Each lateral isolation trench fill structure (74, 76) comprises a plurality of neck portions 78N having a first width w1 along a second horizontal direction that is perpendicular to the first horizontal direction hd1 and a plurality of laterally bulging portions 78B having a variable width along the second horizontal direction that is greater than the first width w1. The plurality of laterally bulging portions 78B is interlaced with the plurality of neck portions 78N along the first horizontal direction hd1. The plurality of laterally bulging portions 78B and neck portions 78N can be formed entirely within the transition region 200 between a respective pair of straight surface segments 78S that extend along the first horizontal direction hd1 in the memory array region 100 and the contact region 300. In this embodiment, the neck portions 78N may lack the straight sidewalls and may be located where the edges of adjacent bulging portions 78B meet each other.

In one embodiment, the maximum of the variable width is a second width w2. In the first alternative configuration, an entire portion of each lateral isolation trench fill structure (74, 76) located in the memory array region 100 may have a uniform array-region width w_a that is less than the second width w2, and an entire portion of each lateral isolation trench fill structure (74, 76) located in the contact region 300 may have a uniform contact-region width w_c that is less than the second width w2. In one embodiment, the uniform array-region width w_a is not less than the first width w1; and the uniform contact-region width w_c is not less than the first width w1. In one embodiment, the uniform array-region width w_a and the uniform contact-region width w_c may be the same as the first width w1 of the neck portions 78N. In one embodiment, the plurality of laterally bulging portions in each lateral isolation trench fill structure (74, 76) has a uniform pitch along the first horizontal direction hd1, which may be the same as the first pitch p1.

Referring to FIG. 24B, a second alternative configuration of the first exemplary structure can be derived from the first alternative configuration of the first exemplary structure by selecting the value for the uniform array-region width w_a to be greater than the first width w1, and/or by selective the value for the uniform contact-region width w_c to be greater than the first width w1.

Referring to FIG. 24C, a third alternative configuration of the first exemplary structure can be derived from the first alternative configuration of the first exemplary structure by providing a straight surface segment in each of the laterally bulging portions 78B and neck portions 78N. In this case, each of the plurality of laterally bulging portions 78B comprises a respective uniform width portion having the second width w2. Each of the plurality of laterally bulging portions 78B comprises four laterally convex surface segments that are laterally spaced from each other and not directly contact each other.

Referring to FIG. 24D, a fourth alternative configuration of the first exemplary structure can be derived from the third alternative configuration of the first exemplary structure by providing multiple stepwise increases in the variable width of the laterally bulging portions 78B. In this case, each of the plurality of laterally bulging portions 78B may comprise four sets of laterally convex surface segments, each set comprising two laterally convex surface segments, which are laterally spaced from each other and not directly contact each other.

Referring to FIG. 24E, a fifth alternative configuration of the first exemplary structure can be derived from the second alternative configuration of the first exemplary structure by providing a straight surface segment in each of the laterally bulging portions 78B and neck portions 78N. In this case, each of the plurality of laterally bulging portions 78B comprises a respective uniform width portion having the second width w2. Each of the plurality of laterally bulging portions comprises four laterally convex surface segments that are laterally spaced from each other and not directly contact each other.

Referring to FIG. 24F, a sixth alternative configuration of the first exemplary structure can be derived from the fifth alternative configuration of the first exemplary structure by providing multiple stepwise increases in the variable width of the laterally bulging portions 78B. In this case, each of the plurality of laterally bulging portions 78B may comprise four sets of laterally convex surface segments, each set comprising two laterally convex surface segments, which are laterally spaced from each other and not directly contact each other.

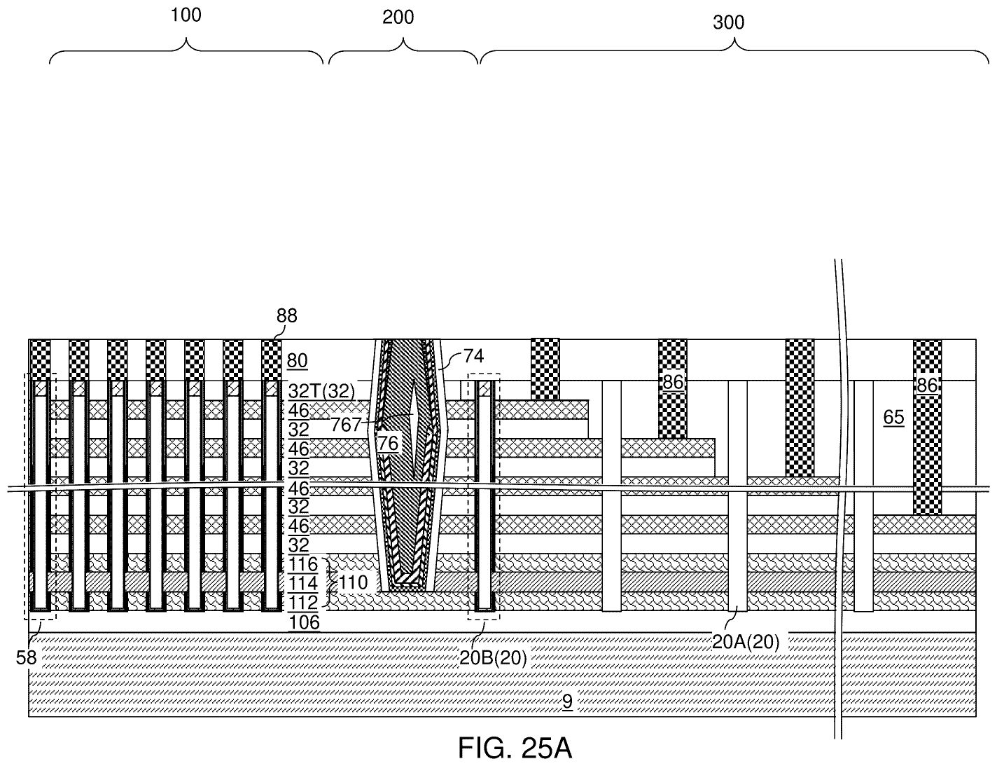

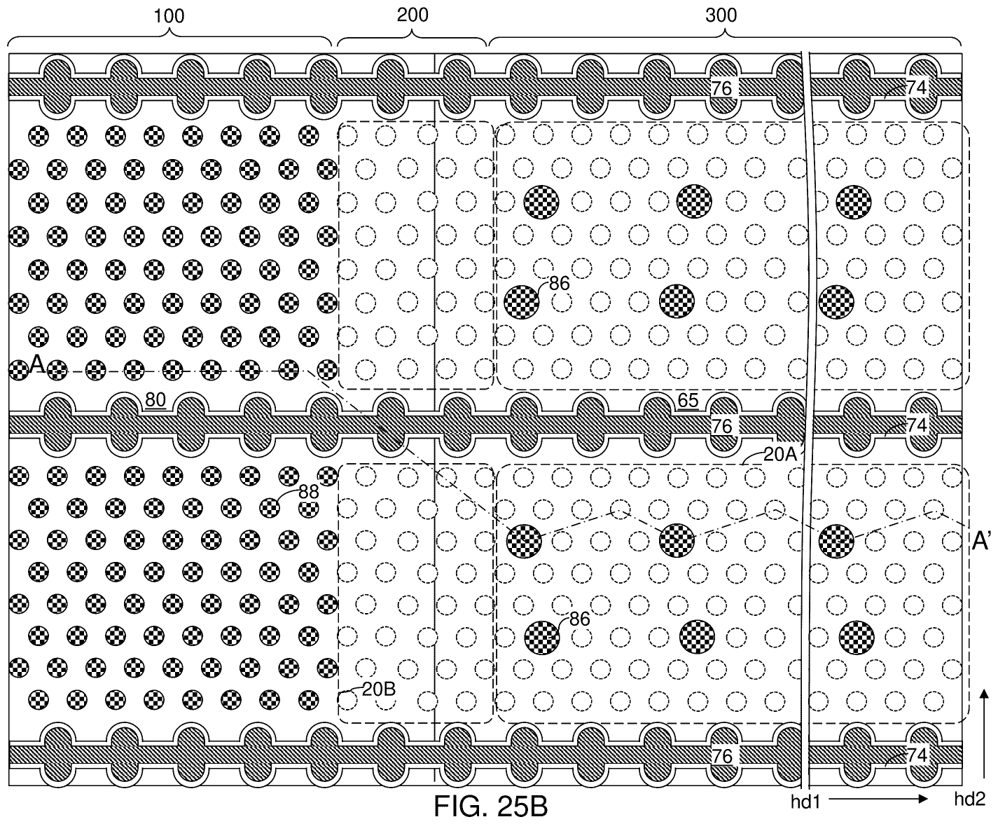

Referring to FIGS. 25A and 25B, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the stepped dielectric material portion 65. Drain contact via cavities can be formed through the contact-level dielectric layer 80 over the memory opening fill structures 58. Layer contact via cavities can be formed through the contact-level dielectric layer 80 and the stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

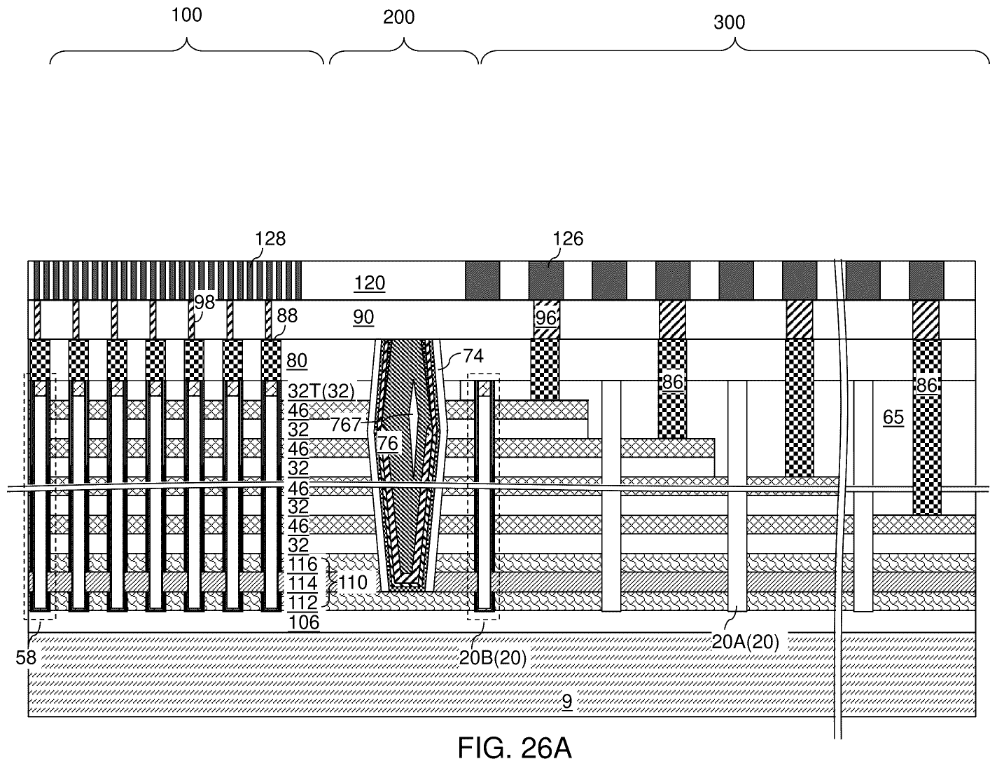

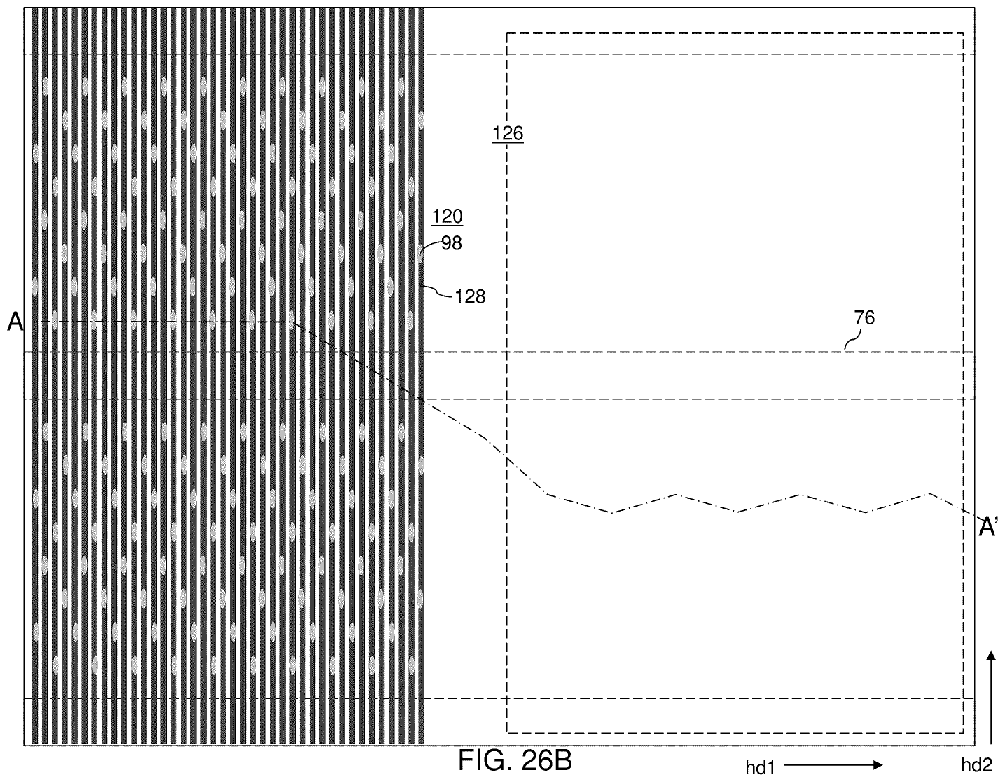

Referring to FIGS. 26A and 26B, a connection-level dielectric layer 90 can be formed above the contact-level dielectric layer 80. Connection via cavities can be formed through the connection-level dielectric layer 90, and can be filled with at least one conductive material (which may comprise at least one metallic material) to form connection-level via structures (98, 96). The connection-level via structures (98, 96) comprise drain connection via structures 98 that contact a respective one of the drain contact via structures 88, and layer connection via structures 96 that contact a respective one of the layer contact via structures 86.

A bit-line-level dielectric layer 120 can be formed above the connection-level dielectric layer 90. Bit-line-level line cavities can be formed through the bit-line-level dielectric layer 120, and can be filled with at least one conductive material (which may comprise at least one metallic material) to form bit-line-level metal lines (128, 126). The bit-line-level metal lines may comprise bit lines 128 that laterally extend along the second horizontal direction hd2, and bit-line-level interconnect metal lines 126 (not individually shown) that can be employed to provide electrical connection to the layer connection via structures 96.

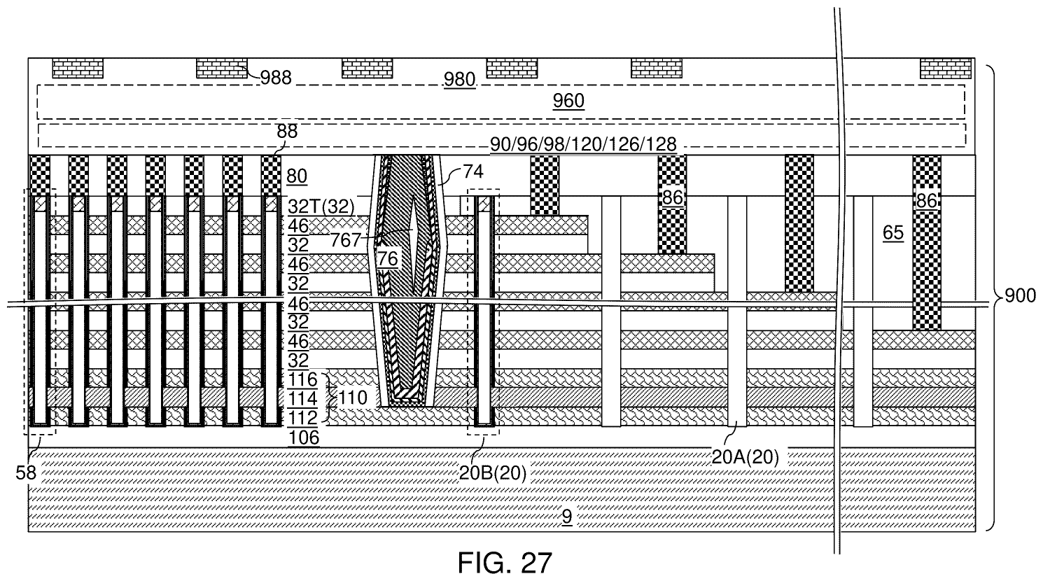

Referring to FIG. 27, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding the bit lines 128, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines for the three-dimensional memory array.

Generally, a memory die 900 is provided, which comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers 32 and electrically conductive layers 46, and further comprises a two-dimensional array of NAND strings (e.g., the memory opening fill structures 58) vertically extending through the alternating stack (32, 46). In one embodiment, the electrically conductive layers 46 comprise word lines of the two-dimensional array of NAND strings. In one embodiment, the memory-side metal interconnect structures 980 comprise the bit lines 128 for the two-dimensional array of NAND strings.

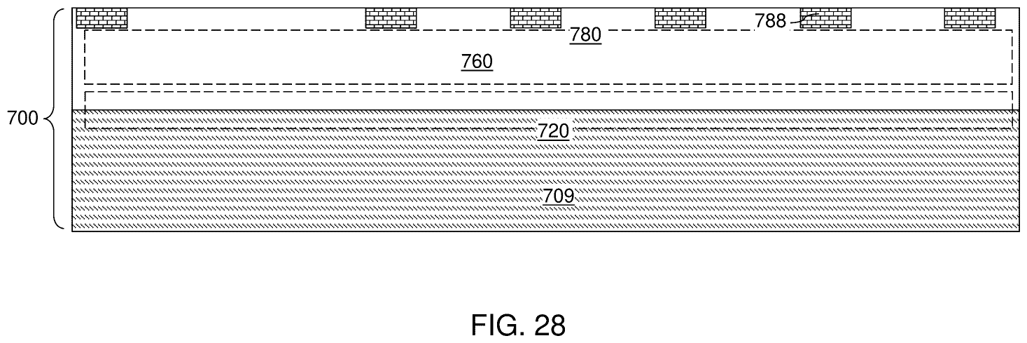

Referring to FIG. 28, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

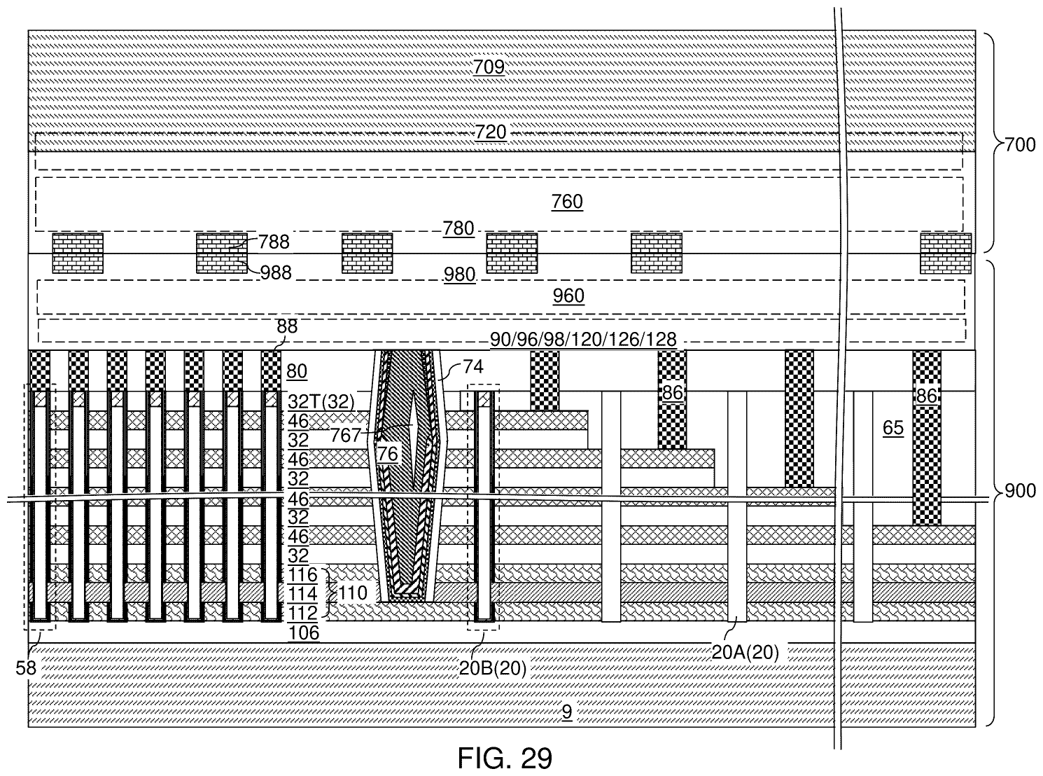

Referring to FIG. 29, a bonded assembly can be formed by bonding a logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

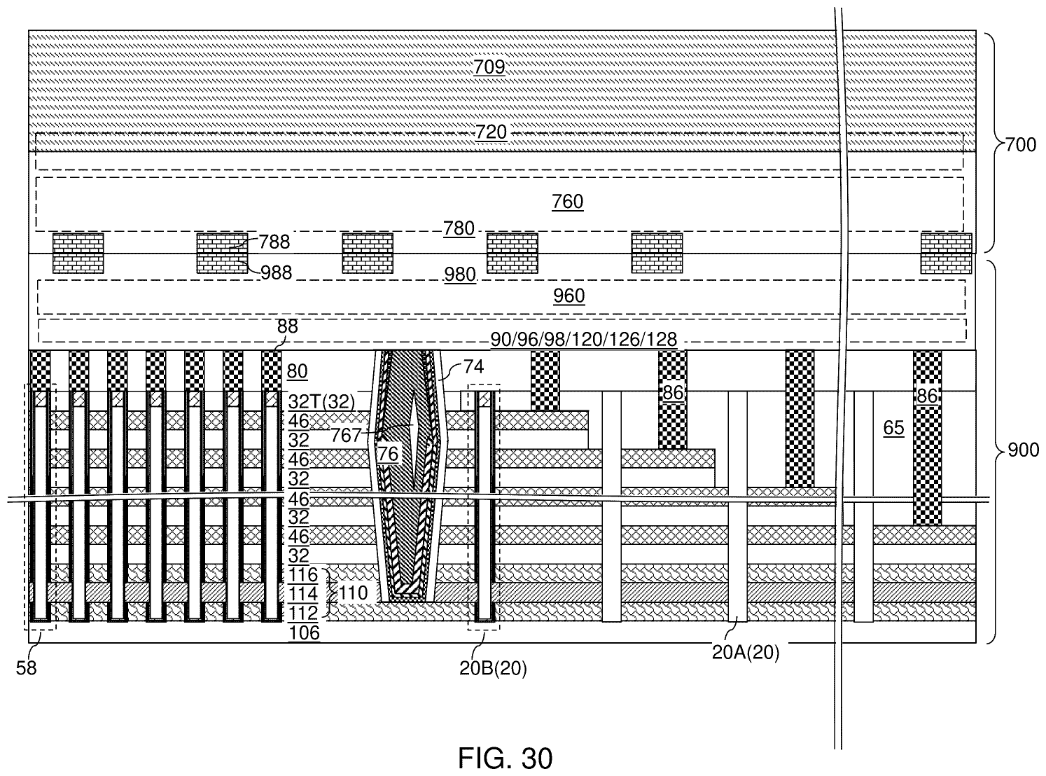

Referring to FIG. 30, the carrier substrate 9 can be removed, for example, by grinding, polishing, cleaving, an isotropic etch process, and/or an anisotropic etch process. If a polishing process such as a chemical mechanical polishing process is employed to remove the carrier substrate 9. In this case, the stopper insulating layer 106 may be employed as a polishing stopper material layer. If an etch process such as a wet etch process is employed to remove the carrier substrate 9, the stopper insulating layer 106 may be subsequently employed as an etch stop material layer.

Referring to FIG. 31, an alternative configuration of the first exemplary structure is illustrated. The alternative configuration of the first exemplary structure can be provided by forming semiconductor devices 620 comprising a peripheral circuit for controlling operation of a three-dimensional memory device on a semiconductor substrate 609, by forming metal interconnect structures 680 embedded in dielectric material layers 660 over the semiconductor devices 620. In other words, the combination of the semiconductor substrate 609, the semiconductor devices 620, the dielectric material layers 660, and the metal interconnect structures 680 can be employed in lieu of the carrier substrate 9. In-process source-level material layers 110′ and a vertically alternating sequence (32, 42) can be formed above the dielectric material layers 660.

Referring to FIG. 32, the processing steps described with reference to FIGS. 2-27 can be performed to provide a memory die, which may optionally be bonded to a logic die 700. In this case, memory-side bonding pads 988 may be present in the memory die. The semiconductor devices 620 may comprise a first subset of a peripheral circuit for controlling operation of a three-dimensional memory device, and the logic die 700 may comprise a second subset of the peripheral circuit for controlling operation of a three-dimensional memory device. The memory-side bonding pads 988 may be omitted if the memory die is not bonded to the logic die 900.

Referring to all drawings and according to various embodiments of the present disclosure, a three-dimensional memory device is provided, which comprises: a pair of alternating stacks (32, 46), wherein each alternating stack (32, 46) within the pair of alternating stacks (32, 46) comprises insulating layers 32 and electrically conductive layers 46 that are interlaced along a vertical direction, and wherein the pair of alternating stacks (32, 46) are laterally spaced from each other by a lateral isolation trench 79 that laterally extends along a first horizontal direction hd1; memory openings 49 vertically extending through a respective one of the pair of alternating stacks (32, 46); memory opening fill structures 58 located in a respective one of the memory openings 49 and comprising a respective vertical stack of memory elements (e.g., portions of the memory film 50) and a respective vertical semiconductor channel 60; and a lateral isolation trench fill structure (74, 76) located in the lateral isolation trench 79. The lateral isolation trench fill structure (74, 76) comprises a plurality of neck portions 78N having a pair of straight sidewalls which extend along the first horizontal direction hd1 and having a first width w1 along a second horizontal direction hd2 that is perpendicular to the first horizontal direction hd1; and a plurality of laterally bulging portions 78B having a second width w2 along the second horizontal direction hd2 that is greater than the first width w1, wherein the plurality of laterally bulging portions 78B is interlaced with the plurality of neck portions 78N along the first horizontal direction hd1.

In one embodiment, the memory opening fill structures 58 are located in a memory array region 100; layer contact via structures 86 contacting a respective one of the electrically conductive layers 46 and located in a contact region 300 that is laterally offset from the memory array region 100 along the first horizontal direction hd1; and the plurality of laterally bulging portions is located at least in a transition region 200 that is located between the memory array region 100 and the contact region 300. In one embodiment, each of the memory opening fill structures 58 further comprises a respective drain region 63 that is contacted by a respective drain contact via structure 88; and the transition region 200 and the contact region 300 are free of any drain contact via structure 88.

In one embodiment, the three-dimensional memory device comprises: first-type support pillar structures 20A each vertically extending through a respective one of the pair of alternating stacks (32, 46) and located in the contact region 300 and consisting essentially of at least one dielectric material; and second-type support pillar structures 20B each vertically extending through a respective one of the pair of alternating stacks (32, 46) and located in the transition region 200 and comprising a respective set of dielectric material layers and a respective semiconductor material layer. In one embodiment, each of the plurality of laterally bulging portions 78B is located adjacent to a respective one of the plurality of the second-type support pillar structures 20B along the second horizontal direction hd2; the respective vertical stack of memory elements comprises portions of a respective memory film 50 located at levels of the electrically conductive layers 46; and the respective memory film 50 has a same set of materials as and has a same thickness as the respective set of dielectric material layers. In one embodiment, the vertical semiconductor channel 60 has a same material composition and a same thickness as the respective semiconductor material layer.

In one embodiment, the plurality of laterally bulging portions 78B are located only in the transition region 200, and are not located in the memory array region 100 or in the contact region 300. In this embodiment, the plurality of interlaced laterally bulging portions 78B and neck portions 78N are located between a respective pair of straight surface segments 78S that extend along the first horizontal direction hd1 in the memory array region 100 and in the contact region 300. In another embodiment, the plurality of laterally bulging portions are also located within the memory array region 100.

In one embodiment, the plurality of laterally bulging portions 78B has a uniform pitch along the first horizontal direction hd1, and each of the plurality of laterally bulging portions has the second width w2 which is variable along the second horizontal direction hd2, and a pair of laterally convex surface segments that are laterally spaced from each other along the second horizontal direction hd2.

In one embodiment, each of the plurality of laterally bulging portions 78B comprises four laterally convex surface segments that are laterally spaced from each other and that do not directly contact each other. In one embodiment, each of the plurality of laterally bulging portions comprises a respective uniform width portion having a second width w2.

In one embodiment, the lateral isolation trench fill structure (74, 76) comprises an insulating spacer 74 and a conductive fill structure 76 that is laterally surrounded by the insulating spacer 74. In one embodiment, the conductive fill structure 76 comprises discrete airgaps 767 located in middle of the laterally bulging portions 78B and in middle of the neck portions 78N; and the discrete airgaps 767 are closed off and do not continue through interface regions between the laterally bulging portions 78B and the neck portions 78N along the first horizontal direction hd1.

In one embodiment, the insulating spacer 74 comprises: a pair of outer lengthwise sidewalls each comprising a plurality of laterally-convex surface segments that are interlaced with a plurality of first laterally-straight surface segments; and a pair of inner lengthwise sidewalls each comprising a plurality of laterally-concave surface segments that are interlaced with a plurality of second laterally-straight surface segments.

The various embodiments of the present disclosure can be employed to provide enhanced structural support by forming lateral isolation trenches 79 having laterally bulging portions 79B, and by forming conductive fill structures 76 having portions that are free of voids (i.e., airgaps) at interfaces between the bulging portions 78B and the neck portions 78N.

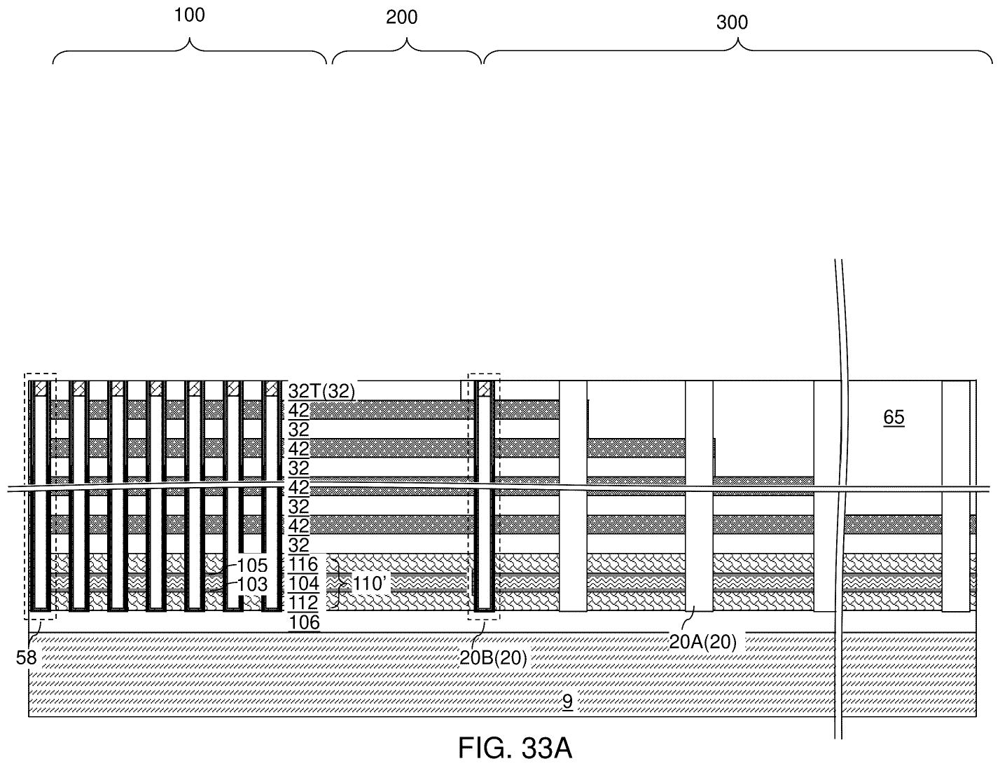

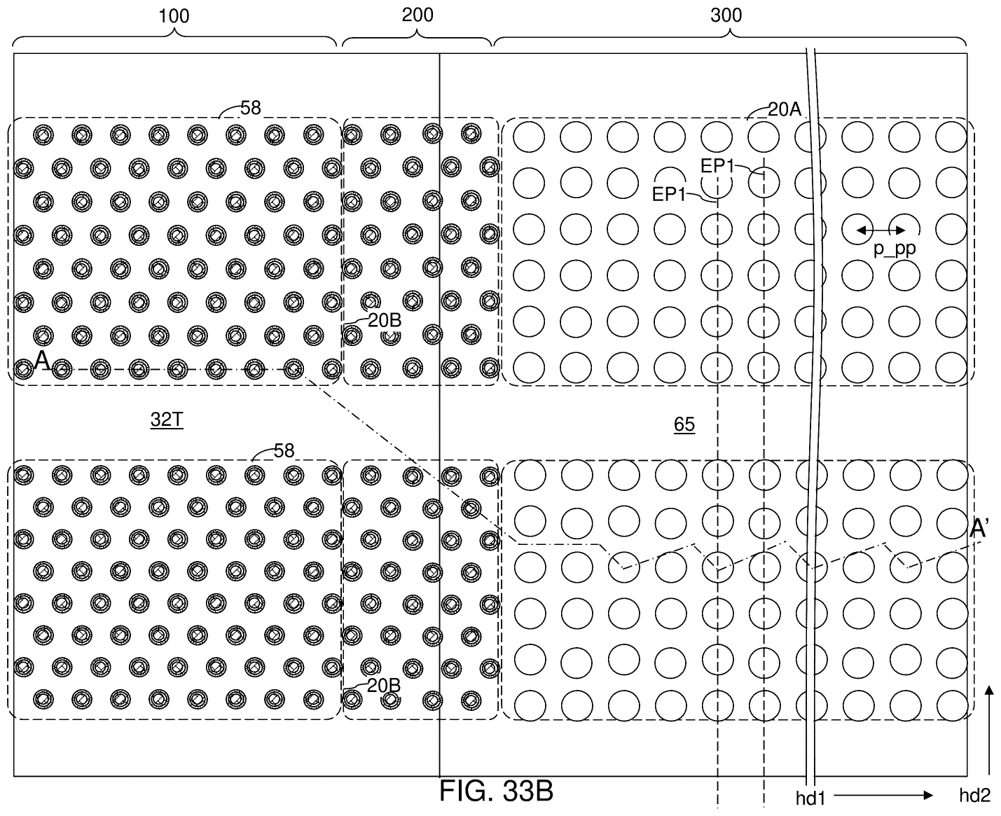

Referring to FIGS. 33A and 33B, a second exemplary structure according to a second embodiment of the present disclosure can be derived from the first exemplary structure illustrated in FIGS. 9A and 9B by altering the pattern of the first-type support pillar structures 20A and optionally altering the size of each first-type support pillar structure 20A. In the second exemplary structure, the first-type support pillar structures 20A are formed in rows arranged along the first horizontal direction hd1. Thus, each row of first-type support pillar structures 20A extends along the first horizontal direction hd1, and the rows of first-type support pillar structures 20A are spaced from each other along the second horizontal direction hd2 which is perpendicular to the first horizontal direction. In one embodiment, the first-type support pillar structures 20A in each row may be periodically arranged along the first horizontal direction hd1 with a uniform pitch, which is herein referred to as a pillar-to-pillar pitch p_pp. The first-type support pillar structures 20A vertically extend through the vertically alternating sequence of continuous insulating layers 32 and continuous sacrificial material layers 42.

Generally, the areas in which the first-type support pillar structures 20A are formed may be the same or approximately the same across the second exemplary structure and the first exemplary structure. In one embodiment, a set of rows of first-type support pillar structures 20A can be located between two strip-shaped areas in which a neighboring pair of lateral isolation trenches are to be subsequently formed. Such a set of rows of first-type support pillar structures 20A may be arranged as a rectangular array of first-type support pillar structures 20A. In this case, the geometrical centers of the first-type support pillar structures 20A may be arranged in a rectangular array in a plan view.

Within a Cartesian coordinate system employing a first axis that is parallel to the first horizontal direction hd1 and a second axis that is parallel to the second horizontal direction hd2 and representing each coordinate with a combination of a first component and a second component, the centers of gravity of the two-dimensional array of first-type support pillar structures 20A may be contained with a set of first Euclidean planes EP1 that are laterally spaced from each other by integer multiples of the pillar-to-pillar pitch p_pp. In this case, the first Euclidean planes EP1 that contain locations of geometrical centers of the first-type support pillar structures 20A are represented by a first set of fixed values for the first component in the Cartesian coordinate system. In an illustrative example, if an (x, y, z) coordinate system employs an x-axis that is parallel to the first horizontal direction hd1 and employs a y-axis that is parallel to the second horizontal direction hd2, the first Euclidean planes EP1 that contain locations of geometrical centers of the first-type support pillar structures 20A are represented by a first set of fixed x values in the (x, y, z) coordinate system. In other words, each first Euclidean plane EP1 can be a set of all points having a respective fixed value for the value of the x coordinate, and thus, is perpendicular to the first horizontal direction hd1. In this case, each fixed value within the first set of fixed values can be offset among one another by integer multiples of the uniform pitch within each row of first-type support pillar structures, i.e., the pillar-to-pillar pitch p_pp. The geometrical centers of the first-type support pillar structures 20A within the rows first-type support pillar structures 20A may be located entirely within the first Euclidean planes EP1.

In one embodiment, the rows of first-type support pillar structures 20A may consist of only dielectric material or materials, such as silicon oxide. The vertically alternating sequence (32, 42) comprises a staircase region in which lateral extents of the continuous sacrificial material layers 42 vary (e.g., decrease) along the first horizontal direction hd1 with a vertical distance from a horizontal plane including the bottommost surface of the vertically alternating sequence (32, 42). The rows of first-type support pillar structures 20A are located in the staircase region of the vertically alternating sequence (32, 42). The maximum lateral dimension (such as a diameter) of each first-type support pillar structure 20A may be in a range from 100 nm to 600 nm, although lesser and greater lateral dimensions may also be employed. In contrast, the maximum lateral dimension (such as a diameter) of each memory opening fill structure 58 described in the first embodiment may be in a range from 100 nm to 300 nm, although lesser and greater lateral dimensions may also be employed. Thus, the maximum lateral dimension of the first-type support pillar structures 20A may be the same as or larger than the maximum lateral dimension of the memory opening fill structures 58.

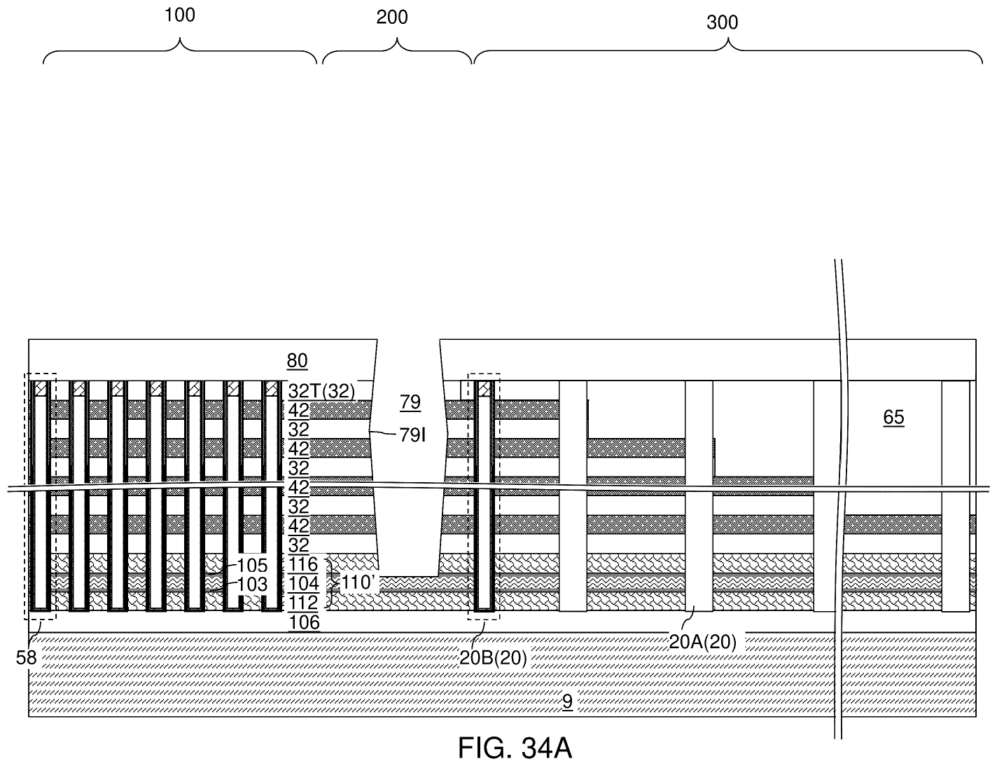

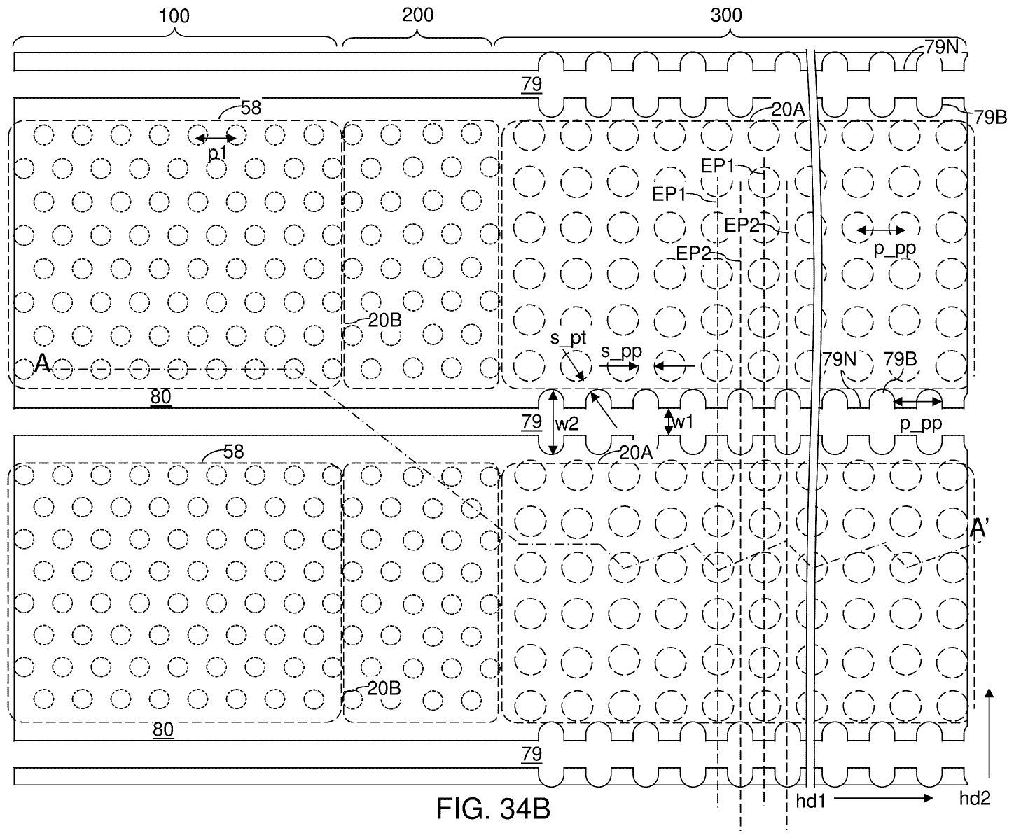

Referring to FIGS. 34A and 34B, the processing steps described with reference to FIGS. 10A and 10B can be performed to form a contact-level dielectric layer 80 and to form lateral isolation trenches 79. The lateral isolation trenches 79 are formed through the vertically alternating sequence of continuous insulating layers 32 and continuous sacrificial material layers 42, and divide the vertically alternating sequence into a plurality of alternating stacks of insulating layers 32 and sacrificial material layers 42 that are laterally spaced apart from each other along the second horizontal direction hd2. According the second embodiment of the present disclosure, the pattern of the lateral isolation trenches 79 in the second exemplary structure is modified such that each lateral isolation trench 79 has a variable width along the second horizontal direction hd2 within areas between each neighboring pair of two-dimensional arrays of first-type support pillar structures 20A. In this case, each lateral isolation trench 79 laterally extends generally along the first horizontal direction hd1, and has a variable width along the second horizontal direction hd2 in the contact region 300. According to an aspect of the second embodiment of the present disclosure, the variable width has a periodic undulation along the first horizontal direction hd1 with a periodicity that is the same as the uniform pitch of the first-type support pillar structures 20A, i.e., the pillar-to-pillar pitch p_pp.

In second embodiment, at least one of the lateral isolation trenches 79 comprises a respective plurality of laterally bulging portions 79B that are interlaced along the first horizontal direction hd1 with the neck portions 79N and with the rows of first-type support pillar structures 20A. Each of the neck portions 79N adjoined to a respective pair of the laterally bulging portions 79B of the lateral isolation trench 79. Thus, at least one of the lateral isolation trenches 79 comprises a respective plurality of laterally bulging portions 79B that is interlaced along the first horizontal direction hd1 with a respective most proximal row of the rows of the first-type support pillar structures 20A. The plurality of laterally bulging portions 79B are laterally spaced along the second horizontal direction hd2 from the rows of first-type support pillar structures 20A, such as from the most proximal row of first-type support pillar structures 20A. In other words, each neck portion 79N of the lateral isolation trench 79 is located adjacent along the second horizontal direction hd2 to a respective one of the first-type support pillar structures 20A of the most proximal row of first-type support pillar structures 20A. In contrast, each of the lateral bulging portion 79B is located adjacent along the second horizontal direction hd2 to a space between respective two of the first-type support pillar structures 20A of the most proximal row of first-type support pillar structures 20A.

Within a Cartesian coordinate system employing a first axis that is parallel to the first horizontal direction hd1 and a second axis that is parallel to the second horizontal direction hd2 and representing each coordinate with a combination of a first component and a second component, and the first Euclidean planes EP1 that contain locations of geometrical centers of the most proximal row of first-type support pillar structures 20A are represented by a first set of fixed values for the first component in the Cartesian coordinate system, second Euclidean planes EP2 that contain locations of maxima for the variable width (i.e., the maxima of the laterally bulging portions 79B) are represented by a second set of fixed values for first component in the Cartesian coordinate system, and each fixed value within the second set of fixed values is offset from a fixed value within the first set of fixed values by a product of an odd number (e.g., one) and one half of the uniform pitch, which is the pillar-to-pillar pitch p_pp. Thus, a first Euclidean plane EP1 may be located midway between a neighboring pair of second Euclidean planes EP2, and a second Euclidean plane EP2 may be located midway between a neighboring pair of first Euclidean planes EP1.

In the second embodiment, the rows of first-type support pillar structures 20A may be arranged as rectangular arrays of first-type support pillar structures 20A that are aligned along the first horizontal direction hd1, and thus, are laterally offset from the memory array region 100 by a same lateral offset distance.

In the second embodiment, each of the plurality of neck portions 79N may have a uniform width which is a first width w1, and each of the laterally bulging portions 79B may have a maximum width which is a second width w2. The second width w2 may be greater than the first width w1. For example, the second width w2 may be greater than the first width w1 by a difference that is in a range from 50% to 150%, such as from 75% to 125%, of the maximum lateral dimension (such as a diameter) of at least one of the first-type support pillar structures 20A. In one embodiment, the second width w2 is greater than the first width w1 by more than the maximum lateral dimension (such as a diameter) of at least one of the first-type support pillar structures 20A.

In one embodiment, for at least one of the lateral isolation trenches 79, each neighboring pair of first-type support pillar structures 20A within the most proximal row of first-type support pillar structures 20A may be laterally spaced apart from each other along the first horizontal direction hd1 by a pillar-to-pillar spacing s_pp. In one embodiment, a minimum distance s_pt between the most proximal row of support pillar structures (such as first-type support pillar structures 20A) and the lateral isolation trench 79 may be less than the pillar-to-pillar spacing s_pp. In one embodiment, for at least one of the lateral isolation trenches 79, the plurality of laterally bulging portions 79B are more proximal to the most proximal row of first-type support pillar structures 20A than the plurality of neck regions 79N are to the most proximal row of first-type support pillar structures 20A. For example, each bulging portion 79B in a lateral isolation trench 79 is spaced by the distance s_pt from two closest first-type support pillar structures 20A in the most proximal row, while each neck portion 79N in the same lateral isolation trench 79 is spaced by a distance that is greater than s_pt from the closest first-type support pillar structures 20A in the most proximal row.

In one embodiment, at least one of the lateral isolation trenches 79 has a uniform width throughout within a region that is located between neighboring clusters of the memory opening fill structures 58 that are laterally spaced from each other by a respective lateral isolation trench 79.

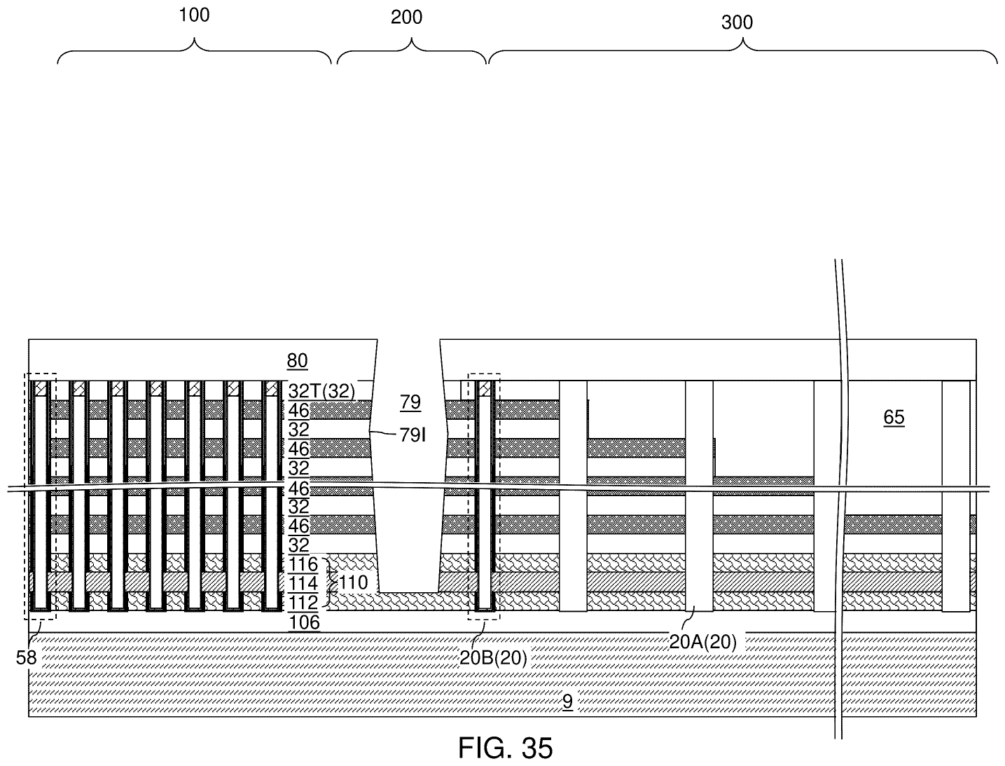

Referring to FIG. 35, the processing steps described with reference to FIGS. 12 and 13 can be performed to replace a combination of an optional lower sacrificial liner 103, a source-level sacrificial layer 104, an optional upper sacrificial liner 105, and surface portions of the memory films 50 with a source contact layer 114. Source-level material layers 110 can be formed underneath the alternating stacks of insulating layers 32 and sacrificial material layers 42.

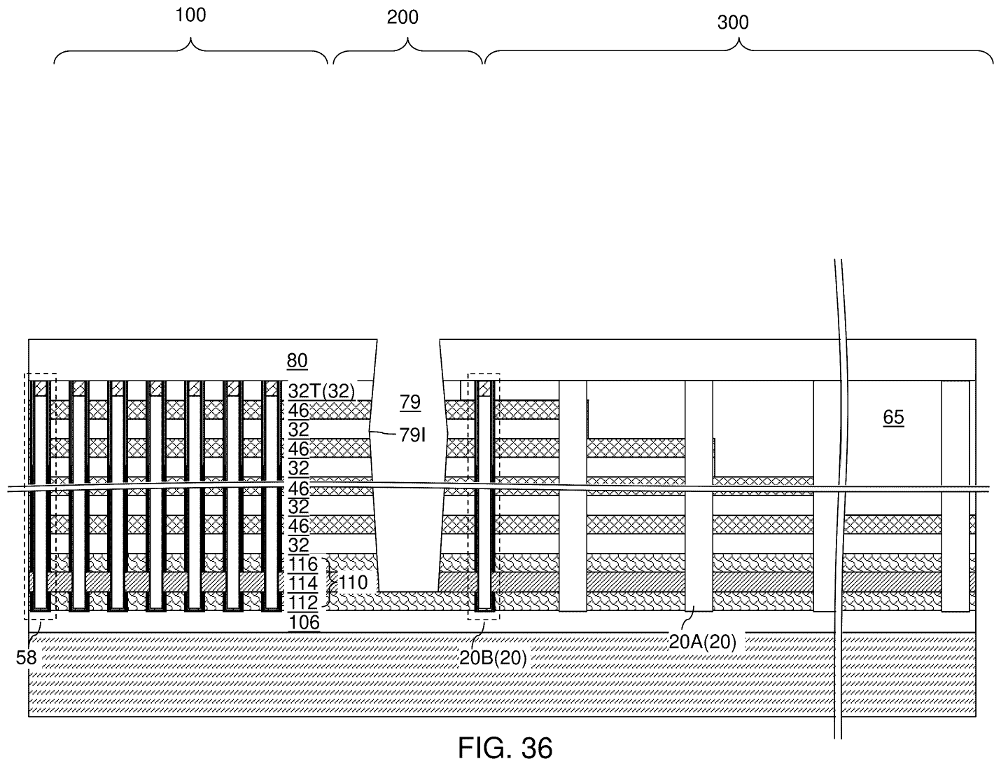

Referring to FIG. 36, the sacrificial material layers 42 can be replaced with electrically conductive layers 46. Alternating stacks of insulating layers 32 and electrically conductive layers 46 can be formed. The alternating stacks (32, 46) of insulating layers 32 and electrically conductive layers 46 are separated from each other by the lateral isolation trenches 79 along the second horizontal direction hd2.

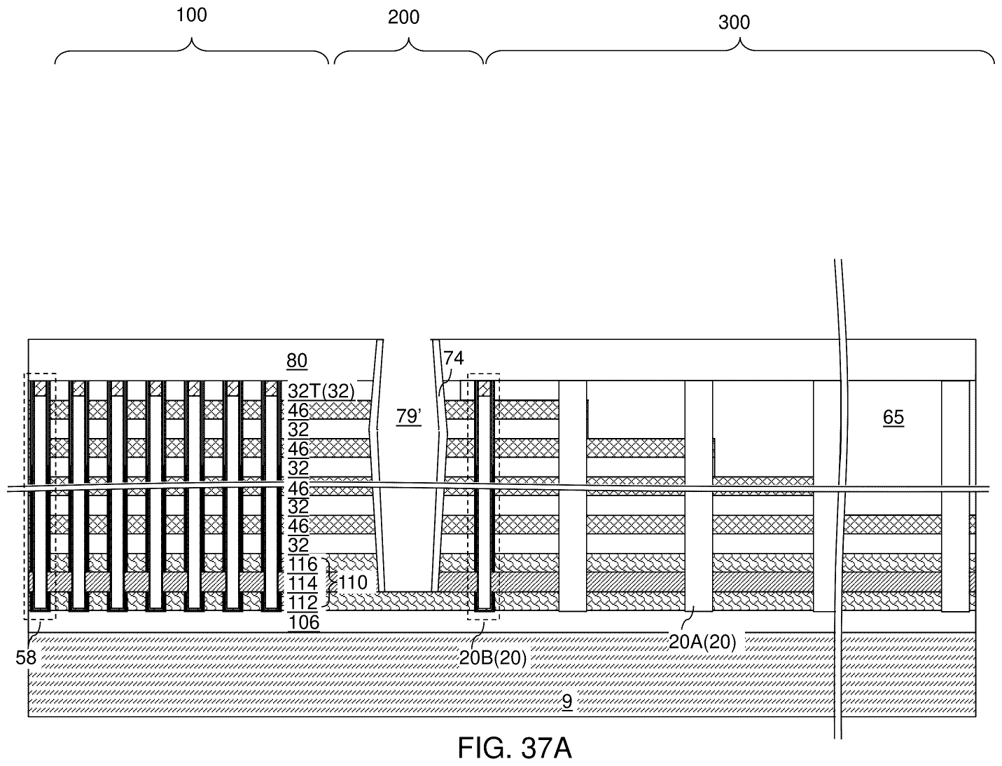

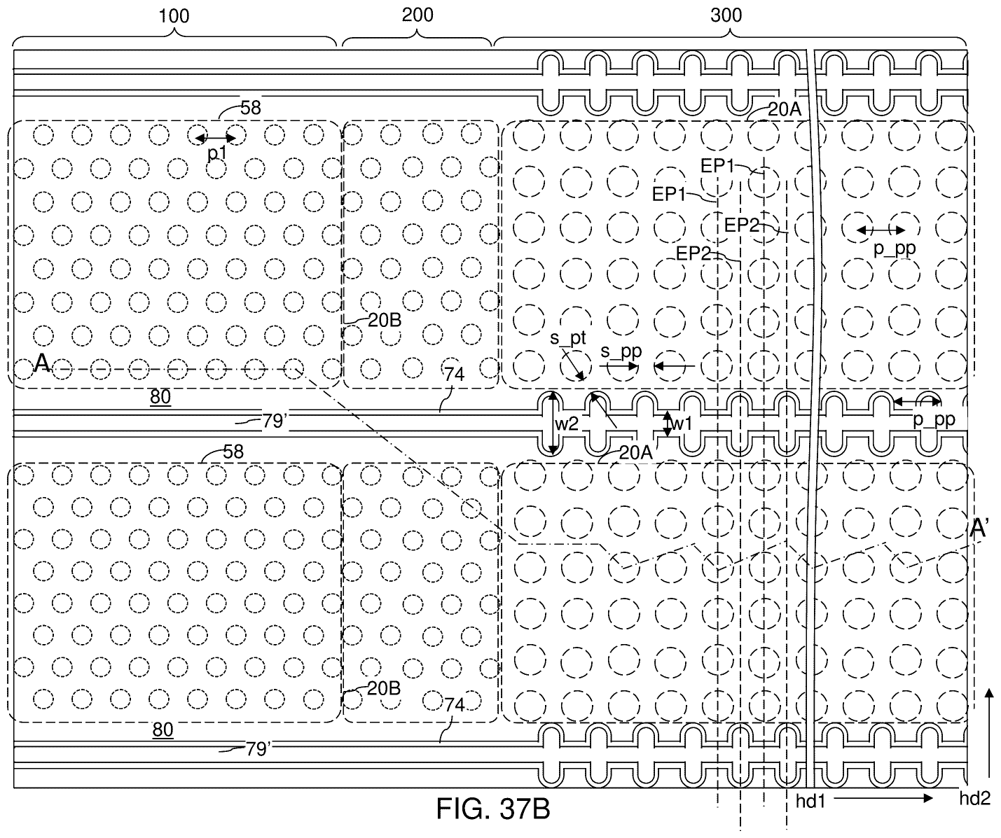

Referring to FIGS. 37A and 37B, the processing steps described with reference to FIGS. 17A-17E can be performed to form insulating spacers 74 in peripheral regions of the lateral isolation trenches 79.

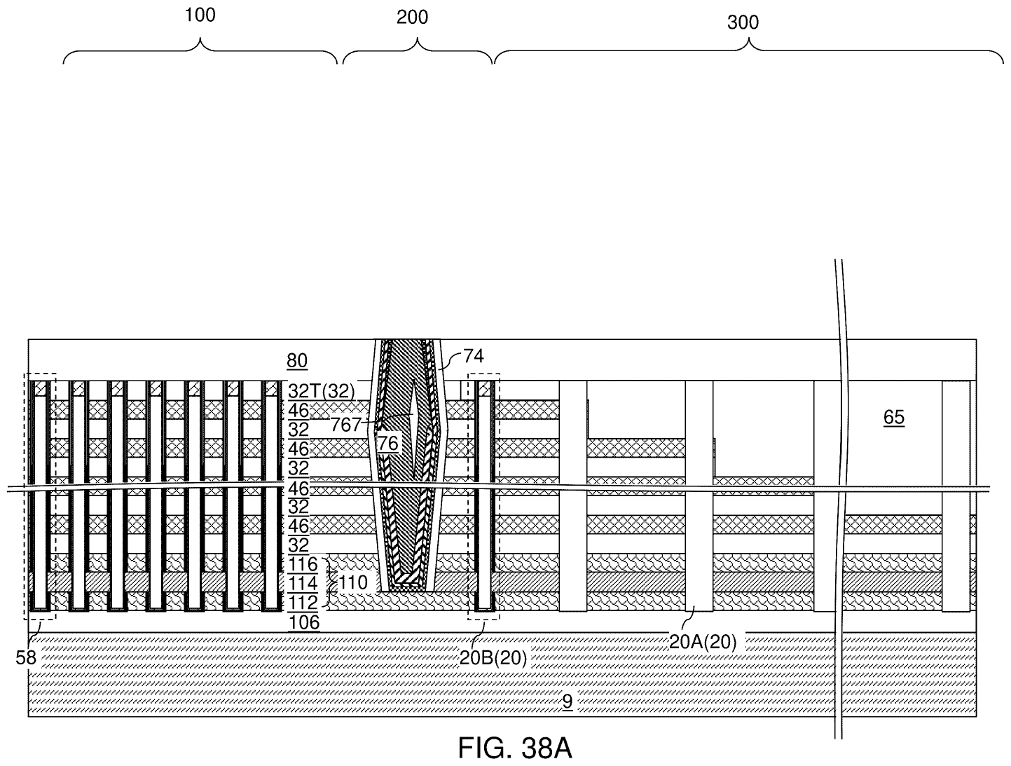

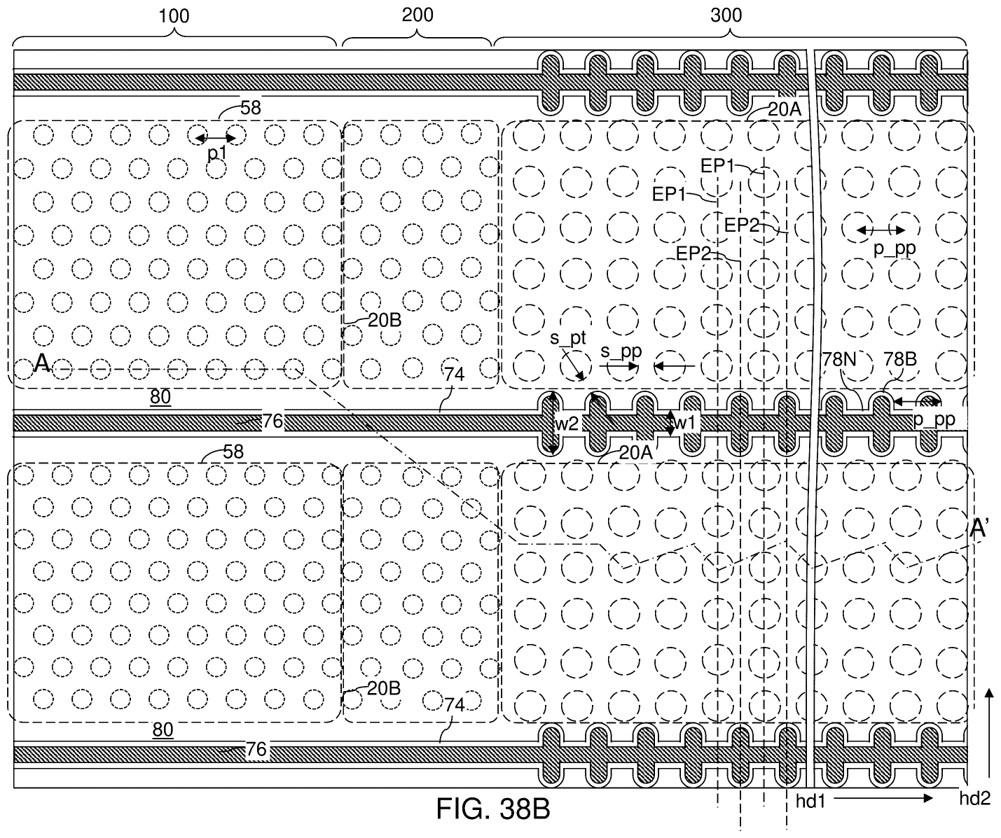

Referring to FIGS. 38A and 38B, the processing steps described with reference to FIGS. 18A-23E can be performed to form conductive fill structures 76. Each conductive fill structure 76 may comprise a same set of components as described with reference to the first exemplary structure. Each contiguous combination of an insulating spacer 74 and a conductive fill structure fills a respective lateral isolation trench 79, and constitutes an isolation trench fill structure (74, 76).

The second exemplary structure comprises a three-dimensional memory device. The three-dimensional memory device comprises: a pair of alternating stacks (32, 46), wherein each alternating stack (32, 46) within the pair of alternating stacks (32, 46) comprises insulating layers 32 and electrically conductive layers 46 that are interlaced along a vertical direction, and wherein the pair of alternating stacks (32, 46) are laterally spaced from each other by a lateral isolation trench 79 that laterally extends along a first horizontal direction hd1; memory openings 49 vertically extending through a respective one of the pair of alternating stacks (32, 46); memory opening fill structures 58 located in a respective one of the memory openings 49 and comprising a respective vertical stack of memory elements (which may comprise as portions of a memory material layer 54 located at levels of the electrically conductive layers 46) and a respective vertical semiconductor channel 60 and a respective vertical stack of memory elements; rows of support pillar structures (such as first-type support pillar structures 20A), wherein each row of the support pillar structures laterally extends along the first horizontal direction hd1 and vertically extends through a respective one of the pair of alternating stacks (32, 46); and a lateral isolation trench fill structure (74, 76) having a variable width along a second horizontal direction hd2 and located in the lateral isolation trench 79, the lateral isolation trench fill structure comprising: a plurality of neck portions 78N having a pair of straight sidewalls which extend along the first horizontal direction hd1 and having a first width w1 along the second horizontal direction hd2 that is perpendicular to the first horizontal direction; and a plurality of laterally bulging portions 78B having a second width w2 along the second horizontal direction hd2 that is greater than the first width w1, wherein the plurality of laterally bulging portions 78B is interlaced with the plurality of neck portions 78B along the first horizontal direction hd1.

In one embodiment, each row of the support pillar structures (such as first-type support pillar structures 20A) is extends along the first horizontal direction hd1 with a uniform pitch p_pp; and the variable width of the lateral isolation trench fill structure (74, 76) has a periodic undulation along the first horizontal direction hd1 with a periodicity that is the same as the uniform pitch p_pp.

In one embodiment, the lateral isolation trench fill structure (74, 76) is laterally spaced along the second horizontal direction hd2 from a most proximal row of the rows of the support pillar structures (such as first-type support pillar structures 20A).

In one embodiment, within a Cartesian coordinate system employing a first axis that is parallel to the first horizontal direction hd1 and a second axis that is parallel to the second horizontal direction hd2 and representing each coordinate with a combination of a first component and a second component, first Euclidean planes EP1 that contain locations of geometrical centers of the most proximal row of support pillar structures (such as first-type support pillar structures 20A) are represented by a first set of fixed values for the first component in the Cartesian coordinate system, second Euclidean planes EP2 that contain locations of maxima for the variable width are represented by a second set of fixed values for first component in the Cartesian coordinate system, and each fixed value within the second set of fixed values is offset from a fixed value within the first set of fixed values by a product of an odd number and one half of the uniform pitch p_pp. In one embodiment, geometrical centers of the support pillar structures (such as first-type support pillar structures 20A) within the rows of support pillar structures (such as first-type support pillar structures 20A) are located entirely within the first Euclidean planes EP1.

In one embodiment, each of the plurality of neck portions has a uniform width which is the first width w1; and each of the laterally bulging portions has a maximum width which is the second width w2. In one embodiment the second width w2 of greater than the first width w1 by a difference that is in a range from 50% to 150% of a maximum lateral dimension (such as a diameter) of one of the support pillar structures (such as the first-type support pillar structures 20A).

In one embodiment, each neighboring pair of support pillar structures (such as first-type support pillar structures 20A) within the most proximal row of support pillar structures (such as first-type support pillar structures 20A) is laterally spaced apart from each other along the first horizontal direction hd1 by a pillar-to-pillar spacing s_pp; and a minimum distance between the most proximal row of support pillar structures (such as first-type support pillar structures 20A) and the lateral isolation trench fill structure (74, 76) is less than the pillar-to-pillar spacing s_pp. In one embodiment, the plurality of laterally bulging portions 78B are more proximal to the most proximal row of support pillar structures (such as first-type support pillar structures 20A) than the plurality of neck regions 78N are to the most proximal row of support pillar structures (such as first-type support pillar structures 20A).

In one embodiment, each of the plurality of bulging portions 78B protrude along the second horizontal direction hd2 into the space between two adjacent support pillar structures 20A in the most proximal row of support pillar structures. In one embodiment, the plurality of laterally bulging portions 78B are more proximal to the most proximal row of the support pillar structures 20A than the plurality of neck regions 78N are to the most proximal row of support pillar structures 20A.

In one embodiment, the rows of support pillar structures (such as first-type support pillar structures 20A) contain only dielectric material or dielectric materials. In one embodiment, the rows of support pillar structures (such as first-type support pillar structures 20A) are arranged as two rectangular arrays of support pillar structures (such as first-type support pillar structures 20A) located within a respective alternating stack (32, 46) of the pair of alternating stacks (32, 46).

In one embodiment, each alternating stack (32, 46) of the pair of alternating stacks (32, 46) comprises a respective staircase region in which lateral extents of electrically conductive layers 46 within said each alternating stack (32, 46) along the first horizontal direction hd1 vary with a vertical distance from a horizontal plane including bottommost surfaces of the pair of alternating stacks (32, 46); and the rows of support pillar structures (such as first-type support pillar structures 20A) are located in the staircase regions of the pair of alternating stacks (32, 46). In one embodiment, the lateral isolation trench fill structure (74, 76) has a uniform width throughout within a region that is located between a first subset of the memory opening fill structures 58 vertically extending through a first alternating stack (32, 46) within the pair of alternating stacks (32, 46) and a second subset of the memory opening fill structures 58 vertically extending through a second alternating stack (32, 46) within the pair of alternating stacks (32, 46).

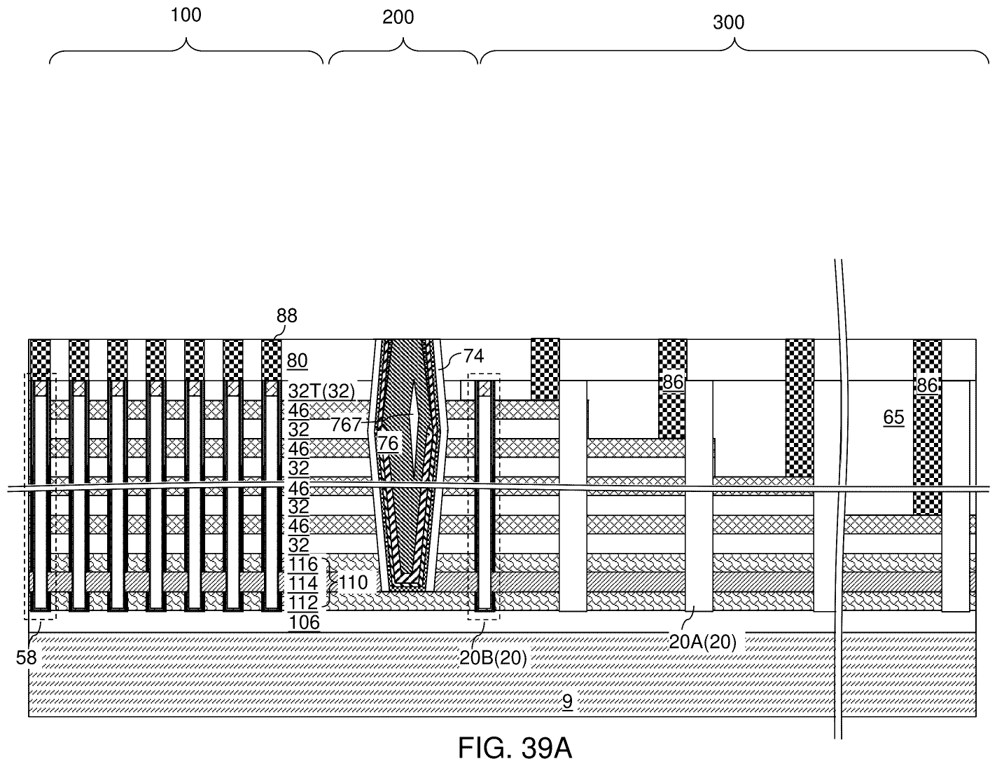

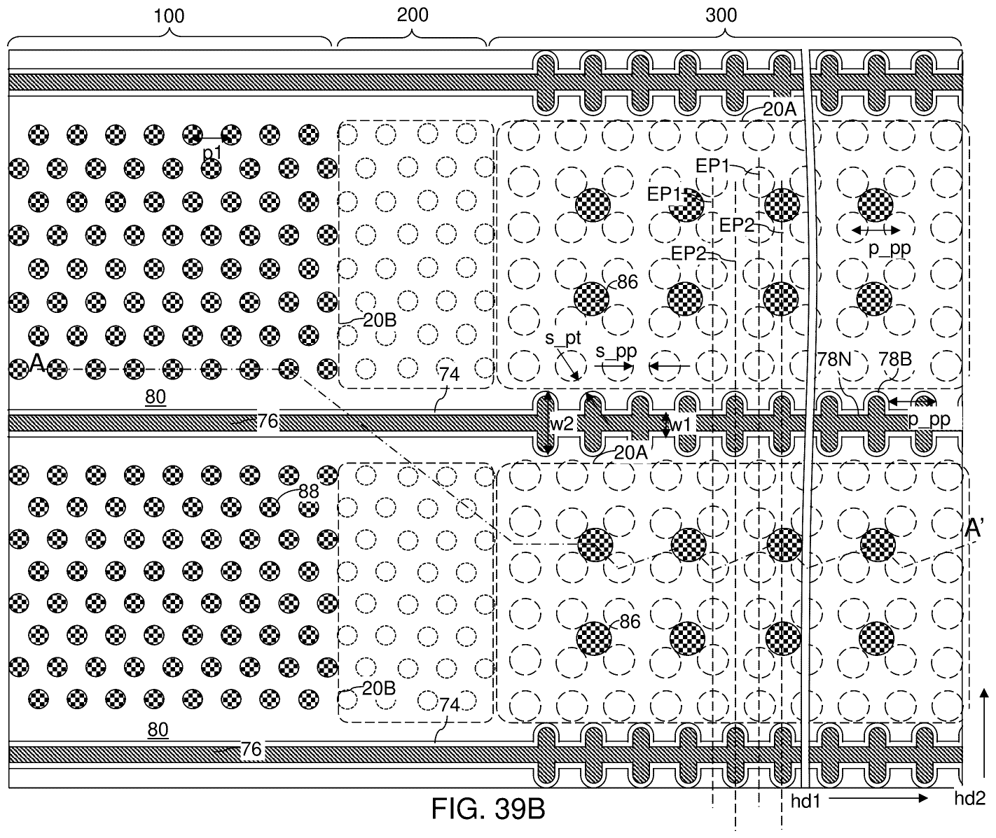

Referring to FIGS. 39A and 39B, the processing steps described with reference to FIGS. 25A and 25B may be performed to form various contact via structures (88, 86). In this case, the contact-level dielectric layer 80 overlies the alternating stacks (32, 46) and comprises multiple portions that are laterally spaced apart by the lateral isolation trenches 79. The drain contact via structures 88 vertically extend through the contact-level dielectric layer 80 and contact a top surface of a respective one of the memory opening fill structures 58. All top surfaces of the support pillar structures (such as first-type support pillar structures 20A) are in contact with a bottom surface of the contact-level dielectric layer 80.

Subsequently, the processing steps described with reference to FIGS. 26A-30 may be performed to form a bonded assembly of a memory die 900 and a logic die 700. Alternatively, the configurations illustrated in FIGS. 31 and 32 may be employed with necessarily modifications described with reference to FIGS. 33A-39A to provide an alternative embodiment of the second exemplary structure.

The laterally bulging portions 78B of the lateral isolation trench fill structures (74, 76) in the second embodiment of the second exemplary structure can reduce mechanical distortion of the three-dimensional memory array in the contact region 300. Specifically, the bulging portions 78B protrude along the second horizontal direction hd2 into the space between two adjacent first-type support pillar structures 20A in the most proximal row. This reduces the distance between the isolation trench fill structure (74, 76) and the closest first-type support pillar structures 20A in the most proximal row. This reduces deflection of the alternating stacks (32, 46) along the second horizontal direction hd2 and tilting of the alternating stacks into the lateral isolation trenches 79 during fabrication. Thus, the mechanical stability and reliability of the three-dimensional memory array may be enhanced.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
a pair of alternating stacks, wherein each alternating stack within the pair of alternating stacks comprises insulating layers and electrically conductive layers that are interlaced along a vertical direction, and wherein the pair of alternating stacks are laterally spaced from each other by a lateral isolation trench that laterally extends along a first horizontal direction;
memory openings vertically extending through a respective one of the pair of alternating stacks;
memory opening fill structures located in a respective one of the memory openings and comprising a respective vertical semiconductor channel and a respective vertical stack of memory elements;
rows of support pillar structures, wherein each row of the support pillar structures laterally extends along the first horizontal direction and vertically extends through a respective one of the pair of alternating stacks; and
a lateral isolation trench fill structure having a variable width along a second horizontal direction and located in the lateral isolation trench, the lateral isolation trench fill structure comprising:
a plurality of neck portions having a pair of straight sidewalls which extend along the first horizontal direction and having a first width along the second horizontal direction that is perpendicular to the first horizontal direction; and
a plurality of laterally bulging portions having a second width along the second horizontal direction that is greater than the first width, wherein the plurality of laterally bulging portions is interlaced with the plurality of neck portions along the first horizontal direction.

2. The three-dimensional memory device of claim 1, wherein:
each row of the support pillar structures extends along the first horizontal direction with a uniform pitch; and
the variable width of the lateral isolation trench fill structure has a periodic undulation along the first horizontal direction with a periodicity that is the same as the uniform pitch.

3. The three-dimensional memory device of claim 2, wherein the lateral isolation trench fill structure is laterally spaced along the second horizontal direction from a most proximal row of the rows of the support pillar structures.

4. The three-dimensional memory device of claim 3, wherein:
first Euclidean planes that contain locations of geometrical centers of the most proximal row of support pillar structures are represented by a first set of fixed values for a first component in a Cartesian coordinate system employing a first axis that is parallel to the first horizontal direction and a second axis that is parallel to the second horizontal direction and representing each coordinate with a combination of the first component and a second component;
second Euclidean planes that contain locations of maxima for the variable width are represented by a second set of fixed values for first component in the Cartesian coordinate system; and
each fixed value within the second set of fixed values is offset from a fixed value within the first set of fixed values by a product of an odd number and one half of the uniform pitch.

5. The three-dimensional memory array of claim 3, wherein:
each of the plurality of neck portions has a uniform width which is the first width;
each of the laterally bulging portions has a maximum width which is the second width.

6. The three-dimensional memory device of claim 3, wherein:
each neighboring pair of support pillar structures within the most proximal row of support pillar structures is laterally spaced apart from each other along the first horizontal direction by a pillar-to-pillar spacing; and
a minimum distance between the most proximal row of support pillar structures and the lateral isolation trench fill structure is less than the pillar-to-pillar spacing.

7. The three-dimensional memory device of claim 6, wherein the plurality of laterally bulging portions are more proximal to the most proximal row of support pillar structures than the plurality of neck regions are to the most proximal row of support pillar structures.

8. The three-dimensional memory device of claim 3, wherein each of the plurality of bulging portions protrude along the second horizontal direction into the space between two adjacent support pillar structures in the most proximal row of support pillar structures.

9. The three-dimensional memory device of claim 3, wherein the plurality of laterally bulging portions are more proximal to the most proximal row of the support pillar structures than the plurality of neck regions are to the most proximal row of support pillar structures.

10. The three-dimensional memory device of claim 1, further comprising:
a contact-level dielectric layer overlying the pair of alternating stacks and comprising two portions that are laterally spaced apart by the lateral isolation trench; and
drain contact via structures vertically extending through the contact-level dielectric layer and contacting a top surface of a respective one of the memory opening fill structures,
wherein all top surfaces of the support pillar structures are in contact with a bottom surface of the contact-level dielectric layer.

11. The three-dimensional memory device of claim 1, wherein the support pillar structures contain only dielectric material or dielectric materials.

12. The three-dimensional memory device of claim 1, wherein the rows of support pillar structures are arranged as two rectangular arrays of support pillar structures located within a respective alternating stack of the pair of alternating stacks.

13. The three-dimensional memory device of claim 1, wherein:
each alternating stack of the pair of alternating stacks comprises a respective staircase region in which lateral extents of electrically conductive layers within said each alternating stack along the first horizontal direction vary with a vertical distance from a horizontal plane including bottommost surfaces of the pair of alternating stacks; and
the rows of support pillar structures are located in the staircase regions of the pair of alternating stacks.

14. The three-dimensional memory device of claim 1, wherein the lateral isolation trench fill structure has a uniform width throughout within a region that is located between a first subset of the memory opening fill structures vertically extending through a first alternating stack within the pair of alternating stacks and a second subset of the memory opening fill structures vertically extending through a second alternating stack within the pair of alternating stacks.

15. A method of forming a three-dimensional memory device, comprising:
forming a vertically alternating sequence of continuous insulating layers and continuous sacrificial material layers over a substrate;
forming memory openings through the vertically alternating sequence;
forming memory opening fill structures in the memory openings, wherein each of the memory opening fill structures comprises a respective vertical stack of memory elements and a vertical semiconductor channel;
forming rows of support pillar structures, wherein each row of the support pillar structures is periodically arranged along a first horizontal direction with a uniform pitch and vertically extends through the vertically alternating sequence;
forming a lateral isolation trench that generally extends along the first horizontal direction through the vertically alternating sequence, wherein the lateral isolation trench has a variable width along a second horizontal direction, the variable width having a periodic undulation along the first horizontal direction with a periodicity that is the same as the uniform pitch; and
replacing remaining portions of the continuous sacrificial material layers with electrically conductive layers to form a pair of alternating stacks of insulating layers and electrically conductive layers that are separated by the lateral isolation trench along the second horizontal direction.

16. The method of claim 15, wherein the lateral isolation trench comprises a plurality of laterally bulging portions that is interlaced along the first horizontal direction with and is laterally spaced along the second horizontal direction from a most proximal row of the rows of the support pillar structures.

17. The method of claim 16, wherein:
first Euclidean planes that contain locations of geometrical centers of the most proximal row of support pillar structures are represented by a first set of fixed values for the first component in a Cartesian coordinate system employing a first axis that is parallel to the first horizontal direction and a second axis that is parallel to the second horizontal direction and representing each coordinate with a combination of the first component and a second component;
second Euclidean planes that contain locations of maxima for the variable width are represented by a second set of fixed values for first component in the Cartesian coordinate system; and
each fixed value within the second set of fixed values is offset from a fixed value within the first set of fixed values by a product of an odd number and one half of the uniform pitch.

18. The method of claim 16, wherein:
the lateral isolation trench comprises a plurality of neck portions that is interlaced along the first horizontal direction with the plurality of laterally bulging portions; and
each neck portion within the plurality of neck portions is adjoined to a respective pair of laterally bulging portions within the plurality of laterally bulging portions.

19. The method of claim 18, wherein:
each of the plurality of neck portions has a uniform width which is a first width; and
each of the laterally bulging portions has a maximum width which is greater than the first width.

20. The method of claim 16, wherein:
each neighboring pair of support pillar structures within the most proximal row of support pillar structures is laterally spaced apart from each other along the first horizontal direction by a pillar-to-pillar spacing; and
a minimum distance between the most proximal row of support pillar structures and the lateral isolation trench fill structure is less than the pillar-to-pillar spacing.
